(19) United States
(12) Patent Application Publication
(10) Pub. No.: US 2006/0022305 A1
(43) Pub. Date: Feb. 2, 2006

(54) Active-matrix-driven display device

(76) Inventor: Atsuhiro Yamashita, Osaka City (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(21) Appl. No.: 11/192,428

(22) Filed: Jul. 29, 2005

(30) Foreign Application Priority Data
Jul. 30, 2004 (JP) 2004-223765
Mar. 29, 2005 (JP) 2005-093490
Jun. 16, 2005 (JP) 2005-176279

(51) Int. Cl. H01L 27/082

(52) U.S. Cl. 257/565

(57) ABSTRACT

In a display panel, each pixel has a display element that emits light when fed with electric power, a writing transistor, a driving transistor that drives the display element, a first capacitive element that is provided in series with a line connecting the second electrode of the writing transistor and the control electrode of the driving transistor, and an adjustment transistor that, during a reset period, is turned on to feed a voltage commensurate with the electrode-to-electrode voltage of the display element to the writing-transistor-side electrode of the first capacitive element. A control signal generation circuit is provided that, during the reset period, lets a voltage commensurate with the light emission start electrode-to-electrode voltage of the display element be held in the first capacitive element.

This application is based on Japanese Patent Application No. 2004-223765 filed on Jul. 30, 2004, Japanese Patent Application No. 2005-093490 filed on Mar. 29, 2005, and Japanese Patent Application No. 2005-176279 filed on Jun. 16, 2005, the contents of which are hereby incorporated by reference.

### BACKGROUND OF THE INVENTION

1. Field of the Invention

The present invention relates to a display device in which a display element such as an organic electroluminescent (EL) element is driven by the use of switching devices such as thin-film transistors (TFTs), and more particularly to an active-matrix-driven display device.

2. Description of Related Art

In recent years, many advancements have been made in the development of organic electroluminescent displays (hereinafter organic EL displays; likewise display devices employing organic EL displays will hereinafter be referred to as organic EL display devices), and studies have been made on the application of organic EL displays to, for example, cellular phones.

Two conventionally known driving methods for organic EL displays are: passive matrix driving whereby time-divisional driving is performed by the use of scan electrodes and data electrodes; and active matrix driving whereby each pixel is kept emitting light for one vertical scan line period.

Driving methods applicable to active-matrix-driven organic EL displays include so-called voltage program driving methods as disclosed, for example, Japanese Patent Applications Laid-open Nos. 2003-108067 and 2003-122301. As will be discussed in detail later, using such a voltage program driving method helps eliminate the influence of pixel-to-pixel variation of the operation threshold voltage of the transistor contained as one component in the circuit configuration of each pixel. This technique will be described below with reference to FIGS. 16 and 17.

FIG. 16 shows the circuit configuration of a pixel 100 used in a voltage program driving method as mentioned above. The pixel 100 is composed of: N-channel MOS transistors (field-effect transistors with insulated gates) TR101, TR102, and TR104, all formed as thin-film transistors (TFTs); a driving transistor TR103 built as a P-channel MOS transistor, also formed as a TFT; a capacitor C101; and an organic EL element (OLED) 42 that emits light when fed with electric power.

The first electrode (for example, source) of the transistor TR101 is connected to a data voltage line to which a data voltage DATA is applied with predetermined timing. The second electrode (for example, drain) of the transistor TR101 is connected to one electrode of the capacitor C101. The gate of the transistor TR101 is connected to a scan voltage line to which a scan voltage SCAN is applied. The first electrode (for example, source) of the transistor TR102 is connected to the other electrode of the capacitor C101 and to the gate of the driving transistor TR103. The second electrode (for example, drain) of the transistor TR102 is connected to the drain of the driving transistor TR103 and to the drain of the transistor TR104. The gate of the transistor TR102 is connected to a control signal line to which a control signal CTL2 is applied.

The source of the transistor TR104 is connected to the anode of the organic EL element 42, and the gate of the transistor TR104 is connected to a control signal line to which a control signal CTL1 is applied. A supply voltage CV is applied to the cathode of the organic EL element 42, and a supply voltage VDD is applied to the source of the driving transistor TR103. The node between the capacitor C101 and the second electrode of the transistor TR101 will be referred to as the node N_{A0}, and the node between the capacitor C101 and the gate of the driving transistor TR103 will be referred to as the node N_{B0}.

Now, how this pixel operates will be described with reference to a time chart in FIG. 17, which shows the sequence of operations it performs. FIG. 17 shows the signal voltages of, from above, the data voltage line, the scan voltage line, the control signal line to which the control signal CTL1 is applied, and the control signal line to which the control signal CTL2 is applied.

During a period T1, the scan voltage SCAN turns high, and thus turns the transistor TR101 on (brings it into a conducting state). During the subsequent period T2, the control signal CTL2 turns high, and thus turns the transistor TR102 on. In period T2, a fixed voltage that does not represent a data voltage (brightness signal) is applied to the data voltage line, and in addition the control signal CTL1 is high. This turns the transistor TR104 on, and hence the differential voltage (VDD−CV) between the supply voltages VDD and CV is distributed between the anode-to-cathode voltage of the organic EL element 42 and the drain-to-source voltage (Vds) of the driving transistor TR103. Consequently, the voltage now appearing at the node N_{B0} is higher than the supply voltage CV by the voltage distributed as the anode-to-cathode voltage of the organic EL element 42.

During the subsequent period T3, the control signal CTL1 turns low, and thus turns the transistor TR104 off. Now, a current from the supply voltage VDD flows through the driving transistor TR103 and the transistor TR102 into the node N_{B0}, and thus the node N_{B0} is charged up to the voltage lower than the supply voltage VDD by the operation threshold voltage (Vth) of the driving transistor TR103. When the potential at the node N_{B0} has stabilized (that is, during the subsequent period T4), the control signal CTL2 turns low, and thus turns the transistor TR102 off (brings it into a cut-off state). The drain potential of the transistor TR104 now also equals (VDD−Vth).

In the period T5 subsequent to the period T4, a data voltage DATA (brightness signal) is applied to the data voltage line, and thus a voltage drop commensurate with the data voltage DATA appears at the node N_{B0}. In other words, a voltage commensurate with the data voltage DATA is written to the node N_{B0}. Then (that is, during the subsequent period T6), the scan voltage SCAN turns low, and thus turns the transistor TR101 off. Then, (that is, during the subsequent period T7), the voltage applied to the data voltage line returns to the fixed voltage mentioned previously. Then, during the subsequent period T8, the control signal CTL1 turns high, and thus turns the transistor TR104 on. Thus, a current with the magnitude commensurate with the voltage written to the node N_{B0} in the period T5 is fed to the organic EL element 42. As a result, the organic EL element 42 is lit with the brightness commensurate with the data voltage DATA. The organic EL element 42 is then kept lit for the period of one vertical scan line.

As will be understood from the foregoing, the voltage commensurate with the data voltage DATA, that is, the voltage written to the node N_{B0} in the period T5 and then held for one vertical scan line period by a voltage holder realized with the capacitor C101 and the gate capacity (unillustrated) of the driving transistor TR103, is determined relative to the voltage (VDD−Vth). Hence, the brightness of the organic EL element 42 is not influenced by variation of the operation threshold voltage (Vth) of the driving transistor TR103.

As discussed above, using a voltage program driving method helps eliminates the influence of pixel-to-pixel variation of the operation threshold voltage of the driving transistor TR103. Disappointingly, however, there still remains the influence of variation of the characteristics of the organic EL element 42. Now, the influence of variation of the characteristics of the organic EL element 42 will be studied with reference to FIG. 18.

FIG. 18 shows the relationship (hereinafter the “Vds-Id characteristic”) between the drain-to-source voltage (Vds) of the driving transistor TR103 and the drain current (Id) thereof and the relationship (hereinafter the “V_{OLED}-I_{OLED} characteristic”) between the anode-to-cathode voltage (V_{OLED}, hereinafter also referred to as the “electrode-to-electrode voltage”) of the organic EL element 42 and the current I_{OLED} that flows therethrough.

In FIG. 18, solid lines 200 each represent the Vds-Id characteristic observed when the gate-to-source voltage (Vgs) of the driving transistor TR103 is kept fixed at one of different voltages. A solid line 201 represents the V_{OLED}-I_{OLED} characteristic of the organic EL element 42 as observed when it is operated in the initial state thereof at a reference ambient temperature (for example, 25° C.). Here, the initial state of the organic EL element 42 denotes the state thereof in which it is at the time of (or immediately after) fabrication or at the time of shipment of the pixel 100.

As shown in FIG. 18, while the magnitude of the electrode-to-electrode voltage of the organic EL element 42 is lower than the magnitude of a voltage V_{F}, which depends on the characteristics of the organic EL element 42, no current flows through the organic EL element 42. When the magnitude of the electrode-to-electrode voltage of the organic EL element 42 reaches the magnitude of the voltage V_{F}, a current starts to flow through the organic EL element 42. This electrode-to-electrode voltage of the organic EL element 42 at which it starts to emit light will hereinafter be referred to the light emission start electrode-to-electrode voltage V_{F}. Since the current I_{OLED} that flows through the organic EL element 42 equals the drain current Id of the driving transistor TR103, the driving transistor TR103 and the organic EL element 42 operate, when considered in FIG. 18, at the intersection between a curve that represents the Vds-Id characteristic and a curve that represents the V_{OLED}-I_{OLED} characteristic.

The problem here is that, as time passes, the V_{OLED}-I_{OLED} characteristic, which is represented by the solid line 201 in the initial state, shifts as indicated by a broken line 202. That is, the operating point of the driving transistor TR103 and the organic EL element 42 varies with time. The consequence is that, depending on the level of gradation, in response to a given data voltage, a current lower than initially supposed flows through the organic EL element 42, resulting in accordingly lower brightness (though, at lower levels of gradation, no such lowering of the current occurs because the operating points lie within the saturation region).

The V_{OLED}-I_{OLED} characteristic of the organic EL element 42 also varies as the operating ambient temperature becomes low (for example, 0° C.) or high (for example, 45° C.). Specifically, when the organic EL element 42 is operated at a low temperature, the V_{OLED}-I_{OLED} characteristic shifts as indicated by the broken line 202. The consequence is that, depending on the level of gradation, in response to a given data voltage, a current lower than initially supposed flows through the organic EL element 42, resulting in accordingly lower brightness. On the other hand, when the organic EL element 42 is operated at a high temperature, the V_{OLED}-I_{OLED} characteristic shifts as indicated by a broken line 203. The consequence is that, depending on the level of gradation, in response to a given data voltage, a current higher than initially supposed flows through the organic EL element 42, resulting in accordingly higher brightness.

The influence of time-related and temperature-related variation as described above can be avoided when the operating points of the driving transistor TR103 and the organic EL element 42 at all the possible levels of gradation are set within the saturation region of the driving transistor TR103. Disadvantageously, however, setting the operating points in that way is equivalent to making the differential voltage between the supply voltages VDD and CV greater, and thus leads to increased power consumption. Moreover, to satisfactorily avoid the influence of time-related and temperature-related variation, the operating points need to be so set that they remain within the saturation region of the driving transistor TR103 even when, in the presence of time-related or temperature-related variation, the V_{OLED}-I_{OLED} characteristic shifts as indicated by the broken line 202 (specifically, the driving transistor TR103 needs to be operated in a higher-voltage part of the saturation region thereof), leading to increased power consumption.

It should be understood that, although the above discussion of the conventionally experienced problems assumes a circuit configuration employing a voltage program driving method, the same problems are encountered also in circuit configurations employing any other driving methods.

### SUMMARY OF THE INVENTION

It is therefore an object of the present invention to provide an active-matrix-driven display device that operates with reduced variation of brightness attributable to time-related or temperature-related variation with no increase in power consumption.

To achieve the above object, according to a first configuration of the present invention, in an active-matrix-driven display device including a display panel composed of a plurality of pixels arrayed in a matrix, the display panel is connected to a scan driver for feeding a scan voltage to each pixel and a data driver for feeding a data voltage to each pixel, the display panel is so driven that each frame period contains at least a reset period and a light emission period, and each pixel is built with a pixel circuit including: a display element that emits light when fed with electric power; a writing transistor that has the first electrode thereof connected to the data driver and that is turned on when a scan voltage having a predetermined level is applied thereto from the scan driver; a driving transistor that drives, according to a voltage applied to the control electrode thereof, the display element during the light emission period; a first capacitive element that is provided in series with the line connecting the second electrode of the writing transistor to the control electrode of the driving transistor; and an adjustment transistor that is turned on during the reset period to feed to the writing-transistor-side electrode of the first capacitive element a voltage commensurate with the electrode-to-electrode voltage of the display element. Here, the active-matrix-driven display device further includes a control signal generation circuit that, during the reset period, for each pixel circuit, lets a voltage commensurate with the light emission start electrode-to-electrode voltage of the display element be held in the first capacitive element.

During the reset period, in each pixel circuit, when the adjustment transistor turns on, a voltage (feedback voltage) commensurate with the electrode-to-electrode voltage of the display element is fed to the writing-transistor-side electrode of the first capacitive element, and, through the operation of the control signal generation circuit, a voltage (held voltage) commensurate with the light emission start electrode-to-electrode voltage is held in the first capacitive element. Then, for example, after the end of the reset period (for example, during a scan period), when the scan driver turns the writing transistor on, a data voltage is fed via the first capacitive element to the control electrode of the driving transistor. Here, in the first capacitive element, the light emission start electrode-to-electrode voltage is already stored. Consequently, a voltage commensurate with the data voltage and the light emission start electrode-to-electrode voltage is applied to the control electrode of the driving transistor.

That is, after the end of the reset period, for each pixel circuit, the scan driver turns the writing transistor on so that a voltage commensurate with the data voltage and the light emission start electrode-to-electrode voltage is applied to the control electrode of the driving transistor.

Thus, in each pixel circuit, the display element is driven by the driving transistor having the light emission start electrode-to-electrode voltage fed back to the control electrode thereof. Thus, even in the presence of variation of the characteristics of the display element attributable to time-related and temperature-related variation, the amount of light emitted by the display element during one frame period remains commensurate with the data voltage. That is, variation of brightness attributable to time-related and temperature-related variation is reduced.

Moreover, such reduction can be achieved with no increase in power consumption. To put otherwise, now that variation of brightness attributable to time-related and temperature-related variation is reduced, the driving transistor can be operated in a lower-voltage part of the saturation region thereof than is conventionally possible, or even in the linear region thereof, leading to lower power consumption. Incidentally, the light emission start electrode-to-electrode voltage denotes the electrode-to-electrode voltage (the voltage between the anode and cathode) of the display element as observed when it starts to emit light.

In one practical configuration, for example, during the reset period, for each pixel circuit, the control signal generation circuit, while turning the adjustment transistor on, turns the driving-transistor-side electrode of the first capacitive element to a predetermined potential to let the voltage commensurate with the light emission start electrode-to-electrode voltage of the display element be held in the first capacitive element, and then turns the adjustment transistor off.

In the first configuration described above, preferably, in each pixel circuit, the driving transistor has the first electrode, a second electrode, and the control electrode and so operates as to control the current flowing between the first electrode and the second electrode according to the voltage between the control electrode and the first electrode. Moreover, the pixel circuit of each pixel further includes: an on/off transistor that is provided in series with a power supply line extending from a power source from which to feed electric power to the display element and that turns on and off the feeding of electric power to the display element; and a threshold value compensation transistor that has the first electrode thereof connected to the control electrode of the driving transistor and that has the second electrode thereof connected to the second electrode of the driving transistor.

Preferably, for example, during the reset period, for each pixel circuit, the control signal generation circuit turns the on/off transistor on and thereby turns the driving transistor on, then turns the on/off transistor off and turns the adjustment transistor and the threshold value compensation transistor on to let a voltage commensurate with the light emission start electrode-to-electrode voltage of the display element and the operation threshold voltage of the driving transistor be held in the first capacitive element, and then turns the adjustment transistor and the threshold value compensation transistor off. Moreover, after the end of the reset period, for each pixel circuit, the scan driver turns the writing transistor on so that a voltage commensurate with the data voltage, the light emission start electrode-to-electrode voltage, and the operation threshold voltage is applied to the control electrode of the driving transistor.

In each pixel circuit, when the on/off transistor is turned on so that the driving transistor is turned on, and then the on/off transistor is turned off and the adjustment transistor and the threshold value compensation transistor are turned on, the voltage at the control electrode of the driving transistor stabilizes at a voltage different from the voltage at the first electrode thereof by the operation threshold voltage, and the voltage at the electrode of the first capacitive element opposite to the driving transistor stabilizes at a voltage commensurate with the light emission start electrode-to-electrode voltage. That is, a voltage commensurate with the light emission start electrode-to-electrode voltage of the display element and the operation threshold voltage of the driving transistor is held in the first capacitive element.

Thus, after the end of the reset period, for each pixel circuit, when the scan driver turns the writing transistor on, via the first capacitive element, a voltage commensurate not only with the data voltage and the light emission start electrode-to-electrode voltage but also with the operation threshold voltage is applied to the control electrode of the driving transistor.

Thus, in each pixel circuit, the display element is driven by the driving transistor having not only the light emission start electrode-to-electrode voltage but also the operation threshold voltage fed back to the control electrode thereof. Thus, with the configuration described above, even in the presence of variation of the operation threshold voltage of the driving transistor, the amount of light emitted by the display element during one frame period remains commensurate with the data voltage. That is, variation of brightness attributable to variation of the characteristics of the driving transistor is reduced.

Incidentally, the driving transistor is either of the type (for example, an N-channel MOS transistor) that permits a current to flow between the first and second electrodes thereof when the voltage between the control and first electrode thereof (that is, the voltage at the control electrode relative to that at the first electrode) is higher than or equal to the operation threshold voltage thereof or of the type (for example, a P-channel MOS transistor) that permits a current to flow between the first and second electrodes thereof when the voltage between the first and control electrode thereof (that is, the voltage at the first electrode relative to that at the control electrode) is higher than or equal to the operation threshold voltage thereof.

Preferably, for example, during the reset period, for each pixel circuit, the control signal generation circuit temporarily feeds from outside the pixel a predetermined reset voltage to the control electrode of the driving transistor to temporarily turn the driving transistor on without turning the on/off transistor on, then turns the adjustment transistor and the threshold value compensation transistor on to let a voltage commensurate with the light emission start electrode-to-electrode voltage of the display element and an operation threshold voltage of the driving transistor be held in the first capacitive element, and then turns the adjustment transistor and the threshold value compensation transistor off. Moreover, after the end of the reset period, for each pixel circuit, the scan driver turns the writing transistor on so that a voltage commensurate with the data voltage, the light emission start electrode-to-electrode voltage, and the operation threshold voltage is applied to the control electrode of the driving transistor.

With this configuration, during the reset period, in each pixel circuit, the on/off transistor does not turn on, and thus the display element does not emit light during the reset period. This leads to higher display quality.

In one practical configuration, for example, the pixel circuit of each pixel further includes a resetting transistor that, when turned on, short-circuits between both electrodes of the first capacitive element. Here, the reset voltage is fed from the data driver during the reset period. Moreover, during the reset period, for each pixel circuit, the scan driver turns the writing transistor on and the control signal generation circuit turns the resetting transistor on so that the reset voltage is temporarily fed to the control electrode of the driving transistor.

Preferable, for example, the active-matrix-driven display device further includes a ramp voltage generation circuit that generates a ramp voltage whose voltage value varies at a predetermined variation rate, and the pixel circuit of each pixel includes a second capacitive element that feeds the variation in the ramp voltage to the writing-transistor-side electrode of the first capacitive element.

Preferably, for example, the active-matrix-driven display device receives a gradation signal for image display to display an image, and the data driver feeds a data voltage corresponding to the gradation signal to each pixel circuit. Here, the variation rate of the ramp voltage is so set that, for each pixel circuit, let D represent the data voltage fed as corresponding to the received gradation signal, let D_{B} represent the data voltage fed when the gradation signal represents the black level of gradation, let L represent the brightness obtained as a result of the display element emitting light according to the fed data voltage D, let L_{B} represent the brightness obtained when the gradation signal represents the black level of gradation, let x represent D−D_{B}, and let y represent L−L_{B}+1, then the formula y=a^{x} (where a is a constant fulfilling a>1) is fulfilled.

With this configuration, lowering of brightness attributable to “lowering of light emission efficiency” of the display element can be reduced (that is, “burn-in” is compensated for). And this is achieved with no (or little) black level deterioration.

To achieve the above object, according to a second configuration of the present invention, in an active-matrix-driven display device including a display panel composed of a plurality of pixels arrayed in a matrix, the display panel is connected to a scan driver for feeding a scan voltage to each pixel and a data driver for feeding a data voltage to each pixel, the display panel is so driven that each frame period contains at least a reset period and a light emission period, and each pixel is built with a pixel circuit including: a display element that emits light when fed with electric power; a writing transistor that has the first electrode thereof connected to the data driver and that is turned on when a scan voltage having a predetermined level is applied thereto from the scan driver; a driving transistor that drives, according to the voltage applied to the control electrode thereof, the display element during the light emission period; a pulse width modulation circuit that outputs, during the light emission period, a predetermined light emission level voltage for making the display element emit light during a period commensurate with a data voltage fed from the data driver while the writing transistor is on; a first capacitive element that is provided in series with the line connecting the output end of the pulse width modulation circuit to the control electrode of the driving transistor; and an adjustment transistor that is turned on during the reset period to feed to the pulse-width-modulation-circuit-side electrode of the first capacitive element a voltage commensurate with the electrode-to-electrode voltage of the display element. Here, the active-matrix-driven display device further includes a control signal generation circuit that, during the reset period, for each pixel circuit, lets a voltage commensurate with the light emission start electrode-to-electrode voltage of the display element be held in the first capacitive element.

During the reset period, in each pixel circuit, when the adjustment transistor turns on, a voltage (feedback voltage) commensurate with the electrode-to-electrode voltage of the display element is fed to the pulse-width-modulation-circuit-side electrode of the first capacitive element. Moreover, during the reset period, a voltage (held voltage) commensurate with the light emission start electrode-to-electrode voltage is held in the first capacitive element. Then, before the beginning of the light emission period of one frame period (for example, after the end of the reset period or during the reset period), when the scan driver turns the writing transistor on, a data voltage is fed to the pulse width modulation circuit. The pulse width modulation circuit outputs a light emission level voltage for a period commensurate with the data voltage fed thereto, and thereby makes the display element emit light. Here, since, during the reset period, in each pixel circuit, a voltage commensurate with the light emission start electrode-to-electrode voltage of the display element is held in the first capacitive element, a voltage commensurate with the light emission level voltage and the light emission start electrode-to-electrode voltage is applied to the control electrode of the driving transistor for a period commensurate with the data voltage (that is, the period for which the pulse width modulation circuit outputs the light emission level voltage).

That is, before the light emission period, for each pixel circuit, the scan driver turns the writing transistor on so that a voltage commensurate with the light emission level voltage and the light emission start electrode-to-electrode voltage is applied to the control electrode of the driving transistor for the period commensurate with the data voltage.

Thus, in each pixel circuit, the display element is driven by the driving transistor having the light emission start electrode-to-electrode voltage fed back to the control electrode thereof. Thus, even in the presence of variation of the characteristics of the display element attributable to time-related and temperature-related variation, the amount of light emitted by the display element during one frame period remains commensurate with the data voltage. That is, variation of brightness attributable to time-related and temperature-related variation is reduced.

Moreover, such reduction can be achieved with no increase in power consumption. To put otherwise, now that variation of brightness attributable to time-related and temperature-related variation is reduced, the driving transistor can be operated in a lower-voltage part of the saturation region thereof than is conventionally possible, or even in the linear region thereof, leading to lower power consumption.

Here, variation of brightness is reduced while the contrast between different levels of gradation is retained as much as possible. Thus, deterioration of display quality attributable to time-related and temperature-related variation can be reduced satisfactorily.

In one practical configuration of the second configuration described above, for example, during the reset period, for each pixel circuit, the control signal generation circuit, while turning the adjustment transistor on, turns a driving-transistor-side electrode of the first capacitive element to a predetermined potential to let the voltage commensurate with the light emission start electrode-to-electrode voltage of the display element be held in the first capacitive element, and then turns the adjustment transistor off.

In the second configuration described above, preferably, in each pixel circuit, the driving transistor has a first electrode, a second electrode, and the control electrode and so operates as to control the current flowing between the first electrode and the second electrode according to the voltage between the control electrode and the first electrode. Moreover, the pixel circuit of each pixel further includes: an on/off transistor that is provided in series with a power supply line extending from a power source from which to feed electric power to the display element and that turns on and off the feeding of electric power to the display element; and a threshold value compensation transistor that has the first electrode thereof connected to the control electrode of the driving transistor and that has the second electrode thereof connected to the second electrode of the driving transistor.

Preferably, for example, during the reset period, for each pixel circuit, the control signal generation circuit turns the on/off transistor on and thereby turns the driving transistor on, then turns the on/off transistor off and turns the adjustment transistor and the threshold value compensation transistor on to let a voltage commensurate with the light emission start electrode-to-electrode voltage of the display element and the operation threshold voltage of the driving transistor be held in the first capacitive element, and then turns the adjustment transistor and the threshold value compensation transistor off. Moreover, before the light emission period, for each pixel circuit, the scan driver turns the writing transistor on so that a voltage commensurate with the light emission level voltage, the light emission start electrode-to-electrode voltage, and the operation threshold voltage is applied to the control electrode of the driving transistor for the period commensurate with the data voltage.

In each pixel circuit, when the on/off transistor is turned on so that the driving transistor is turned on, and then the writing transistor and the on/off transistor are turned off and the adjustment transistor and the threshold value compensation transistor are turned on, the voltage at the control electrode of the driving transistor stabilizes at a voltage different from the voltage at the first electrode thereof by the operation threshold voltage, and the voltage at the electrode of the first capacitive element opposite to the driving transistor stabilizes at a voltage commensurate with the light emission start electrode-to-electrode voltage. That is, a voltage commensurate with the light emission start electrode-to-electrode voltage of the display element and the operation threshold voltage of the driving transistor is held in the first capacitive element.

Thus, during the period for which the pulse width modulation circuit outputs the light emission level voltage, in each pixel circuit, a voltage commensurate not only with the light emission level voltage and the light emission start electrode-to-electrode voltage but also with the operation threshold voltage is applied to the control electrode of the driving transistor.

Thus, in each pixel circuit, the display element is driven by the driving transistor having not only the light emission start electrode-to-electrode voltage but also the operation threshold voltage fed back to the control electrode thereof. Thus, with the configuration described above, even in the presence of variation of the operation threshold voltage of the driving transistor, the amount of light emitted by the display element during one frame period remains commensurate with the data voltage. That is, variation of brightness attributable to variation of the characteristics of the driving transistor is reduced.

Preferably, for example, the pixel circuit of each pixel further includes a clipping circuit that prevents the potential at the control electrode of the driving transistor from becoming higher than a predetermined clip potential, or lower than a predetermined clip potential. Here, the clip potential is set at a potential that permits, during the reset period, for each pixel circuit, the control signal generation circuit to turn the adjustment transistor on and thereby temporarily turn the driving transistor on. Moreover, during the reset period, for each pixel circuit, the control signal generation circuit turns the adjustment transistor and the threshold value compensation transistor on, without turning the on/off transistor on, to let a voltage commensurate with the light emission start electrode-to-electrode voltage of the display element and the operation threshold voltage of the driving transistor be held in the first capacitive element, and then turns the adjustment transistor and the threshold value compensation transistor off. Moreover, before the light emission period, for each pixel circuit, the scan driver turns the writing transistor on so that a voltage commensurate with the light emission level voltage, the light emission start electrode-to-electrode voltage, and the operation threshold voltage is applied to the control electrode of the driving transistor for the period commensurate with the data voltage.

In the configuration described above, what would happen if the clipping circuit were not included in each pixel circuit is as follows. The potential at the control electrode of the driving transistor varies as the output voltage of the pulse width modulation circuit varies. Depending on the output voltage of the pulse width modulation circuit (the light emission level voltage, or the voltage outputted when the light emission level voltage is not being outputted), however, the driving transistor may not be turned on unless the on/off transistor is turned on during the reset period. If the driving transistor does not turn on at all during the reset period, it is impossible to hold a voltage commensurate with the operation threshold voltage of the driving transistor in the first capacitive element.

By contrast, when, as described above, the clipping circuit is included in each pixel circuit, and the clip potential is set at a potential that permits, during the reset period, for each pixel circuit, the control signal generation circuit to turn the adjustment transistor on and thereby temporarily turn the driving transistor on, the control signal generation circuit can then let a voltage commensurate with the operation threshold voltage of the driving transistor be held in the first capacitive element without turning the on/off transistor on during the reset period. Thus, with the configuration described above, in each pixel circuit, the on/off transistor does not turn on during the reset period, and thus the display element does not emit light during the reset period. This leads to higher display quality.

Preferably, for example, the active-matrix-driven display device further includes a ramp voltage generation circuit that generates a ramp voltage whose voltage value varies at a predetermined variation rate. Moreover, in each pixel circuit, the pulse width modulation circuit performs pulse width modulation on the data voltage by using the ramp voltage, and outputs, during the light emission period, the light emission level voltage for a period corresponding to the width of the pulse resulting from the pulse width modulation.

To achieve the above object, according to a third configuration of the present invention, in an active-matrix-driven display device including a display panel composed of a plurality of pixels arrayed in a matrix, the display panel is connected to a scan driver for feeding a scan voltage to each pixel and a data driver for feeding a data voltage to each pixel, the display panel is so driven that each frame period contains a first field and a second field of which each consists of a light emission preparation period and a light emission period, and each pixel is built with a pixel circuit including: a display element that emits light when fed with electric power; a writing transistor that has a first electrode thereof connected to the data driver and that is turned on when a scan voltage having a predetermined level is applied thereto from the scan driver; a driving transistor that drives, according to the voltage applied to the control electrode thereof, the display element; a first capacitive element that, at one end thereof, is connected to the control electrode of the driving transistor; and an adjustment transistor that is so connected to the display element as to receive, at the first electrode thereof, a voltage commensurate with the electrode-to-electrode voltage of the display element and that can transmit a feedback voltage commensurate with the light emission start electrode-to-electrode voltage of the display element to the first capacitive element. Here, the active-matrix-driven display device further includes a feedback controller that, during the light emission preparation period of, of the first and second fields, only the first field, for each pixel circuit, transmits the feedback voltage to the first capacitive element so that a held voltage reflecting the feedback voltage is held in the first capacitive element.

With the configuration described above, during the light emission preparation period of, of the first and second fields, only the first field, a voltage commensurate with the light emission start electrode-to-electrode voltage is held in the first capacitive element. Thus, in each pixel circuit, the display element is driven, in the first field, by the driving transistor having the light emission start electrode-to-electrode voltage fed back to the control electrode thereof and, in the second field, by the driving transistor receiving no such feedback.

Moreover, since one frame period contains a first and a second field each including a light emission period, the data voltage fed to each pixel circuit can be changed between in the first and second fields. Thus, for example, light emission corresponding to a low-gradation side can be dealt with in the second field. Thus, so-called black level deterioration that may result from the feedback mentioned above is reduced.

Moreover, as with the first configuration described above, the light emission start electrode-to-electrode voltage is fed back to the driving transistor, and thus variation of brightness attributable to time-related and temperature-related variation is reduced. Moreover, this reduction can be achieved with no increase in power consumption.

To permit light emission corresponding to a low-gradation side to be dealt with in the second field, for example, the active-matrix-driven display device receives a gradation signal for image display to display an image, and the active-matrix-driven display device further includes a gamma conversion circuit that, on receiving a gradation signal representing the middle level of gradation, converts the gradation signal into a first converted gradation signal corresponding to the first field and a second converted gradation signal corresponding to the second field and then feeds the first and second converted gradation signals to the data driver so that the effective value of the current that flows through the display element during the light emission period of the first field is smaller than the effective value of the current that flows through the display element during the light emission period of the second field. Moreover, the data driver feeds each pixel circuit with a data voltage corresponding to the first converted gradation signal in the first field and with a data voltage corresponding to the second converted gradation signal in the second field.

Alternatively, to permit light emission corresponding to a low-gradation side to be dealt with in the second field, for example, the active-matrix-driven display device receives a gradation signal for image display to display an image, and the active-matrix-driven display device further includes a gamma conversion circuit that converts the gradation signal into a first converted gradation signal corresponding to the first field and a second converted gradation signal corresponding to the second field and then feeds the first and second converted gradation signals to the data driver so that, assuming that the effective value of the current to be passed through the display element of each pixel circuit to correspond to a gradation signal representing the middle level of gradation is the reference current value, the effective value of the current that flows through the display element during the light emission period of the first field is smaller than the reference current value and the effective value of the current that flows through the display element during the light emission period of the second field is larger than the reference current value. Moreover, the data driver feeds each pixel circuit with a data voltage corresponding to the first converted gradation signal in the first field and with a data voltage corresponding to the second converted gradation signal in the second field.

Preferably, for example, in each pixel circuit, the driving transistor, during the light emission period of the second field, receives at the control electrode thereof a voltage commensurate with the data voltage corresponding to the second converted gradation signal and drives the display element according to that voltage, and, during the light emission period of the first field, receives at the control electrode thereof a voltage commensurate not only with the data voltage corresponding to the first converted gradation signal but also with the held voltage and drives the display element according to those voltages.

Preferably, for example, in each pixel circuit, the adjustment transistor has the second electrode thereof connected to the first capacitive element. Moreover, during the light emission preparation period of the first field, for each pixel circuit, the feedback controller extracts, via the adjustment transistor and the display element, the positive electric charge at the second electrode of the adjustment transistor which is temporarily given a potential higher than the potential equal to the sum of the potential at the cathode of the display element and the light emission start electrode-to-electrode voltage to thereby transmit the feedback voltage to the first capacitive element, and then turns the adjustment transistor off to thereby let the held voltage be held in the first capacitive element.

Preferably, for example, the feedback controller includes a control signal generation circuit that controls the turning on and off of the adjustment transistor in each pixel circuit. Moreover, in each pixel circuit, the first capacitive element is provided in series with a line connecting the second electrode of the writing transistor to the control electrode of the driving transistor, and the second electrode of the adjustment transistor is connected to the writing-transistor-side electrode of the first capacitive element. Moreover, during the light emission preparation period of the first field, for each pixel circuit, the control signal generation circuit turns the adjustment transistor on to transmit the feedback voltage to the first capacitive element, and then turns the adjustment transistor off to let the held voltage be held in the first capacitive element.

Practical examples of such configurations will be described later as the seventh, tenth, eleventh, and twelfth embodiments.

Preferably, for example, the active-matrix-driven display device further includes a ramp voltage generation circuit that generates a ramp voltage whose voltage value varies at a predetermined variation rate, and the pixel circuit of each pixel includes a second capacitive element that feeds the variation in the ramp voltage to the writing-transistor-side electrode of the first capacitive element.

Preferably, for example, in each pixel circuit, the driving transistor has a first electrode, a second electrode, and the control electrode and so operates as to control the current flowing between the first electrode and the second electrode according to the voltage between the control electrode and the first electrode. Moreover, the pixel circuit of each pixel further includes: an on/off transistor that is provided in series with a power supply line extending from a power source from which to feed electric power to the display element and that turns on and off the feeding of electric power to the display element; and a threshold value compensation transistor that has the first electrode thereof connected to the control electrode of the driving transistor and that has the second electrode thereof connected to the second electrode of the driving transistor.

With this configuration, in each pixel circuit, the operation threshold voltage of the driving transistor can also be fed back to the control electrode of the driving transistor. That is, variation of brightness attributable to variation of the characteristics of the driving transistor can be reduced.

Preferably, for example, the feedback controller includes a ramp voltage generation circuit that, during the light emission period of each field, for each pixel circuit, feeds a first ramp voltage to the first electrode of the writing transistor and that outputs a second ramp voltage for controlling the turning on and off of the adjustment transistor. Moreover, in each pixel circuit, the first capacitive element is provided in series with the line connecting the second electrode of the writing transistor to the control electrode of the driving transistor, and the second electrode of the adjustment transistor is connected to the driving-transistor-side electrode of the first capacitive element. Moreover, during the light emission preparation period of the first field, for each pixel circuit, the ramp voltage generation circuit turns the adjustment transistor on to transmit the feedback voltage to the first capacitive element, and then turns the adjustment transistor off to let the held voltage be held in the first capacitive element.

A practical example of such a configuration will be described later as the eighth embodiment.

Preferably, for example, the active-matrix-driven display device further includes a ramp voltage generation circuit that generates a ramp voltage whose voltage value varies at a predetermined variation rate and that, during each light emission period, for each pixel circuit, feeds a variation in the ramp voltage via the first capacitive element to the control electrode of the driving transistor. Moreover, in each pixel circuit, the one end of the first capacitive element is connected to the second electrode of the writing transistor, and the other end of the first capacitive element is connected to the second electrode of the adjustment transistor. Moreover, during the light emission preparation period of the first field, for each pixel circuit, the feedback controller turns the adjustment transistor on to transmit the feedback voltage to the first capacitive element, and then turns the adjustment transistor off to let the held voltage be held in the first capacitive element.

A practical example of such a configuration will be described later as the ninth embodiment.

To achieve the above object, according to a fourth configuration of the present invention, in an active-matrix-driven display device including a display panel composed of a plurality of pixels arrayed in a matrix, the display panel is connected to a scan driver for feeding a scan voltage to each pixel and a data driver for feeding a data voltage to each pixel, the display panel is so driven that each frame period contains a first field and a second field of which each consists of a light emission preparation period and a light emission period, and each pixel is built with a pixel circuit including: a display element that emits light when fed with electric power; a writing transistor that has the first electrode thereof connected to the data driver and that is turned on when a scan voltage having a predetermined level is applied thereto from the scan driver; a driving transistor that drives, according to the voltage applied to the control electrode thereof, the display element; a first capacitive element that, at one end thereof, is connected to the control electrode of the driving transistor; and an adjustment transistor that is so connected to the display element as to receive, at the first electrode thereof, a voltage commensurate with the electrode-to-electrode voltage of the display element and that can transmit a feedback voltage commensurate with the light emission start electrode-to-electrode voltage of the display element to the first capacitive element. Here, the active-matrix-driven display device receives a gradation signal for image display to display an image, and further includes: a ramp voltage generation circuit that generates a ramp voltage whose voltage value varies at a predetermined variation rate and that, during each light emission period, for each pixel circuit, feeds the variation in the ramp voltage via the first capacitive element to the control electrode of the driving transistor; a feedback controller that, during the light emission preparation periods of both the first and second fields, for each pixel circuit, transmits the feedback voltage to the first capacitive element so that a held voltage reflecting the feedback voltage is held in the first capacitive element; and a gamma conversion circuit that converts the gradation signal into a first converted gradation signal corresponding to the first field and a second converted gradation signal corresponding to the second field and then feeds the first and second converted gradation signals to the data driver so that, for each pixel circuit, a first data voltage that represents as a data voltage a high-gradation side of the gradation signal is fed to the pixel circuit in the first field and a second data voltage that represents as a data voltage a low-gradation side of the gradation signal is fed to the pixel circuit in the second field. Here, the variation rate of the ramp voltage in the second field is higher than the variation rate of the ramp voltage in the first field.

The fourth configuration described above corresponds to, for example, the thirteenth embodiment described later. With the configuration described above, during the light emission preparation period of both the first and second fields, in each pixel circuit, a voltage commensurate with the light emission start electrode-to-electrode voltage is held in the first capacitive element. Moreover, for example, during the light emission preparation period of each field, the scan driver turns the writing transistor on so that a data voltage is transmitted to the control electrode of the driving transistor. Furthermore, during the light emission period of each field, the variation in the ramp voltage is fed via the first capacitive element to the control electrode of the driving transistor. Thus, during the light emission period of each field, the light emission by the display element is controlled according to “the light emission start electrode-to-electrode voltage, the data voltage, and the variation in the ramp voltage” applied to the control electrode of the driving transistor.

As described above, in both fields, in each pixel circuit, a voltage commensurate with the light emission start electrode-to-electrode voltage is held in the first capacitive element. Here, the variation in the ramp voltage in the second field is greater than that in the first field. Thus, the degree to which the variation of the light emission start electrode-to-electrode voltage contributes to brightness (the duration of light emission) is lower in the second field than in the first degree.

Moreover, the gamma conversion circuit permits a high-gradation side to be represented in the first field and a low-gradation side to be represented in the second field. Thus, in each pixel circuit, the current that flows through the display element as corresponding to a low-gradation-side gradation signal is influenced comparatively slightly by the variation of the light emission start electrode-to-electrode voltage. Thus, so-called black level deterioration that may result from the feedback of the light emission start electrode-to-electrode voltage is reduced.

Even then, as with the first configuration described above, the light emission start electrode-to-electrode voltage is fed back to the driving transistor, and thus variation of brightness attributable to time-related and temperature-related variation is reduced. Moreover, this reduction can be achieved with no increase in power consumption.

In the fourth configuration described above, preferably, for example, in each pixel circuit, the adjustment transistor has the second electrode thereof connected to the first capacitive element. Moreover, during the light emission preparation period of each of the first and second fields, for each pixel circuit, the feedback controller extracts, via the adjustment transistor and the display element, the positive electric charge at the second electrode of the adjustment transistor which is temporarily given a potential higher than the potential equal to the sum of the potential at the cathode of the display element and the light emission start electrode-to-electrode voltage to thereby transmit the feedback voltage to the first capacitive element, and then turns the adjustment transistor off to thereby let the held voltage be held in the first capacitive element.

To achieve the above object, according to a fifth configuration of the present invention, in an active-matrix-driven display device including a display panel composed of a plurality of pixels arrayed in a matrix, the display panel is connected to a scan driver for feeding a scan voltage to each pixel and a data driver for feeding a data voltage to each pixel, the display panel is so driven that each frame period contains at least a reset period and a light emission period, and each pixel is built with a pixel circuit including: a display element that emits light when fed with electric power; a writing transistor that has the first electrode thereof connected to the data driver and that is turned on when a scan voltage having a predetermined level is applied thereto from the scan driver; a driving transistor that drives, according to the voltage applied to the control electrode thereof, the display element during the light emission period; a switching transistor that, when turned on, feeds a voltage for turning the driving transistor on to the control electrode of the driving transistor; a first capacitive element that is provided in series with the line connecting the second electrode of the writing transistor to the control electrode of the switching transistor; and an adjustment transistor that is turned on during the reset period to feed to the writing-transistor-side electrode of the first capacitive element a voltage commensurate with the electrode-to-electrode voltage of the display element. Here, the active-matrix-driven display device further includes a control signal generation circuit that, during the reset period, for each pixel circuit, lets a voltage commensurate with the light emission start electrode-to-electrode voltage of the pixel be held in the first capacitive element.

The fifth configuration described above corresponds to, for example, the fourteenth embodiment described later. With the configuration described above, the switching transistor turns on and off according to the light emission start electrode-to-electrode voltage and the data voltage. When the switching transistor turns on, the driving transistor turns on and makes the display element emit light. That is, the display element is driven by the driving transistor that turns on according to the light emission start electrode-to-electrode voltage. Thus, as with the first configuration described above, variation of brightness attributable to time-related and temperature-related variation is reduced.

In the fifth configuration described above, preferably, for example, the active-matrix-driven display device further includes a ramp voltage generation circuit that generates a ramp voltage whose voltage value varies at a predetermined variation rate. Moreover, the pixel circuit of each pixel includes a second capacitive element that feeds the variation in the ramp voltage to the writing-transistor-side electrode of the first capacitive element.

Preferably, for example, the active-matrix-driven display device receives a gradation signal for image display to display an image, and the data driver feeds a data voltage corresponding to the gradation signal to each pixel circuit. Here, the variation rate of the ramp voltage is so set that, for each pixel circuit, let D represent the data voltage fed as corresponding to the received gradation signal, let D_{B} represent the data voltage fed when the gradation signal represents the black level of gradation, let I represent the effective value of the current that flows through the display element as corresponding to the fed data voltage D, let I_{B} represent the effective value of the current that flows through the display element when the gradation signal represents a black level of gradation, let x represent D−D_{B}, and let y_{I} represent I−I_{B}+1, then the formula y_{I}=a^{x} (where a is a constant fulfilling a>1) is fulfilled.

To achieve the above object, according to a sixth configuration of the present invention, in an active-matrix-driven display device including a display panel composed of a plurality of pixels arrayed in a matrix, the display panel is connected to a scan driver for feeding a scan voltage to each pixel and a data driver for feeding a data voltage to each pixel, the display panel is so driven that each frame period contains a first field and a second field of which each consists of a light emission preparation period and a light emission period, and each pixel is built with a pixel circuit including: a display element that emits light when fed with electric power; a writing transistor that has the first electrode thereof connected to the data driver and that is turned on when a scan voltage having a predetermined level is applied thereto from the scan driver; a driving transistor that drives, according to the voltage applied to the control electrode thereof, the display element; a switching transistor that, when turned on, feeds a voltage for turning the driving transistor on to the control electrode of the driving transistor; a first capacitive element that is provided in series with the line connecting the second electrode of the writing transistor to the control electrode of the switching transistor; and an adjustment transistor that is so connected to the display element as to receive, at the first electrode thereof, a voltage commensurate with the electrode-to-electrode voltage of the display element and that can transmit a feedback voltage commensurate with the light emission start electrode-to-electrode voltage of the display element to the first capacitive element. Here, the active-matrix-driven display device further includes a feedback controller that, during the light emission preparation period of, of the first and second fields, only the first field, for each pixel circuit, transmits the feedback voltage to the first capacitive element so that a held voltage reflecting the feedback voltage is held in the first capacitive element.

The sixth configuration described above corresponds to, for example, the fifteenth embodiment described later. The sixth configuration offers the same advantages as the fifth configuration. In addition, as with the third configuration described above, light emission corresponding to a low-gradation side can be dealt with in the second field. Thus, so-called black level deterioration that may result from the feedback of the light emission start electrode-to-electrode voltage is reduced.

In the sixth configuration described above, preferably, for example, the active-matrix-driven display device further includes a ramp voltage generation circuit that generates a ramp voltage whose voltage value varies at a predetermined variation rate, and the pixel circuit of each pixel includes a second capacitive element that feeds the variation in the ramp voltage to the writing-transistor-side electrode of the first capacitive element.

Preferably, for example, the active-matrix-driven display device receives a gradation signal for image display to display an image. Moreover, the active-matrix-driven display device further includes a gamma conversion circuit that converts the gradation signal into a first converted gradation signal corresponding to the first field and a second converted gradation signal corresponding to the second field and then feeds the first and second converted gradation signals to the data driver. Moreover, the data driver feeds each pixel circuit with a first data voltage corresponding to the first converted gradation signal in the first field and with a second data voltage corresponding to the second converted gradation signal in the second field. Here, the variation rate of the ramp voltage is so set that, for each pixel circuit, let D represent the first data voltage fed as corresponding to the received gradation signal, let D_{B} represent the first data voltage fed when the gradation signal represents the black level of gradation, let I represent the effective value of the current that flows, in the first field, through the display element as corresponding to the fed first data voltage D, let I_{B} represent the effective value of the current that flows, in the first field, through the display element when the gradation signal represents the black level of gradation, let x represent D−D_{B}, and let y_{I} represent I−I_{B}+1, then the formula y_{I}=a^{x} (where a is a constant fulfilling a>1) is fulfilled.

Preferably, for example, in each pixel circuit having the fifth or sixth configuration described above, the voltage fed to the control electrode of the driving transistor while the switching transistor is on is constant.

By making the voltage constant, it is possible to obtain a square wave as the current waveform of the display element. This makes it possible to keep low the maximum value of the current (peak current) that flows through the display element.

Preferably, for example, in each pixel circuit having the fifth or sixth configuration described above, the operating point at which the driving transistor operates while the switching transistor is on is set within the linear region.

This is expected to further reduce current consumption. Moreover, by making sufficiently high the voltage fed to the control electrode of the driving transistor when the switching transistor turns on, it is possible to almost eliminate the influence of the variation of the operation threshold voltage of the driving transistor on the current value of the display element.

Preferably, for example, in the third, fourth, or sixth configuration described above, the pixels constituting the display panel are divided into a first pixel group and a second pixel group with periodicity in the vertical and/or the horizontal direction of the display panel. Moreover, during each frame period, the first and second fields are made to occur in different orders between in the first and second pixel groups.

This reduces fluctuation of brightness, and thus helps reduce flickering. It is also possible to keep low the maximum value of the current that flows through the display element.

Preferably, for example, in the third, fourth, or sixth configuration described above, during each frame period, the first and second fields occur simultaneously, and each pixel has two of the pixel circuit. Moreover, during each frame period, for each pixel, the feedback controller makes one pixel circuit operate in the first field and simultaneously makes the other pixel circuit operate in the second field, and in addition switches, every predetermined number of frames, between the two pixel circuits the pixel circuits that are made to operate in the first and second fields.

This enhances the dynamic characteristics of the display panel, and thus helps reduce flickering. Moreover, every predetermined number of frames, the pixel circuit operated in the first field and the pixel circuit operated in the second field are switched between the two pixel circuits. This helps keep uniform the speed of deterioration of the display element.

Preferably, for example, in the third, fourth, or sixth configuration described above, the active-matrix-driven display device further includes a supply voltage controller that controls the magnitude of the supply voltage for feeding electric power, in each pixel circuit, via the driving transistor to the display element, and the supply voltage controller makes the magnitude of the supply voltage lower in the second field than in the first field.

This helps further reduce power consumption.

Preferably, for example, in each pixel circuit having any of the first to sixth configurations described above, when the magnitude of the light emission start electrode-to-electrode voltage of the display element varies from a first voltage value to a second voltage value higher than the first voltage value, the effective value of the current that flows through the display element as corresponding to a given gradation signal increases.

With this configuration, it is possible to compensate for the lowering of brightness attributable to lowering of the light emission efficiency of the display element.

To achieve the above object, according to a seventh configuration of the present invention, in an active-matrix-driven display device including a display panel composed of a plurality of pixels arrayed in a matrix, the display panel is connected to a scan driver for feeding a scan voltage to each pixel and a data driver for feeding a data voltage to each pixel, and each pixel is built with a pixel circuit including: a display element that emits light when fed with electric power; a writing transistor that has the first electrode thereof connected to the data driver and that has the control electrode thereof connected to the scan driver; a driving transistor that drives, according to the voltage applied to the control electrode thereof, the display element; a first capacitive element that is provided in series with the line connecting the second electrode of the writing transistor to the control electrode of the driving transistor; and an adjustment transistor that turns on and off conduction between the writing-transistors-side electrode of the first capacitive element and the display element.

To achieve the above object, according to an eighth configuration of the present invention, in an active-matrix-driven display device including a display panel composed of a plurality of pixels arrayed in a matrix, the display panel is connected to a scan driver for feeding a scan voltage to each pixel and a data driver for feeding a data voltage to each pixel, and each pixel is built with a pixel circuit including: a display element that emits light when fed with electric power; a writing transistor that has the first electrode thereof connected to the data driver and that has the control electrode thereof connected to the scan driver; a driving transistor that drives, according to the voltage applied to the control electrode thereof, the display element; a switching transistor that has one conducting electrode thereof connected to the control electrode of the driving transistor; a first capacitive element that is provided in series with the line connecting the second electrode of the writing transistor to the control electrode of the switching transistor; and an adjustment transistor that turns on and off conduction between the writing-transistors-side electrode of the first capacitive element and the display element.

By giving an active-matrix-driven display device the seventh or eighth configuration described above, it is possible to obtain the various advantages mentioned above. Incidentally, a “conducting electrode” denotes, for example when the switching transistor is a MOS transistor, the drain or source electrode thereof.

### BRIEF DESCRIPTION OF THE DRAWINGS

FIG. 1 is a block diagram showing the overall configuration of the organic EL display device of a first embodiment of the present invention;

FIG. 2 is a diagram showing the circuit configuration of each pixel constituting the display panel shown in FIG. 1;

FIG. 3 is a diagram illustrating the operation of the organic EL display device of the first embodiment of the present invention;

FIG. 4 is a diagram illustrating the operating point of the driving transistor shown in FIG. 2;

FIG. 5 is a diagram showing the circuit configuration of each pixel in a second embodiment of the present invention;

FIG. 6 is a diagram illustrating the operation of the organic EL display device of the second embodiment of the present invention;

FIG. 7 is a diagram showing the circuit configuration of each pixel in a third embodiment of the present invention;

FIG. 8 is a diagram illustrating the operation of the organic EL display device of the third embodiment of the present invention;

FIG. 9 is a diagram showing the circuit configuration of each pixel in a fourth embodiment of the present invention;

FIG. 10 is a diagram illustrating the operation of the organic EL display device of the fourth embodiment of the present invention;

FIG. 11 is a diagram showing the circuit configuration of each pixel in a fifth embodiment of the present invention;

FIG. 12 is a diagram illustrating the operation of the organic EL display device of the fifth embodiment of the present invention;

FIG. 13 is a block diagram showing the overall configuration of the organic EL display device of a sixth embodiment of the present invention;

FIG. 14 is a diagram showing the circuit configuration of each pixel constituting the display panel shown in FIG. 13;

FIG. 15 is a diagram illustrating the operation of the organic EL display device of the sixth embodiment of the present invention;

FIG. 16 is a diagram showing the circuit configuration of each pixel constituting a conventional display panel;

FIG. 17 is a diagram illustrating the operation of the pixel shown in FIG. 16;

FIG. 18 is a diagram showing the characteristics of the organic EL display device and the driving transistor shown in FIG. 16;

FIG. 19 is a diagram illustrating the black level deterioration that may occur in some of the embodiments;

FIG. 20 is a block diagram showing the overall configuration of the organic EL display device of a seventh embodiment of the present invention;

FIG. 21 is a diagram showing the circuit configuration of each pixel in the seventh embodiment of the present invention;

FIG. 22 is a diagram illustrating the operation of the organic EL display device of the seventh embodiment of the present invention;

FIG. 23 is a diagram showing an example of the relationship between the level of gradation in each field and the effective value of the current I_{OLED}, as observed in the absence of time-related variation or the like;

FIG. 24 is a diagram showing the same relationship as the FIG. 23, as observed in the presence of time-related variation or the like;

FIG. 25 is a diagram showing another example of the relationship between the level of gradation in each field and the effective value of the current I_{OLED}, as observed in the absence of time-related variation or the like;

FIG. 26 is a diagram showing the same relationship as the FIG. 25, as observed in the presence of time-related variation or the like;

FIG. 27 is a diagram showing still another example of the relationship between the level of gradation and the effective value of the current I_{OLED};

FIG. 28 is a diagram showing the circuit configuration of each pixel in an eighth embodiment of the present invention;

FIG. 29 is a diagram illustrating the operation of the organic EL display device of the eighth embodiment of the present invention;

FIG. 30 is a diagram showing the circuit configuration of each pixel in a ninth embodiment of the present invention;

FIG. 31 is a diagram illustrating the operation of the organic EL display device of the ninth embodiment of the present invention;

FIG. 32 is a diagram showing the circuit configuration of each pixel in a tenth embodiment of the present invention;

FIG. 33 is a diagram illustrating the operation of the organic EL display device of the tenth embodiment of the present invention;

FIG. 34 is a diagram illustrating a modified example applicable to the first or second embodiment of the present invention;

FIG. 35 is a diagram showing the circuit configuration of each pixel in an eleventh embodiment of the present invention;

FIG. 36 is a diagram illustrating the operation of the organic EL display device of the eleventh embodiment of the present invention;

FIG. 37 is a block diagram showing the overall configuration of the organic EL display device of a twelfth embodiment of the present invention;

FIG. 38 is a diagram showing the circuit configuration of each pixel in the twelfth embodiment of the present invention;

FIG. 39 is a diagram illustrating the operation of the organic EL display device of the twelfth embodiment of the present invention;

FIG. 40 is a diagram illustrating the operation of the organic EL display device of a thirteenth embodiment of the present invention;

FIG. 41 is a diagram showing the circuit configuration of each pixel in a fourteenth embodiment of the present invention;

FIG. 42 is a diagram illustrating the operation of the organic EL display device of the fourteenth embodiment of the present invention;

FIG. 43 is a diagram illustrating the operating point of the driving transistor shown in FIG. 41;

FIG. 44 is a diagram showing the relationship between the data voltage and the current I_{OLED} in the configuration shown in FIG. 41;

FIG. 45 is a diagram showing the circuit configuration of each pixel in a fifteenth embodiment of the present invention;

FIG. 46 is a diagram illustrating the operation of the organic EL display device of the fifteenth embodiment of the present invention;

FIG. 47 is a diagram showing the configuration of the display panel of the organic EL display device of a sixteenth embodiment of the present invention;

FIG. 48 is a diagram showing part of the horizontal lines constituting the display panel shown in FIG. 47;

FIG. 49 is a diagram illustrating the operation in the sixteenth embodiment of the present invention;

FIG. 50 is a diagram showing an example of the arrangement of pixels in the display panel shown in FIG. 47;

FIG. 51 is a diagram showing one of the pixels of the organic EL display device of a seventeenth embodiment of the present invention, illustrating the pixel incorporating two pixel circuits;

FIG. 52 is a diagram showing the difference in operation between the two pixel circuits shown in FIG. 51;

FIG. 53 is a diagram showing an example of the arrangement of the two pixel circuits shown in FIG. 51; and

FIG. 54 is a diagram showing another example of the arrangement of the two pixel circuits shown in FIG. 51.

### DETAILED DESCRIPTION OF PREFERRED EMBODIMENTS

### First Embodiment

A first embodiment of the present invention as applied to an organic EL display device will be specifically described below with reference to the relevant drawings.

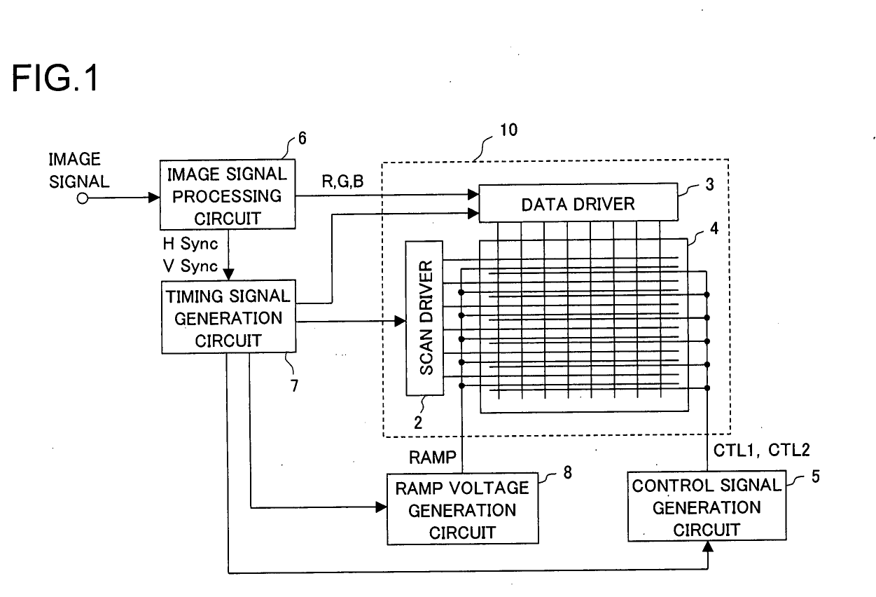

FIG. 1—Overall Configuration Block Diagram

FIG. 1 is a block diagram showing the overall configuration of the organic EL display device of a first embodiment of the present invention. As shown in FIG. 1, the organic EL display 10 has a display panel 4 composed of a plurality of pixels arrayed in a matrix, and this display panel 4 is connected to: a scan driver 2 that feeds a scan voltage to each pixel; a data driver 3 that feeds a data voltage to each pixel; a ramp voltage generation circuit 8; and a control signal generation circuit 5. The organic EL display device shown in FIG. 1 displays on the display panel 4 an image according to an image signal fed from an image source (external signal source) such as a television receiver (unillustrated).

The image signal fed from an image source such as a television receiver (unillustrated) is fed to an image signal processing circuit 6, where the image signal is subjected to necessary signal processing to produce image signals of three primary colors (RGB), namely red (R), green (G), and blue (B), which signals are then fed to the data driver 3 of the organic EL display 10.

The image signal processing circuit 6 also produces a horizontal synchronizing signal Hsync and a vertical synchronizing signal Vsync, which are fed to a timing signal generation circuit 7 to produce timing signals, which are then fed to the scan driver 2 and the data driver 3.

The timing signal produced by the timing signal generation circuit 7 is fed also to the ramp voltage generation circuit 8. Based on this timing signal, the ramp voltage generation circuit 8 produces a ramp voltage RAMP and feeds it to each pixel of the display panel 4. As will be described later, the ramp voltage RAMP is used to drive the organic EL display 10.

The timing signal produced by the timing signal generation circuit 7 is fed also to the control signal generation circuit 5. Based on this timing signal, the control signal generation circuit 5 produces control signals CTL1 and CTL2 and feeds them to each pixel of the display panel 4. As will be described later, the control signals CTL1 and CTL2 are used to drive the organic EL display 10. Although, in FIG. 1, the control signal lines extending from the control signal generation circuit 5 are illustrated as being provided one for each horizontal line, in reality, they are provided two (CTL1 and CTL2) for each horizontal line.

All the circuits, drivers, and organic EL display shown in FIG. 1 are connected to a power supply circuit (unillustrated).

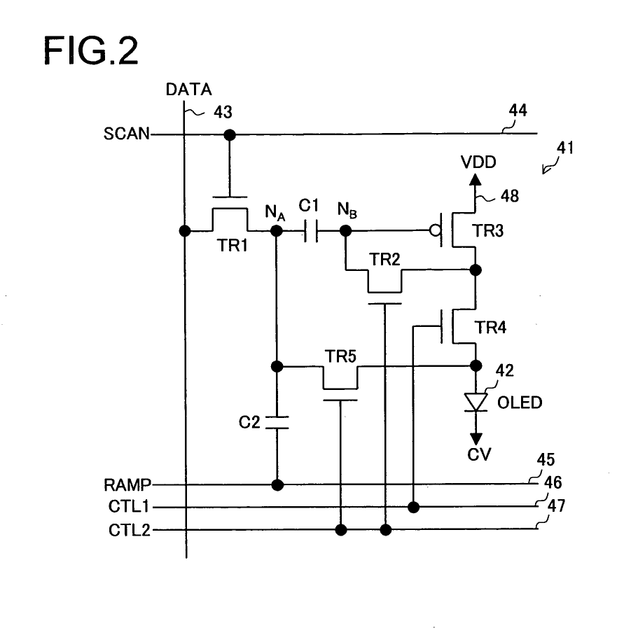

FIG. 2—Pixel Configuration

Next, the circuit configuration of each pixel 41 constituting the display panel 4 will be described with reference to FIG. 2. Each pixel is built with a pixel circuit including: an organic EL element (OLED) 42 that functions as a display element by emitting light when fed with electric power; a writing transistor TR1; a driving transistor TR3 that, according to the voltage applied to the gate (control electrode) thereof, drives the organic EL element 42; a threshold value compensation transistor TR2 that compensates for the variation in the operation threshold voltage (Vth) of the driving transistor TR3; an on/off transistor TR4 that is provided in series with a power supply line 48 extending from a power source from which to feed electric power to the organic EL element 42 and that serves to turn on an off the supply of electric power to the organic EL element 42; an adjustment transistor TR5 that adjusts brightness according to the variation in the light emission start electrode-to-electrode voltage of the organic EL element 42 (that is, the electrode-to-electrode voltage of the organic EL element 42 at the start of light emission); a capacitor Cl (first capacitive element); and a capacitor C2 (second capacitive element).

The writing transistor TR1, the threshold value compensation transistor TR2, the on/off transistor TR4, and the adjustment transistor TR5 are all N-channel MOS transistors formed as thin-film transistors (TFTs). The driving transistor TR3 is a P-channel MOS transistor formed as a thin-film transistor (TFT). Needless to say, possible modifications include one in which the N-channel MOS transistors are replaced with P-channel MOS transistors or the P-channel MOS transistor is replaced with an N-channel MOS transistor.

The first electrode (for example, source) of the writing transistor TR1 is connected to a data voltage line 43 to which a data voltage DATA is applied with predetermined timing. The second electrode (for example, drain) of the writing transistor TR1 is connected to one electrode of the capacitor C1. The gate of the writing transistor TR1 is connected to a scan voltage line 44 to which a scan voltage SCAN is applied. The first electrode (for example, source) of the threshold value compensation transistor TR2 is connected to the other electrode of the capacitor C1 and to the gate of the driving transistor TR3. The second electrode (for example, drain) of the threshold value compensation transistor TR2 is connected to the drain of the driving transistor TR3 and to the drain of the on/off transistor TR4. The gate of the threshold value compensation transistor TR2 is connected to a control signal line 47 to which a control signal CTL2 is applied.

The source of the on/off transistor TR4 is connected to the anode of the organic EL element 42. The gate of the on/off transistor TR4 is connected to a control signal line 46 to which a control signal CTL1 is applied. A negative-side supply voltage CV is applied to the cathode of the organic EL element 42, and a positive-side supply voltage VDD is applied to the source of the driving transistor TR3. The node between the capacitor C1 and the second electrode of the writing transistor TR1 will be referred to as the node N_{A}, and the node between the capacitor C1 and the gate of the driving transistor TR3 will be referred to as the node N_{B}.

The first electrode (for example, drain) of the adjustment transistor TR5 is connected to the anode of the organic EL element 42. The second electrode (for example, source) of the adjustment transistor TR5 is connected to the node N_{A}. The gate of the adjustment transistor TR5 is connected to the control signal line 47. One electrode of the capacitor C2 is connected to the node N_{A}. The other electrode of the capacitor C2 is connected to a ramp voltage line 45 to which a ramp voltage RAMP is applied.

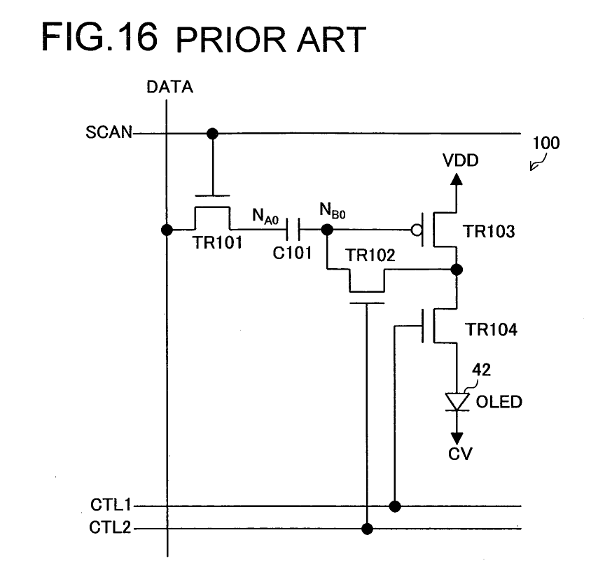

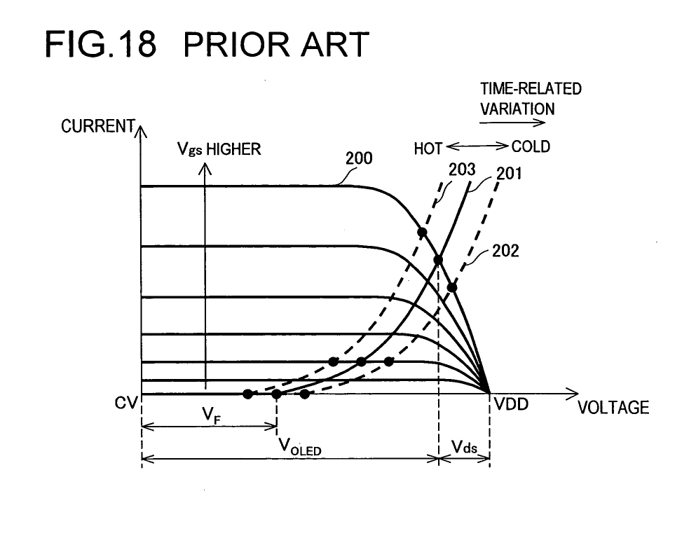

The driving transistor TR3 shown in FIG. 2 has characteristics similar to those of the driving transistor TR103 shown in FIG. 16, and therefore the characteristics of the driving transistor TR3 are similar to those described earlier with reference to FIG. 18. The organic EL element 42 shown in FIG. 2 is identical with the one shown in FIG. 16, and therefore has characteristic similar to those described earlier with reference to FIG. 18.

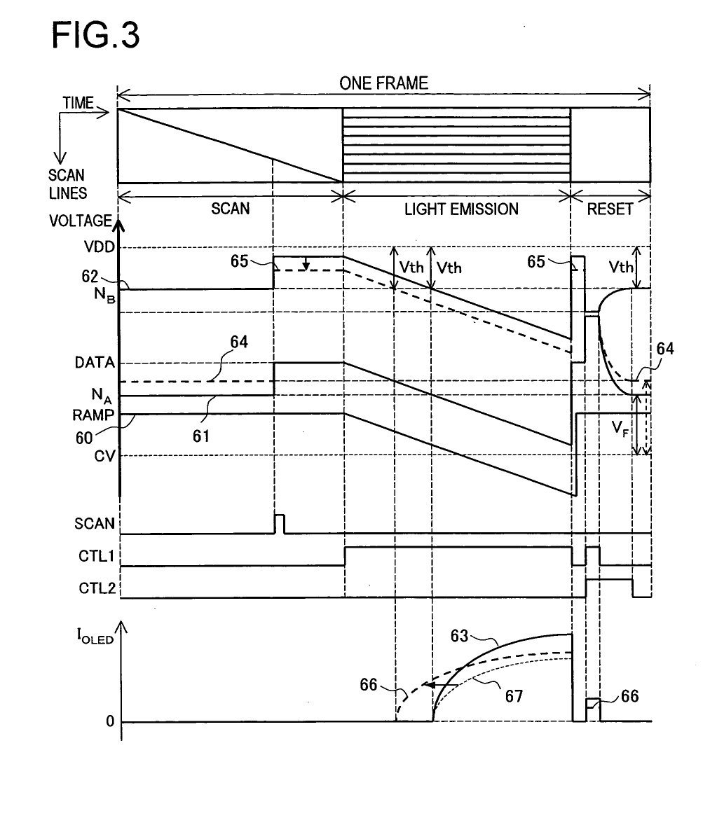

FIG. 3—Operation

Next, with reference to FIG. 3, the operation of the organic EL display device of the first embodiment will be described. FIG. 3 shows the voltages at relevant points in FIG. 2 and the current I_{OLED} through the organic EL element 42 as observed over one frame period.

As shown in FIG. 3, the period for the display of one screen, that is, one frame period (the reciprocal of the frame frequency), consists of a scan period, a light emission period, and a reset period. During the scan period, a high-level scan voltage SCAN is applied to one scan voltage line 44 after another so that a plurality of writing transistors TR1 connected to a given scan voltage line are tuned on at a time to permit data voltages DATA to be written to the corresponding pixels (of which each is like the pixel 41). During the light emission period, according to the data voltages DATA written during the scan period, the corresponding organic EL elements 42 are made to emit light. During the reset period, the variation in the operation threshold voltage (Vth) of the driving transistor TR3 and the variation in the light emission start electrode-to-electrode voltage V_{F} of the organic EL element 42 are compensated for. Since the reset period and/or the scan period are periods during which the organic EL element 42 is made ready to emit light during the light emission period, those periods can be collectively referred to as a light emission preparation period.

The scan period, the light emission period, and the reset period occur in this order, and, at the end of the kth (where k is a natural number) frame period, then subsequently the (k+1)th frame period begins, during the period of which the scan period, the light emission period, and the reset period occur in this order.

A solid line 60 represents the voltage waveform of the ramp voltage RAMP fed from the ramp voltage generation circuit 8 to the ramp voltage line 45. The ramp voltage RAMP remains fixed at a previously set initial voltage during the scan period, and then decreases monotonically at a previously set variation rate (for example, −1 V per millisecond) during the light emission period. Then, during the reset period, the ramp voltage RAMP stops decreasing monotonically and turns back to the initial voltage.

Solid lines 61 and 62 represent the voltage waveforms observed at the nodes N_{A} and N_{B}, respectively, when the V_{OLED}-I_{OLED} characteristic of the organic EL element 42 is as indicated by the solid line 201 in FIG. 18. A solid line 63 represents the waveform of the current I_{OLED} that flows through the organic EL element 42 when the V_{OLED}-I_{OLED} characteristic of the organic EL element 42 is as indicated by the solid line 201 in FIG. 18.

Broken lines 64 and 65 represent the voltage waveforms observed at the nodes N_{A} and N_{B}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66 represents the waveform of the current I_{OLED} that flows through the organic EL element 42 when the V_{OLED}-I_{OLED} characteristic of the organic EL element 42 has shifted as indicated by the broken line 202 in FIG. 18.

For easy understanding of the operation, the following description thereof starts with the reset period of the kth frame period.

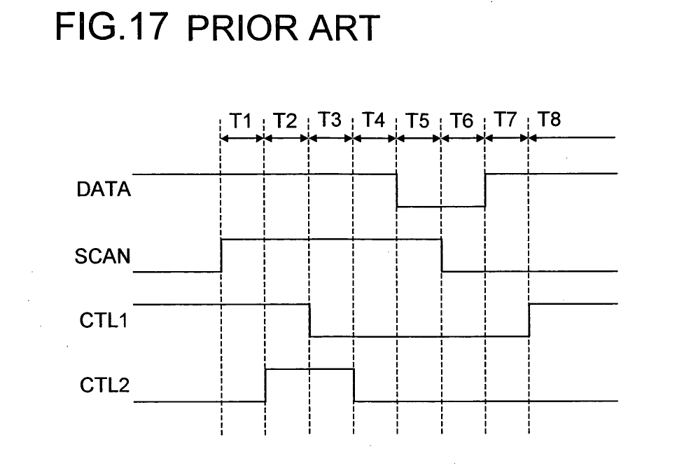

On completion of the kth light emission period (the light emission period in the kth frame period), the kth reset period (the reset period in the kth frame period) begins, during which the control signals CTL1 and CTL2, which both have thus far been low, are both turned high. This turns the threshold value compensation transistor TR2, the on/off transistor TR4, and the adjustment transistor TR5 on (brings them into a conducting state), so that the differential voltage (VDD−CV) between the supply voltages VDD and CV is distributed between the electrode-to-electrode voltage V_{OLED} of the organic EL element 42 and the drain-to-source Vds(=Vgs) of the driving transistor TR3 (see the period T2 in FIG. 17). Consequently, now, the voltage appearing at the nodes N_{A} and N_{B} are higher than the supply voltage CV by the voltage distributed as the anode-to-cathode voltage of the organic EL element 42. Moreover, now, a small current flows through the organic EL element 42.

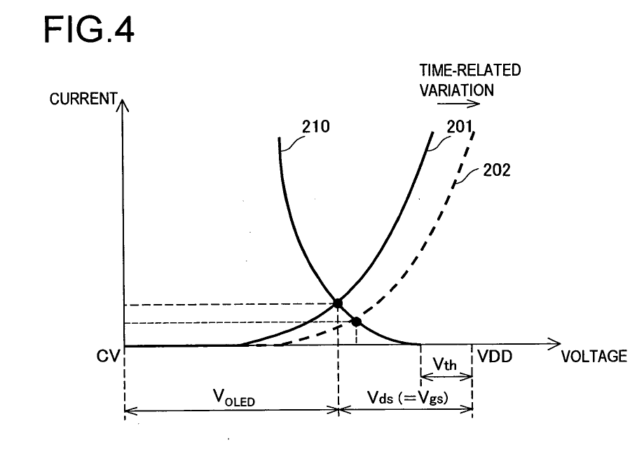

FIG. 4 shows how the voltage is distributed when the control signals CTL1 and CTL2 are both high. In FIG. 4, a solid line 201 and a broken line 202 are the same as those in FIG. 18. A solid line 210 represents the Vds-Id characteristic observed when Vds=Vgs in the driving transistor TR3. As shown in FIG. 4, when the control signals CTL1 and CTL2 are both high, the current I_{OLED}(=Id) decreases with the time-related variation.

Subsequently, from the state in which the control signals CTL1 and CTL2 are both high, only the control signal CTL1 turns low, and thus the on/off transistor TR4 turns off. Now, a current from the supply voltage VDD flows via the driving transistor TR3 and the threshold value compensation transistor TR2 into the node N_{B}, and thus the node N_{B} is charged up to the voltage lower than the supply voltage VDD by the operation threshold voltage (Vth) of the driving transistor TR3 (see the period T3 in FIG. 17). Moreover, now, a current flows from the node N_{A} via the adjustment transistor TR5 and the organic EL element 42 into the negative-side supply voltage CV. That is, part of the electric charge (positive electric charge) at the node N_{A}, which is now temporarily higher than the potential represented as (CV+V_{F}), is extracted via the adjustment transistor TR5 and the organic EL element 42, so that the voltage appearing at the node N_{A} stabilizes at a voltage higher than the supply voltage CV by the light emission start electrode-to-electrode voltage V_{F} of the organic EL element 42 (that is the electrode-to-electrode voltage V_{OLED} of the organic EL element at the start of light emission)

Then, when the potential at the nodes N_{A} and N_{B} has stabilized, the control signal CTL2 is turned low to turn the threshold value compensation transistor TR2 and the adjustment transistor TR5 off (bring them into a cut-off state). Now, the capacitor C1 holds a voltage (VDD−CV−Vth −V_{F}), that is, a voltage commensurate with the operation threshold voltage of the driving transistor TR3 and the light emission start electrode-to-electrode voltage V_{F} of the organic EL element 42. In the following description, the light emission start electrode-to-electrode voltage V_{F} is referred to also as the “voltage V_{F}”.

It should be noted that, during the reset period, both while a current is flowing into the organic EL element 42 and while the voltage appearing at the node N_{A} has stabilized at (CV+V_{F}), the voltage applied to the node N_{A} is a voltage higher than the supply voltage CV by the electrode-to-electrode voltage of the organic EL element 42 (in other words, a voltage commensurate with the electrode-to-electrode voltage of the organic EL element 42). Moreover, as will be understood from the V_{OLED}-I_{OLED} characteristic of the organic EL element 42 shown in FIG. 18, the voltage V_{F} as indicated by the broken line 64, that is, the voltage observed in the presence of a time-related variation or the like, is higher than the voltage V_{F} as indicated by the solid line 61.

Thereafter, while the control signals CTL1 and CTL2 are both let at low, the kth reset period ends, and subsequently the (k+1)th scan period (the scan period in the (k+1)th frame period) begins. It should be noted that, during the reset period, the scan voltage SCAN is kept low.

When the (k+1)th scan period begins, the potentials at the nodes N_{A} and N_{B} are kept at their respective potentials at the end of the kth reset period. Hence, (the voltage at the node N_{A} as indicated by the broken line 64)>(the voltage at the node N_{A} as indicated by the solid line 61). During the scan period, the control signals CTL1 and CTL2 are both kept low.

During the scan period, when a high-level scan voltage SCAN is applied to a pixel 41 of interest, the writing transistor TR1 turns on. Now, the voltage at the node N_{A} rises to become equal to the data voltage DATA applied to the data voltage line 43 (that is, the data voltage DATA is written), and correspondingly, through the coupling provided by the capacitor C1, the voltage at the node N_{B} rises by the same voltage. Here, the voltage by which the voltages at the nodes N_{A} and N_{B} rise equals (DATA−V_{F}−CV). Thus, the voltage at the node N_{B} (that is, the gate voltage of the driving transistor TR3) equals (VDD−CV+DATA−V_{F}−Vth), that is, a voltage commensurate with the data voltage DATA, the voltage V_{F}, and the operation threshold voltage Vth of the driving transistor TR3.

Here, since (the voltage V_{F} as indicated by the broken line 64)>(the voltage V_{F} as indicated by the solid line 61), once the data voltage DATA is written, the following relationship holds: (the voltage at the node N_{B} as indicated by the broken line 65)<(the voltage at the node N_{B} as indicated by the solid line 62).

After the data voltage DATA is written, the scan voltage SCAN applied to the pixel 41 of interest is turned back low. When data voltages are written to all the pixels 41 constituting the display panel 4, the scan period ends, and the light emission period begins.

During the light emission period, the control signal CTL1 is turned high, and thus the on/off transistor TR4 turns on. Moreover, during the light emission period, as described above, the ramp voltage RAMP decreases monotonically at a predetermined variation rate, and thus, through the coupling provided by the capacitors C2 and C1, the voltages appearing at the nodes N_{A} and N_{B} also each decrease monotonically at the same variation rate as the ramp voltage RAMP.

Then, when the voltage at the node N_{B} (the gate of the driving transistor TR3) becomes equal to or lower than the voltage (VDD−Vth), a current starts to flow through the organic EL element 42. Here, since, at the beginning of the light emission period, (the voltage at the node N_{B} as indicated by the broken line 65)<(the voltage at the node N_{B} as indicated by the solid line 62), light emission starts earlier in the case indicated by the broken line 65. Then, the current that has started to flow through the organic EL element 42 during the light emission period increases gradually. At the end of the light emission period, the control signal CTL1 is turned low so that the organic EL element 42 stops emitting light, and now the (k+1)th reset period begins.

If, as in the conventional configuration, the variation in the voltage V_{F} attributable to a time-related variation or the like in the organic EL element 42 is not fed back at all, the time-related variation or the like causes the current I_{OLED}, which should be as indicated by the solid line 63, to diminish as indicated by the broken line 67, resulting in significantly lower brightness for a given data voltage DATA. In this embodiment, however, as described above, the voltage at the node N_{B} (that is, the gate voltage of the driving transistor TR3) at the beginning of the light emission period equals (VDD−CV+DATA−V_{F}−Vth), and thus, even when a time-related variation or the like is present, the current I_{OLED} behaves as indicated by the broken line 66 so that the loss therein (the loss in brightness) is compensated for. Needless to say, thanks to the use of the voltage program driving method, the brightness of the organic EL element 42 is not influenced by a variation in the operation threshold voltage (Vth) of the driving transistor TR3.

In other words, in this embodiment, when the voltage V_{F} is higher than a reference voltage (the light emission start electrode-to-electrode voltage in the solid line 201 in FIG. 18), the period for which the organic EL element 42 emits light is extended. On the other hand, when the voltage V_{F} is lower than the reference voltage (the light emission start electrode-to-electrode voltage in the solid line 201 in FIG. 18), the period for which the organic EL element 42 emits light is shortened.

Thereafter, during the (k+1)th reset period, the ramp voltage RAMP is turned back to the initial voltage (that is, it rises). Correspondingly, the voltage appearing at the nodes N_{A} and N_{B} each rise. Then, the control signals CTL1 and CTL2 and both turned high, and the sequence of operations described above is repeated. In this way, basically, gradation is modulated by the light emission duration of the organic EL element 42 that varies according to the data voltage DATA.

Moreover, as described above, in the first embodiment, the reset period includes a period during which the control signal CTL1 turns high to make the organic EL element 42 emit light. This period is reserved for making the potential at the node N_{A} higher than (V_{F}+CV) and the potential at the node N_{B} lower than (VDD−Vth), and can be set sufficiently short (for example, 1 microsecond) relative to the essential light emission period (for example, 10 milliseconds) of the organic EL element 42. Thus, this light emission during the reset period does not much influence display quality, but may be eliminated, if so desired, by a method discussed in connection with the second embodiment described later.

### Second Embodiment

A second embodiment of the present invention as applied to an organic EL display device will be described below. The overall configuration of the organic EL display device of the second embodiment of the present invention is substantially the same as that shown in FIG. 1; therefore, no separate diagram is furnished in that aspect, and the following description places emphasis on differences from the first embodiment.

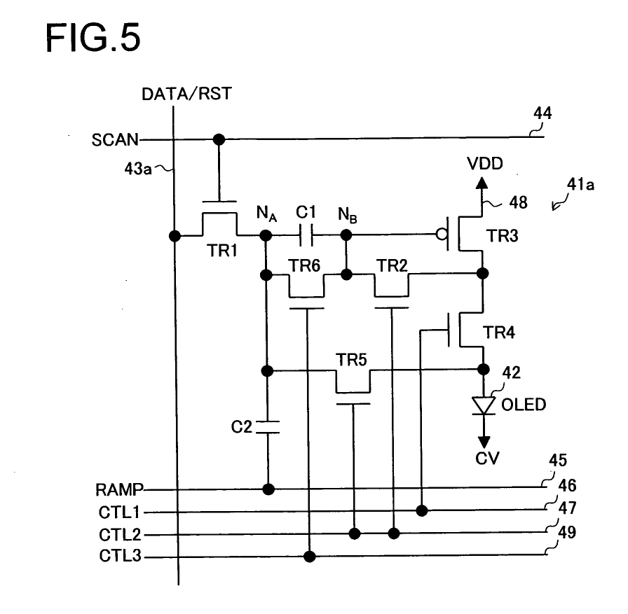

The display panel 4 is so modified that each pixel 41a constituting it is configured as shown in FIG. 5. In FIG. 5, such elements as are found also in FIG. 2 are identified with common reference numerals and symbols, and no overlapping explanations will be repeated. The pixel 41a (the pixel circuit of the pixel 41a) differs from the pixel 41 (the pixel circuit of the pixel 41) shown in FIG. 2 in the following respects: a resetting transistor TR6 is additionally provided of which the first electrode (for example, drain) and the second electrode (for example, source) are connected to the nodes N_{A} and N_{B}, respectively, and of which the gate is connected to a control signal line 49 to which a control signal CTL3 is applied from the control signal generation circuit 5; the first electrode of the writing transistor TR1 is connected to a data voltage line 43a to which a data voltage DATA from the data driver 3 is applied during the scan period and to which a reset voltage RST (this reset voltage RST has a previously set voltage) is applied during the reset period. These differences are achieved as a result of the data driver 3 and the control signal generation circuit 5 being configured differently from in the first embodiment.

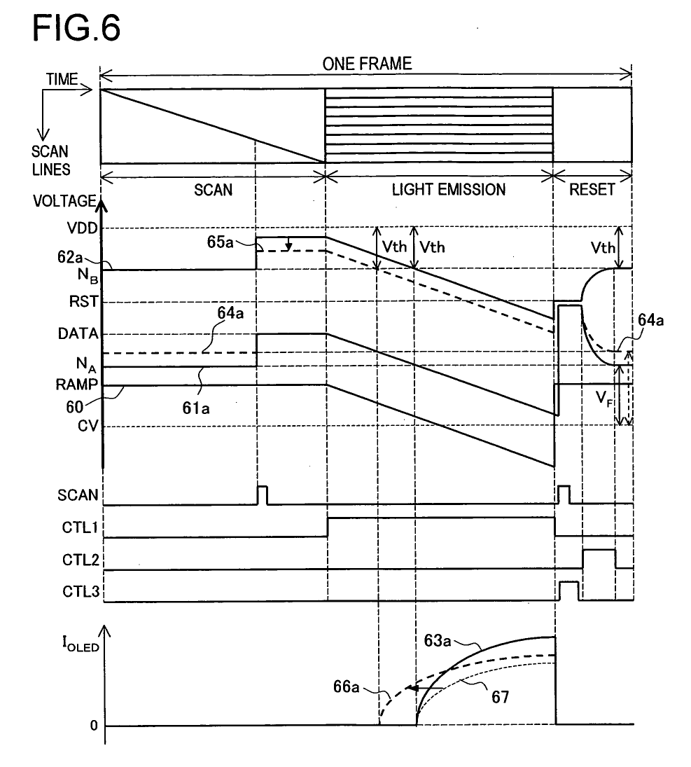

FIG. 6 shows the voltages at relevant points in FIG. 5 and the current I_{OLED} through the organic EL element 42 as observed over one frame period. In FIG. 6, such elements as are found also in FIG. 3 are identified with common reference numerals and symbols, and no overlapping explanations will be repeated.

Solid lines 61a and 62a represent the voltage waveforms observed at the nodes N_{A} and N_{B}, respectively, when the V_{OLED}-I_{OLED} characteristic of the organic EL element 42 is as indicated by the solid line 201 in FIG. 18. A solid line 63a represents the waveform of the current I_{OLED} that flows through the organic EL element 42 when the V_{OLED}-I_{OLED} characteristic of the organic EL element 42 is as indicated by the solid line 201 in FIG. 18.

Broken lines 64a and 65a represent the voltage waveforms observed at the nodes N_{A} and N_{B}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66a represents the waveform of the current I_{OLED} that flows through the organic EL element 42 when the V_{OLED}-I_{OLED} characteristic of the organic EL element 42 has shifted as indicated by the broken line 202 in FIG. 18.

The operations performed during the scan period and the light emission period in FIG. 6 are similar to those performed in FIG. 3; therefore, no explanations thereof will be repeated, and the following description concentrates on the reset period, which proceeds in a manner unique to the second embodiment.

On completion of the light emission period, the reset period begins, during which a high-level scan voltage SCAN is fed to the gate of the writing transistor TR1 to turn it on and simultaneously a high-level control signal CTL3 is fed to the gate of the resetting transistor TR6 to turn it on. Meanwhile, the data driver 3 keeps applying the reset voltage RST to the data voltage line 43a (FIG. 5), and thus the reset voltage RST is applied to both the nodes N_{A} and N_{B}.

The potential of this reset voltage RST is higher than (CV+V_{F}) but lower than (VDD−Vth). Thus, when the scan voltage SCAN and the control signal CTL3 are both turned low, and then the control signal CTL2 is turned from low to high, the threshold value compensation transistor TR2 and the adjustment transistor TR5 turn on. A predetermined period thereafter, the node N_{A} stabilizes at the voltage (CV+V_{F}), and the node N_{B} stabilizes at the voltage (VDD−Vth). The operations performed after the stabilization of the voltages there are similar to those performed in the first embodiment.

As will be understood from the description above, in the second embodiment, during the reset period, the on/off transistor TR4 is not turned on, and thus the organic EL element 42 does not emit light. This helps realize further enhanced display quality. Needless to say, the same advantages as achieved in the first embodiment are achieved also here.

### Third Embodiment

A third embodiment of the present invention as applied to an organic EL display device will be described below. The overall configuration of the organic EL display device of the third embodiment of the present invention is substantially the same as that shown in FIG. 1; therefore, no separate diagram is furnished in that aspect, and the following description places emphasis on differences from the first embodiment.

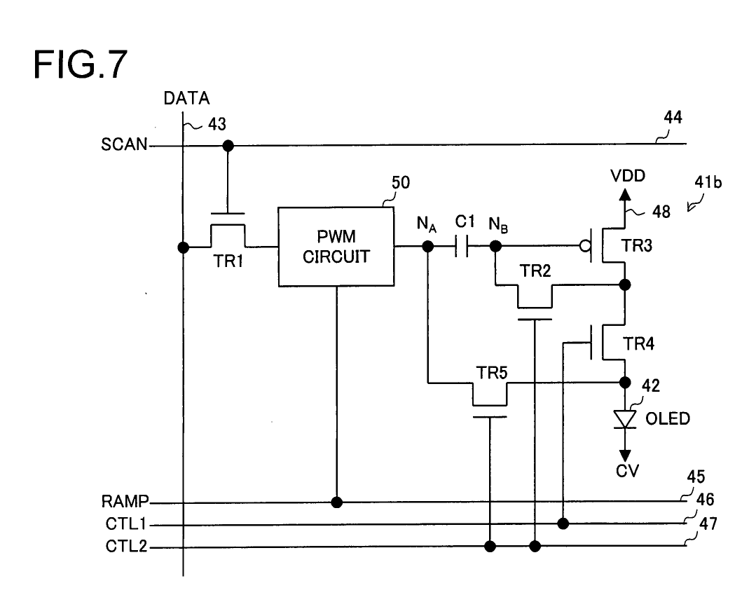

The display panel 4 is so modified that each pixel 41b constituting it is configured as shown in FIG. 7. In FIG. 7, such elements as are found also in FIG. 2 are identified with common reference numerals and symbols, and no overlapping explanations will be repeated. The pixel 41b (the pixel circuit of the pixel 41b) differs from the pixel 41 (the pixel circuit of the pixel 41) shown in FIG. 2 in the following respects: a PWM circuit (pulse width modulation circuit) 50 is provided between the second electrode of the writing transistor TR1 and the node N_{A}; the ramp voltage RAMP is fed not to the capacitor C2 (see FIG. 2) but to the PWM circuit 50. Thus, the capacitor C1 is located in series with the line connecting the output side (node N_{A}) of the PWM circuit 50 to the gate of the driving transistor TR3.

The PWM circuit 50 produces a pulse voltage by performing pulse width modulation on the data voltage DATA fed from the data driver 3 while the writing transistor TR1 is on, and feeds the pulse voltage to the node N_{A} during the light emission period. The PWM circuit 50 is built with, for example, a comparator (unillustrated) whose non-inverting input terminal (+), inverting input terminal (−), and output terminal are connected to the second electrode of the writing transistor TR1, to the ramp voltage line 45, and to the node N_{A}, respectively.

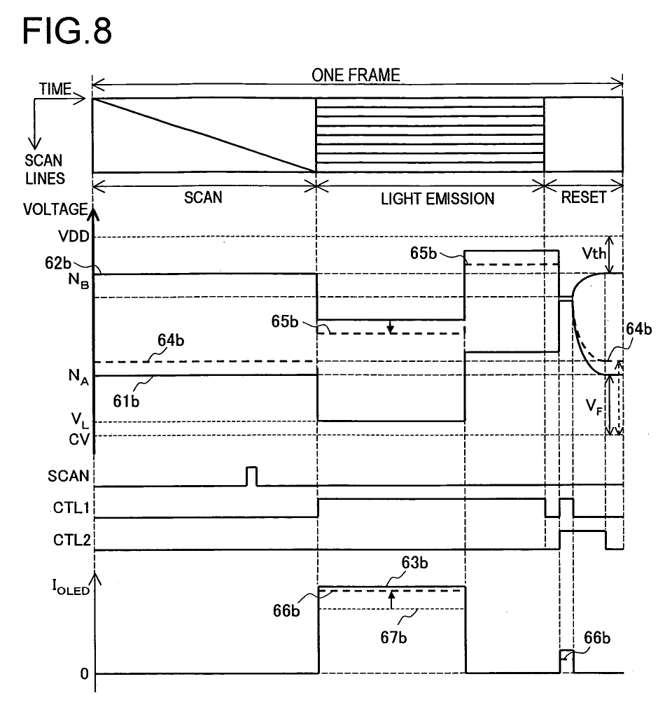

FIG. 8 shows the voltages at relevant points in FIG. 7 and the current I_{OLED} through the organic EL element 42 as observed over one frame period. In FIG. 8, such elements as are found also in FIG. 3 are identified with common reference numerals and symbols, and no overlapping explanations will be repeated. In FIG. 8, the voltage waveform of the ramp voltage RAMP is omitted from illustration.

Solid lines 61b and 62b represent the voltage waveforms observed at the nodes N_{A} and N_{B}, respectively, when the V_{OLED}-I_{OLED} characteristic of the organic EL element 42 is as indicated by the solid line 201 in FIG. 18. A solid line 63b represents the waveform of the current I_{OLED} that flows through the organic EL element 42 when the V_{OLED}-I_{OLED} characteristic of the organic EL element 42 is as indicated by the solid line 201 in FIG. 18.

Broken lines 64b and 65b represent the voltage waveforms observed at the nodes N_{A} and N_{B}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66a represents the waveform of the current I_{OLED} that flows through the organic EL element 42 when the V_{OLED}-I_{OLED} characteristic of the organic EL element 42 has shifted as indicated by the broken line 202 in FIG. 18.

The operations performed during the reset period in FIG. 8 are similar to those performed in FIG. 3; therefore, no explanations thereof will be repeated. During the scan period, the control signals CTL1 and CTL2 are both kept low. During the light emission period, the control signal CTL1 is kept high, and the control signal CTL2 is kept low.

During the scan period, when a high-level scan voltage SCAN is applied to a pixel 41b of interest, the writing transistor TR1 turns on, and the data voltage DATA is fed to the PWM circuit 50. When the light emission period begins, the control signal CTL1 turns high, and, during the light emission period, the PWM circuit 50 outputs a predetermined light emission level voltage V_{L} for a period commensurate with the data voltage DATA (for a period proportional to the magnitude of the data voltage DATA) that has been fed thereto during the scan period.

While this light emission level voltage V_{L} is being outputted, the driving transistor TR3 turns on to make the organic EL element 42 emit light. Thus, by varying the data voltage DATA, it is possible to achieve display with multiple levels of gradation. Needless to say, the length of the period for which the PWM circuit 50 outputs the light emission level voltage V_{L} can vary from one pixel to another.

When the light emission level voltage V_{L} starts to be outputted, the voltage at the node N_{A} becomes lower by the voltage (CV+V_{F}−V_{L}), and correspondingly, through the coupling provided by the capacitor C1, the voltage at the node N_{B} becomes lower by the same voltage. As a result, the voltage at the node N_{B} (that is, the gate voltage of the driving transistor TR3) is commensurate with the voltage (VDD−CV+V_{L}−V_{F}−Vth), that is, commensurate with the light emission level voltage V_{L}, the light emission start electrode-to-electrode voltage V_{F} of the organic EL element 42, and the operation threshold voltage Vth of the driving transistor TR3.

Here, since, as described above, (the voltage V_{F} as indicated by the broken line 64b)>(the voltage V_{F} as indicated by the solid line 61b), while the PWM circuit 50 is outputting the light emission level voltage V_{L} during the light emission period, that is, while the organic EL element 42 is emitting light, the following relationship holds: (the voltage at the node N_{B} as indicated by the broken line 65b)<(the voltage at the node N_{B} as indicated by the solid line 62b). Thus, the gate-to-source voltage of the driving transistor TR3 is higher in the case where a time-related variation is present (the case indicated by the broken line 65b).

If, as in the conventional configuration, the variation in the voltage V_{F} attributable to a time-related variation or the like in the organic EL element 42 is not fed back at all, the time-related variation or the like causes the current I_{OLED}, which should be as indicated by the solid line 63b, to diminish as indicated by the broken line 67b, resulting in significantly lower brightness for a given data voltage DATA. In this embodiment, however, as described above, the voltage at the node N_{B} (that is, the gate voltage of the driving transistor TR3) at the beginning of the light emission period equals (VDD−CV+V_{L}−Vth−V_{F}), and thus, even when a time-related variation or the like is present, the current I_{OLED} behaves as indicated by the broken line 66b so that the loss therein (the loss in brightness) is compensated for.

In other words, in this embodiment, when the voltage V_{F} is higher than a reference voltage (the light emission start electrode-to-electrode voltage in the solid line 201 in FIG. 18), the gate voltage of the driving transistor TR3 is so adjusted that the magnitude of the current that flows through the organic EL element 42 increases. On the other hand, when the voltage V_{F} is lower than the reference voltage, the gate voltage of the driving transistor TR3 is so adjusted that the magnitude of the current that flows through the organic EL element 42 decreases. This adjustment is performed on a frame-by-frame basis.

Needless to say, thanks to the use of the voltage program driving method, the brightness of the organic EL element 42 is not influenced by a variation in the operation threshold voltage (Vth) of the driving transistor TR3.

In the first embodiment, when a time-related variation or the like is present, regardless of the level of gradation (that is, regardless of whether the level of gradation is black, white, or somewhere in between), the period for which the organic EL element 42 is made to emit light is extended (or shortened) by an equal length of time. That is, to put in an exaggerated (though incorrect) way, the loss in brightness is compensated for by increasing the brightness to an equal degree at all levels of gradation (as if achieved through brightness adjustment). This is true also in the second embodiment.

By contrast, in the third embodiment, the length of time for which the organic EL element 42 emits light during the light emission period depends solely on the data voltage DATA, and therefore the loss in brightness is compensated for by increasing the magnitude of current during light emission. For example, consider a case where, in the absence of a time-related variation or the like, the effective values of the current I_{OLED} corresponding to a first level of gradation (white), a second level of gradation (middle), and a third level of gradation (black) are 10, 5, and 0, respectively (the peak value corresponds to the solid line 63b). Moreover, assume that, if a time-related variation appears, and if the loss in brightness attributable thereto is not compensated for, the effective values of the current I_{OLED} corresponding to the first, second, and third levels of gradation will be 6, 3, and 0, respectively (the peak value corresponds to the solid line 67b).

By contrast, if the loss in brightness is compensated for as in this embodiment, the effective values of the current I_{OLED} corresponding to the first, second, and third levels of gradation will be 9(=6×1.5), 4.5(=3×1.5), and 0(=0×1.5), respectively; that is, while the current is greatly increased for the white level of gradation, not altogether or very little for the black level of gradation. This means that the loss in brightness is compensated for in such a way that as much contrast as possible is retained between different levels of gradation. This helps further reduce deterioration of display quality attributable to a time-related variation or the like than in the first and second embodiments.

The PWM circuit 50, after outputting the light emission level voltage V_{L} for a period commensurate with the data voltage DATA fed thereto, then raise the output voltage thereof to a predetermined voltage. This predetermined voltage is so set that the rise thereto causes the voltage at the node N_{B} to become higher than (VDD−Vth). Thus, at the same time that the light emission level voltage V_{L} stops being outputted, the organic EL element 42 stops emitting light.

### Fourth Embodiment

Next, a fourth embodiment of the present invention will be described to present a practical configuration of the PWM circuit 50 introduced in the third embodiment. The overall configuration of the organic EL display device of the fourth embodiment is substantially the same as that shown in FIG. 1; therefore, no separate diagram is furnished in that aspect, and the following description places emphasis on differences from the first embodiment.

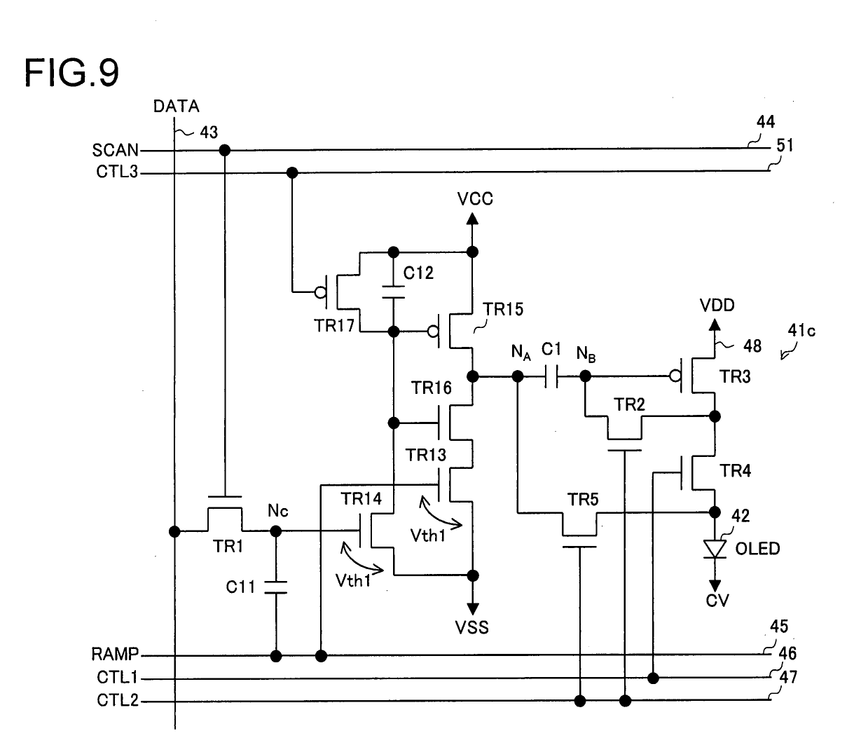

The display panel 4 is so modified that each pixel 41c constituting it is configured as shown in FIG. 9. In FIG. 9, such elements as are found also in FIG. 2 are identified with common reference numerals and symbols, and no overlapping explanations will be repeated.

The PWM circuit 50 is composed of: a turning-on transistor TR13, a turning-off transistor TR14, and a transistor TR16, all built as N-channel MOS transistors; transistors TR15 and TR17 built as P-channel MOS transistors; and capacitors C11 and C12.

The gate of the transistor TR17 is connected to a control signal line 51 to which a control signal CTL3 from the control signal generation circuit 5 is applied. The source of the transistor TR17 is connected to one electrode of the capacitor C12 and to the source of the transistor TR15. The drain of the transistor TR17 is connected to the other electrode of the capacitor C12, to the gate of the transistor TR15, to the gate of the transistor TR16, and to the drain of the turning-off transistor TR14. The drains of the transistors TR15 and TR16 are connected together to serve as the output end of the PWM circuit 50, via which it outputs a pulse voltage to the node N_{A}. The source of the transistor TR16 is connected to the drain of the turning-on transistor TR13. One electrode of the capacitor C11 and the gate of the turning-on transistor TR13 are both connected to the ramp voltage line 45. The other electrode of the capacitor C11 is connected to the second electrode of the writing transistor TR1 and to the gate of the turning-off transistor TR14.

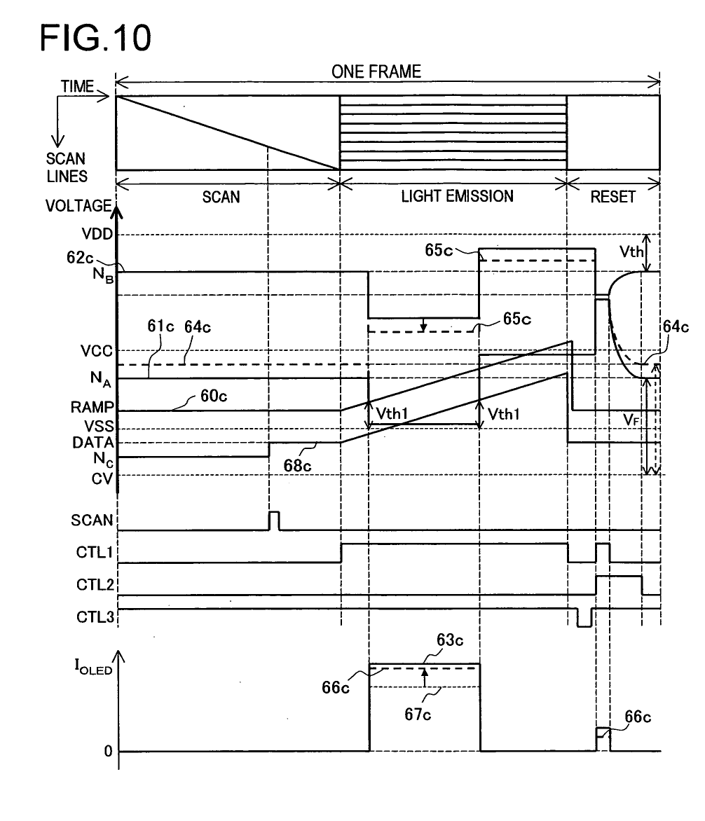

A positive-side supply voltage VCC for the PWM circuit 50 is supplied to the source of the transistor TR17, to one electrode of the capacitor C12, and to the source of the transistor TR15. A negative-side supply voltage VSS for the PWM circuit 50 is supplied to the source of the turning-on transistor TR13 and to the source of the turning-off transistor TR14. The purpose of using, as the positive-side supply voltage for the PWM circuit 50, a voltage VCC different from VDD is simply to avoid complicating the later-described operations shown in FIG. 10. Instead, the supply voltage VDD itself may be used as the supply voltage for the PWM circuit 50. The control signal generation circuit 5 is so modified, as compared with in the first embodiment, as to feed each pixel with, in addition to the control signals CTL1 and CTL2, a control signal CTL3.

The turning-on and turning-off transistors TR13 and TR14 are formed simultaneously on a single semiconductor substrate by a single process, and are formed close together within a single pixel 41c. Thus, the operation threshold voltages (Vth1) of the turning-on and turning-off transistors TR13 and TR14 are approximately equal. The node between the second electrode of the writing transistor TR1 and the gate of the turning-off transistor TR14 will be referred to as the node N_{C}.

FIG. 10 shows the voltages at relevant points in FIG. 9 and the current I_{OLED} through the organic EL element 42 as observed over one frame period. In FIG. 10, such elements as are found also in FIG. 3 are identified with common reference numerals and symbols, and no overlapping explanations will be repeated.

A solid line 60c represents the voltage waveform of the ramp voltage RAMP fed from the ramp voltage generation circuit 8 to the ramp voltage line 45. The ramp voltage RAMP remains fixed at a previously set initial voltage during the scan period, and then increases monotonically at a previously set variation rate (for example, 1 V per millisecond) during the light emission period. Then, during the reset period, the ramp voltage RAMP stops increasing monotonically and turns back to the initial voltage. The ramp voltage generation circuit 8 is modified as described above as compared with in the first embodiment.

Solid lines 61c and 62c represent the voltage waveforms observed at the nodes N_{A} and N_{B}, respectively, when the V_{OLED}-I_{OLED} characteristic of the organic EL element 42 is as indicated by the solid line 201 in FIG. 18. A solid line 63c represents the waveform of the current I_{OLED} that flows through the organic EL element 42 when the V_{OLED}-I_{OLED} characteristic of the organic EL element 42 is as indicated by the solid line 201 in FIG. 18. A solid line 68c represents the voltage waveform at the node N_{C}.

Broken lines 64c and 65c represent the voltage waveforms observed at the nodes N_{A} and N_{B}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66c represents the waveform of the current I_{OLED} that flows through the organic EL element 42 when the V_{OLED}-I_{OLED} characteristic of the organic EL element 42 has shifted as indicated by the broken line 202 in FIG. 18.

First, in the kth reset period, the control signal CTL3 turns from high to low, and thus turns the transistor TR17 on. This turns the transistor TR15 off. At the moment, the other transistors TR13, TR14, and TR16 are all off.

Then, the control signal CTL3 is turned back high, and the operations performed thereafter are similar to those performed in the first embodiment. Specifically, the control signal CTL1 and 2 are turned from low to high, so that the potential at the node N_{A} becomes higher than (V_{F}+CV) and the potential at the node N_{B} becomes lower than (VDD−Vth). Then, the control signal CTL1 is turned low, and then the control signal CTL2 is turned low in this order as in the first embodiment. Thus, as in the first embodiment, at the end of the reset period, a voltage (VDD−CV−Vth−V_{F}) is held in the capacitor C1.

Then, while the control signals CTL1 and CTL2 are both kept low, the kth reset period ends, and subsequently the (k+1)th scan period begins. Incidentally, the scan voltage SCAN is kept low during the reset period, and the control signal CTL3 is kept high during the scan period and the light emission period.

When the (k+1)th scan period begins, the potentials at the nodes N_{A} and N_{B} are kept at their respective potentials at the end of the kth reset period. Hence, (the voltage at the node N_{A} as indicated by the broken line 64c)>(the voltage at the node N_{A} as indicated by the solid line 61c). During the scan period, the control signals CTL1 and CTL2 are both kept low. During the light emission period, the control signal CTL1 remains high, and the control signal CTL2 remains low.

During the scan period, when a high-level scan voltage SCAN is applied to a pixel 41c of interest, the writing transistor TR1 turns on. Thus, a data voltage DATA fed from the data driver 3 is held in the capacitor C11 with reference to the above-mentioned initial voltage of the ramp voltage.

When the scan period ends, the light emission period begins, during which the ramp voltage RAMP increases and thus its difference from the negative-side supply voltage VSS increases. When the gate-to-source voltage of the turning-on transistor TR13 becomes higher than the operation threshold voltage Vth1, the turning-on transistor TR13 turns on. This brings the transistor TR16 into a conducting state, and thus causes the voltage at the node N_{A} to fall to become equal to the supply voltage VSS, and correspondingly the voltage at the node N_{B} falls by the same voltage (for the sake of simplicity, here, the voltage drops across the transistor TR16 and the turning-on transistor TR13 are ignored). Now, the driving transistor TR3 conducts, and thus the organic EL element 42 starts to emit light.

Here, the voltage by which the voltages at the nodes N_{A} and N_{B} fall equals (−VSS+V_{F}+CV). Thus, the voltage at the node N_{B} (that is, the gate voltage of the driving transistor TR3) equals (VDD−CV+VSS−V_{F}−Vth), that is, a voltage commensurate with the voltage VSS (light emission level voltage), the light emission start electrode-to-electrode voltage V_{F} of the organic EL element 42, and the operation threshold voltage Vth of the driving transistor TR3.

Here, since (the voltage V_{F} as indicated by the broken line 64c)>(the voltage V_{F} as indicated by the solid line 61c), while the PWM circuit 50 is keeping the voltage at the node N_{A} equal to the voltage VSS (light emission level voltage) during the light emission period, that is, while the organic EL element 42 is emitting light, the following relationship holds: (the voltage at the node N_{B} as indicated by the broken line 65c)<(the voltage at the node N_{B} as indicated by the solid line 62c). Thus, the gate-to-source voltage of the driving transistor TR3 is higher in the case where a time-related variation is present (the case indicated by the broken line 65c).

Thereafter, the ramp voltage further increases, and correspondingly the voltage at the node N_{C} increases, causing its difference from the negative-side supply voltage VSS to increase. When the gate-to-source voltage of the turning-off transistor TR14 becomes higher than the operation threshold voltage Vth1, the turning-off transistor TR14 turns on. This turns the transistor TR16 off, and turns the transistor TR15 on, causing the voltage at the node N_{A} to rise to become equal to the supply voltage VCC (for the sake of simplicity, here, the voltage drop across the transistor TR15 is ignored). Correspondingly, the voltage at the node N_{B} becomes higher than the voltage (VDD−Vth). This turns the driving transistor TR3 off, and thus causes the organic EL element 42 to stop emitting light.

As described above, according to the magnitude of the data voltage, the time point at which the organic EL element 42 stops emitting light varies. Thus, the light emission duration varies in proportion to the magnitude of the data voltage. This achieves display with multiple levels of gradation. Incidentally, the PWM circuit 50 can be said to perform pulse width modulation on the data voltage DATA by using the ramp voltage RAMP to output, during the light emission period, the voltage VSS (light emission level voltage) for a period corresponding to the width of the pulse resulting from the pulse width modulation thus performed.

While the PWM circuit 50 keeps the voltage at the node N_{A} equal to the voltage VSS (light emission level voltage) during the light emission period, that is, while the organic EL element 42 is emitting light, (the voltage at the node N_{B} as indicated by the broken line 65c)<(the voltage at the node N_{B} as indicated by the solid line 62c). Hence, the gate-to-source voltage of the driving transistor TR3 is higher in the case where a time-related variation or the like is present (the case indicated by the broken line 65c). Thus, the same advantages as achieved in the third embodiment (among others, the advantage that loss in brightness is compensated for while as much contrast as possible is retained between different levels of gradation) are achieved. (If, as in the conventional configuration, the variation in the voltage V_{F} attributable to a time-related variation or the like in the organic EL element 42 is not fed back at all, the time-related variation or the like causes the current I_{OLED}, which should be as indicated by the solid line 63c, to diminish as indicated by the broken line 67c, resulting in significantly lower brightness for a given data voltage DATA.)

In other words, in this embodiment, when the voltage V_{F} is higher than a reference voltage (the light emission start electrode-to-electrode voltage in the solid line 201 in FIG. 18), the gate voltage of the driving transistor TR3 is so adjusted that the magnitude of the current that flows through the organic EL element 42 increases. On the other hand, when the voltage V_{F} is lower than the reference voltage, the gate voltage of the driving transistor TR3 is so adjusted that the magnitude of the current that flows through the organic EL element 42 decreases. This adjustment is performed on a frame-by-frame basis.

Moreover, thanks to the use of the voltage program driving method, the brightness of the organic EL element 42 is not influenced by a variation in the operation threshold voltage (Vth) of the driving transistor TR3.

Moreover, the turning-on and turning-off transistors TR13 and TR14 are formed simultaneously on a single semiconductor substrate by a single process, and are formed close together within a single pixel 41c. Hence, the operation threshold voltages (Vth1) of the turning-on and turning-off transistors TR13 and TR14 are approximately equal. Thus, even if a fabrication-associated variation causes to deviate the time point at which the turning-on transistor TR13 turns the driving transistor TR3 on, it also causes to deviate, by the same length of time and in the same direction, the time point at which the turning-off transistor TR14 later turns the driving transistor TR3 off.

Thus, regardless of variations in the operation threshold voltages of the transistors TR13 and TR14, the length of time after the turning-on transistor TR13 turns the driving transistor TR3 on until the turning-off transistor TR14 turns the driving transistor TR3 off remains accurately commensurate with the data voltage.

Moreover, throughout one frame period, at least one of the transistors TR15 and TR16 is always off. This prevents unnecessary flow of current from the supply voltage VCC to the supply voltage VSS.

In the fourth embodiment, the reset period includes a period during which the control signal CTL1 turns high to make the organic EL element 42 emit light. This period is reserved for making the potential at the node N_{A} higher than (V_{F}+CV) and the potential at the node N_{B} lower than (VDD−Vth), and can be set sufficiently short (for example, 1 microsecond) relative to the essential light emission period (for example, 10 milliseconds) of the organic EL element 42. Thus, this light emission during the reset period does not much influence display quality, but may be eliminated, if so desired, by a method discussed in connection with the fifth embodiment described later.

### Fifth Embodiment

A fifth embodiment of the present invention as applied to an organic EL display device will be described below. The overall configuration of the organic EL display device of the fifth embodiment of the present invention is substantially the same as that shown in FIG. 1; therefore, no separate diagram is furnished in that aspect. The organic EL display device of the fifth embodiment is similar to that of the fourth embodiment, and therefore the following description places emphasis on differences from the fourth embodiment. That is, unless specifically described, the configuration and operation of the organic EL display device of the fifth embodiment are the same as in the fourth embodiment.

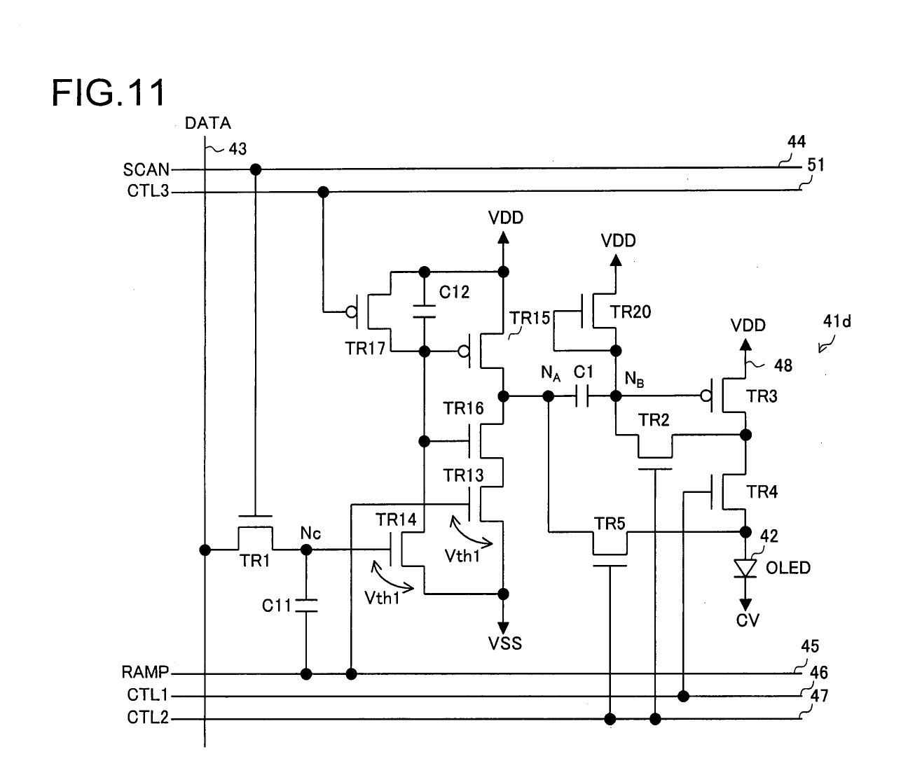

The display panel 4 is so modified that each pixel 41d constituting it is configured as shown in FIG. 11. In FIG. 11, such elements as are found also in FIG. 9 are identified with common reference numerals and symbols, and no overlapping explanations will be repeated. The pixel 41d (the pixel circuit of the pixel 41d) differs from the pixel 41c (the pixel circuit of the pixel 41c) shown in FIG. 9 in the following respects: a clipping transistor TR20 (clipping circuit) that receives the supply voltage VDD at the source thereof and of which the drain and gate are connected together and then connected to the node N_{B}; the supply voltage VDD is supplied to the source of the transistor TR17, to one electrode of the capacitor C12, and to the source of the transistor TR15.

Let the operation threshold voltage of the clipping transistor TR20 be Vth2. Then, the clipping transistor TR20 can be said to function to prevent the potential at the node N_{B} from becoming higher than (VDD+Vth2). This potential (VDD+Vth2) will hereinafter be referred to as the clip potential. Needless to say, the clipping transistor TR20 may be replaced with a diode; depending on a modification made to the circuit configuration of the pixel 41d, the clipping transistor TR20 may be so modified as to prevent the potential at the node N_{B} from becoming lower than the clip potential (in such a case, the clip potential may be different from VDD+Vth2).

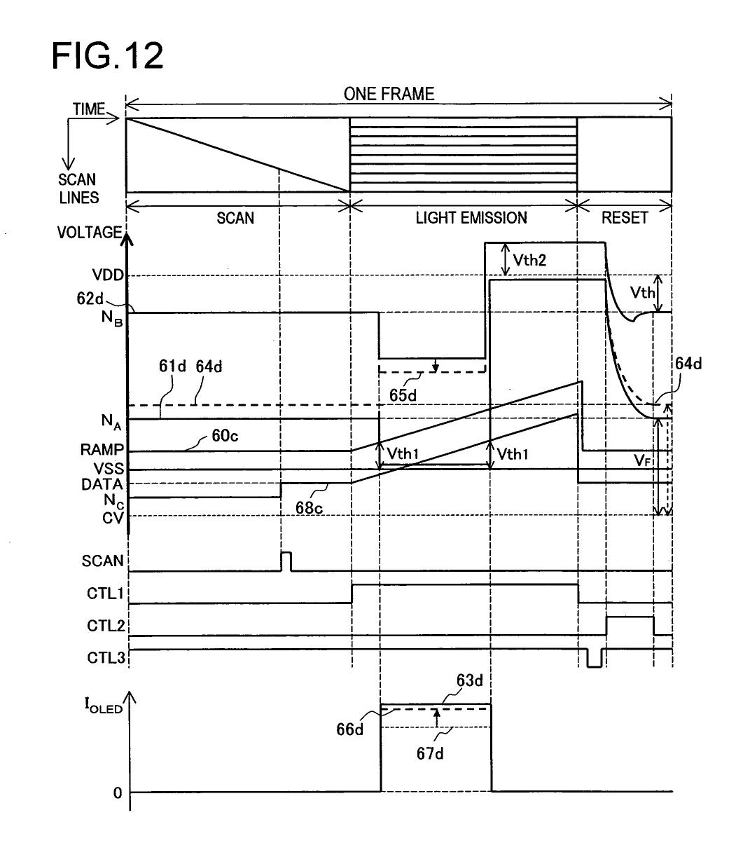

FIG. 12 shows the voltages at relevant points in FIG. 11 and the current I_{OLED} through the organic EL element 42 as observed over one frame period. In FIG. 12, such elements as are found also in FIGS. 3 and 10 are identified with common reference numerals and symbols, and no overlapping explanations will be repeated.

Solid lines 61d and 62d represent the voltage waveforms observed at the nodes N_{A} and N_{B}, respectively, when the V_{OLED}-I_{OLED} characteristic of the organic EL element 42 is as indicated by the solid line 201 in FIG. 18. A solid line 63d represents the waveform of the current I_{OLED} that flows through the organic EL element 42 when the V_{OLED}-I_{OLED} characteristic of the organic EL element 42 is as indicated by the solid line 201 in FIG. 18.

Broken lines 64d and 65d represent the voltage waveforms observed at the nodes N_{A} and N_{B}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66d represents the waveform of the current I_{OLED} that flows through the organic EL element 42 when the V_{OLED}-I_{OLED} characteristic of the organic EL element 42 has shifted as indicated by the broken line 202 in FIG. 18.

The voltage waveforms of the ramp voltage 60c, the scan voltage SCAN, and the control signals CTL2 and CTL3 shown in FIG. 12 are similar to those show in FIG. 10, and the operations performed in the scan period and the light emission period in FIG. 12 are similar to those performed in FIG. 10. In this embodiment, the control signal CTL1 does not turn high during the reset period. This differs from in the fourth embodiment, and constitutes a feature unique to this embodiment.

During the light emission period, the potential at node N_{C} becomes higher than (VSS+Vth1), then the turning-off transistor TR14 turns on, then the transistor TR15 turns on, and thus the potential at the node N_{A} rises from VSS to VDD. Now, through the coupling provided by the capacitor C1, the potential at the node N_{B} is ready to rise by the same voltage (VDD−VSS).

If the clipping transistor TR20 is not provided, the potential at the node N_{B} will actually rise by the voltage (VDD−VSS). In that case, during the reset period, when the control signal CTL2 is turned high to turn the adjustment transistor TR5 on, the potential at the node N_{B} does decrease as the potential at the node N_{A} decreases, but, because of the loss in the capacitor C1 and other factors, stops decreasing at a potential higher than (VDD−Vth). This prevents the voltage held in the capacitor C1 at the end of the reset period from becoming equal to (VDD−CV−Vth−V_{F}). That is, the capacitor C1 does not hold a voltage commensurate with the operation threshold voltage Vth of the driving transistor TR3. This means that the voltage program driving method does not function correctly (the brightness of he organic EL element 42 is influenced by a variation in the operation threshold voltage (Vth) of the driving transistor TR3).

In reality, however, in the pixel 41d shown in FIG. 11, thanks to the provision of the clipping transistor TR20 described above, even when the potential at the node N_{A} rises from VSS to VDD, the potential at the node N_{B} does not become higher than (VDD+Vth2); strictly speaking, it becomes temporarily higher than but eventually equal to (VDD+Vth2) when the reset period begins. Thus, during the reset period, when the control signal CTL2 is turned high to turn the adjustment transistor TR5 on, as the potential at the node N_{A} decreases, correspondingly the potential at the node N_{B} decreases until about to become lower than (VDD+Vth2). As soon as the potential at the node N_{B} becomes lower than (VDD+Vth2), however, the driving transistor TR3 turns temporarily on to permit a current to flow from the supply voltage VDD via the driving transistor TR3 and the threshold value compensation transistor TR2 into the node N_{B}. Thus, eventually (at the end of the reset period), the potential at the node N_{B} stabilizes at (VDD−Vth).

Through the operations described above, at the end of the reset period, the voltage held in the capacitor C1 equals (VDD−CV−Vth−V_{F}). Thus, the same advantages as achieved in the fourth embodiment are achieved also here. (If, as in the conventional configuration, the variation in the voltage V_{F} attributable to a time-related variation or the like in the organic EL element 42 is not fed back at all, the time-related variation or the like causes the current I_{OLED}, which should be as indicated by the solid line 63d, to diminish as indicated by the broken line 67d, resulting in significantly lower brightness for a given data voltage DATA.)

Moreover, during the reset period, the on/off transistor TR4 is not turned on, and thus the organic EL element 42 does not emit light (there is no need to make it emit light). This helps realize further enhanced display quality.

### Sixth Embodiment

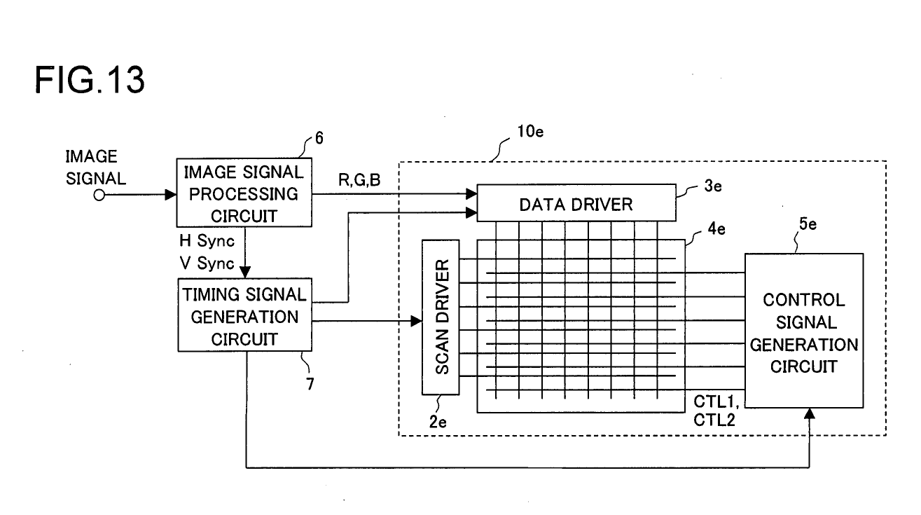

A sixth embodiment of the present invention as applied to an organic EL display device will be described below. FIG. 13 is a block diagram showing the overall configuration of the organic EL display device of the sixth embodiment of the present invention.

As shown in FIG. 13, the organic EL display 10e has a display panel 4e composed of a plurality of pixels arrayed in a matrix, and this display panel 4e is connected to: a scan driver 2e that feeds a scan voltage to each pixel; a data driver 3e that feeds a data voltage to each pixel; and a control signal generation circuit 5e. The organic EL display device shown in FIG. 13 displays on the display panel 4e an image according to an image signal fed from an image source (external signal source) such as a television receiver (unillustrated).

The image signal fed from an image source such as a television receiver (unillustrated) is fed to an image signal processing circuit 6, where the image signal is subjected to necessary signal processing to produce image signals of three primary colors (RGB), namely red (R), green (G), and blue (B), which signals are then fed to the data driver 3e of the organic EL display 10e.

The image signal processing circuit 6 also produces a horizontal synchronizing signal Hsync and a vertical synchronizing signal Vsync, which are fed to a timing signal generation circuit 7 to produce timing signals, which are then fed to the scan driver 2e and the data driver 3e.

The timing signal produced by the timing signal generation circuit 7 is fed also to the control signal generation circuit 5e. Based on this timing signal, the control signal generation circuit 5e produces control signals CTL1 and CTL2 and feeds them to each pixel of the display panel 4e. As will be described later, the control signals CTL1 and CTL2 are used to drive the organic EL display 10e. Although, in FIG. 13, the control signal lines extending from the control signal generation circuit 5e are illustrated as being provided one for each horizontal line, in reality, they are provided two (CTL1 and CTL2) for each horizontal line.

All the circuits, drivers, and organic EL display shown in FIG. 13 are connected to a power supply circuit (unillustrated).

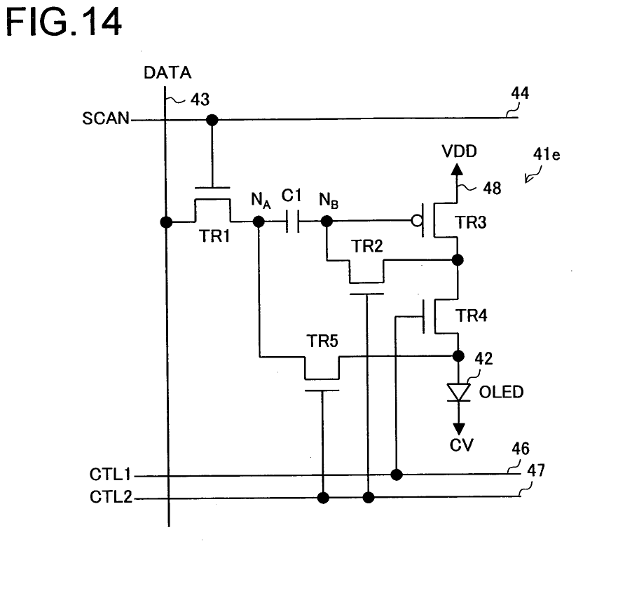

In the display panel 4e, each pixel 41e constituting it is built with a pixel circuit configured as shown in FIG. 14. In FIG. 14, such elements as are found also in FIG. 2 are identified with common reference numerals and symbols, and no overlapping explanations will be repeated. The pixel 41e (the pixel circuit of the pixel 41e) shown in FIG. 14 differs from the pixel 41 (the pixel circuit of the pixel 41) shown in FIG. 2 in that, as compared with the latter, the former lacks the capacitor C2 and the ramp voltage line 45 (see FIG. 2), and are otherwise identical.

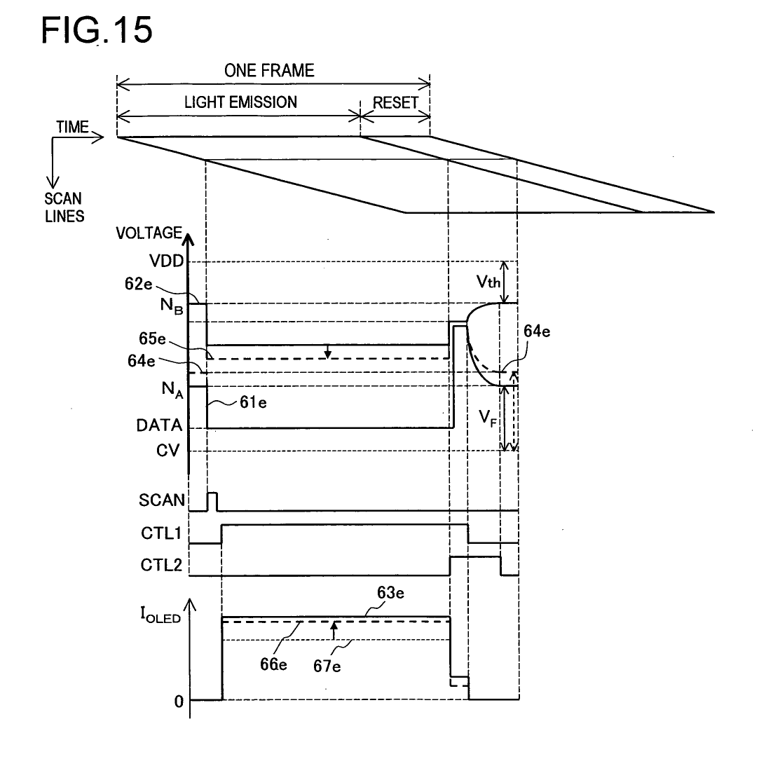

FIG. 15 shows the voltages at relevant points in FIG. 14 and the current I_{OLED} through the organic EL element 42 as observed over one frame period.

As shown in FIG. 15, the period for the display of one screen, that is, one frame period (the reciprocal of the frame frequency), consists of a light emission period and a reset period. Each one frame period begins and ends with different timing from one scan line to the next; that is, the beginning and end of one frame period occur first for the first scan line, then for the second scan line, . . . , and then for the nth scan line (where n represents the number of scan lines), with a predetermined time interval secured in between. FIG. 15 shows, for a given scan line of interest among the total of n scan lines, the voltage at relevant points in FIG. 14 etc.

For a given scan line, the light emission period and the reset period occur in this order and, at the end of the kth (where k is a natural number) frame period, then subsequently the (k+1)th frame period begins, during the period of which the light emission period and the reset period occur in this order. Thus, superficially, this embodiment appears to involve no scan period. In substance, however, as will be made clear in the following description, at the beginning of the light emission period, a scan voltage SCAN is turned high to write a data voltage DATA to a pixel. Thus, this embodiment can also be considered to have a scan period incorporated into the light emission period. This scan period may be separated from the light emission period as in the first to fifth embodiments so that the scan period, the light emission period, and the reset period occurs with identical timing for all the scan lines.

Solid lines 61e and 62e represent the voltage waveforms observed at the nodes N_{A} and N_{B}, respectively, when the V_{OLED}-I_{OLED} characteristic of the organic EL element 42 is as indicated by the solid line 201 in FIG. 18. A solid line 63e represents the waveform of the current I_{OLED} that flows through the organic EL element 42 when the V_{OLED}-I_{OLED} characteristic of the organic EL element 42 is as indicated by the solid line 201 in FIG. 18.

Broken lines 64e and 65e represent the voltage waveforms observed at the nodes N_{A} and N_{B}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66e represents the waveform of the current I_{OLED} that flows through the organic EL element 42 when the V_{OLED}-I_{OLED} characteristic of the organic EL element 42 has shifted as indicated by the broken line 202 in FIG. 18.

The operations performed in the kth reset period are basically similar to those performed in the first embodiment. First, the control signals CTL1 and CTL2 are both turned high, then only the control signal CTL1 is turned low, and then, after the potentials at the nodes N_{A} and N_{B} have stabilized at (CV+V_{F}) and (VDD−Vth), respectively, the control signal CTL2 is turned low. Through these operations, as in the first embodiment, at the end of the reset period, a voltage (VDD−CV−Vth−V_{F}) is held in the capacitor C1.

Thereafter, while the control signals CTL1 and CTL2 are both kept low, the kth reset period ends, and subsequently the (k+1)th light emission period begins. Incidentally, during the reset period, the scan voltage SCAN is kept low.

At the start of the (k+1)th light emission period, the scan voltage SCAN is turned high to turn the writing transistor TR1 on. At the moment, a data voltage DATA from the data driver 3e is being applied to the data voltage line 43, and therefore the voltage at the node N_{A} now falls to become equal to the data voltage DATA. Correspondingly, through the coupling provided by the capacitor C1, the voltage at the node N_{B} falls by the same voltage. Here, the voltage by which the voltages at the nodes N_{A} and N_{B} fall equals −(DATA−V_{F}−CV), and this voltage fall makes the voltage at the node N_{B} (that is, the gate voltage of the driving transistor TR3) equal to (VDD−CV+DATA−V_{F}−Vth).

After the data voltage DATA is written to the node N_{A}, the scan voltage SCAN is turned low, and then the control signal CTL1 is turned high, so that the organic EL element 42 starts to emit light. Here, since (the voltage V_{F} as indicated by the broken line 64e)>(the voltage V_{F} as indicated by the solid line 61e), once the data voltage DATA is written, the following relationship holds: (the voltage at the node N_{B} as indicated by the broken line 65e)<(the voltage at the node N_{B} as indicated by the solid line 62e). That is, the gate-to-source voltage of the driving transistor TR3 is higher in the case where a time-related variation is present (the case indicated by the broken line 65e).

If, as in the conventional configuration, the variation in the voltage V_{F} attributable to a time-related variation or the like in the organic EL element 42 is not fed back at all, the time-related variation or the like causes the current I_{OLED}, which should be as indicated by the solid line 63e, to diminish as indicated by the broken line 67e, resulting in significantly lower brightness for a given data voltage DATA. In this embodiment, however, as described above, the voltage at the node N_{B} (that is, the gate voltage of the driving transistor TR3) at the beginning of the light emission period equals (VDD−CV+DATA−Vth−V_{F}), and thus, even when a time-related variation or the like is present, the current I_{OLED} behaves as indicated by the broken line 66e so that the loss therein (the loss in brightness) is compensated for.

In other words, in this embodiment, when the voltage V_{F} is higher than a reference voltage (the light emission start electrode-to-electrode voltage in the solid line 201 in FIG. 18), the gate voltage of the driving transistor TR3 is so adjusted that the magnitude of the current that flows through the organic EL element 42 increases. On the other hand, when the voltage V_{F} is lower than the reference voltage, the gate voltage of the driving transistor TR3 is so adjusted that the magnitude of the current that flows through the organic EL element 42 decreases. This adjustment is performed on a frame-by-frame basis.

Needless to say, thanks to the use of the voltage program driving method, the brightness of the organic EL element 42 is not influenced by a variation in the operation threshold voltage (Vth) of the driving transistor TR3.

Although, in the first and second embodiments, the ramp voltage monotonically decreases during the light emission period, the configurations may be modified so that they monotonically increase instead. Likewise, although, in the fourth and fifth embodiment, the ramp voltage monotonically increases during the light emission period, the configurations may be modified so that they monotonically decrease instead. The ramp voltage may be given a curvature to conform to a specific gamma characteristic.

### Seventh Embodiment

In the embodiments described thus far, the loss in the current I_{OLED} attributable to a time-related variation or the like is compensated for. In the first, second, and sixth embodiments, however, the compensation may lead to black level deterioration.

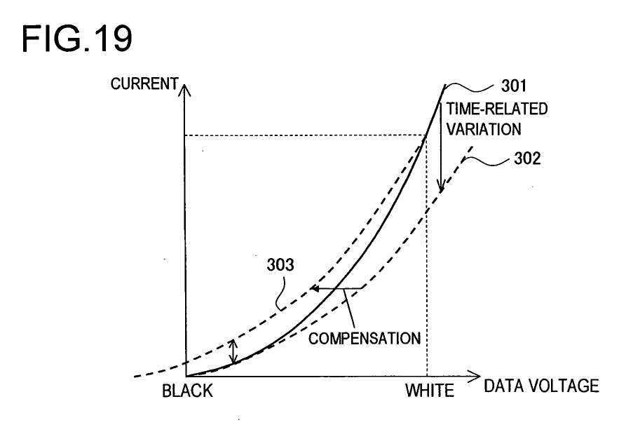

FIG. 19 is a diagram illustrating how black level deterioration occurs. In FIG. 19, the horizontal axis represents the data voltage DATA fed from the data driver 3 or 3e (FIG. 1 or 13), and the vertical axis represents the current I_{OLED} that flows to correspond to the data voltage DATA thus fed. Along the horizontal axis, going leftward means moving toward the black level of gradation, and going rightward means moving toward the white level of gradation. A solid line 301 represents the relationship between the data voltage DATA and the current I_{OLED} in the initial state. A broken line 302 represents the relationship between the data voltage DATA and the current I_{OLED} as observed when the V_{OLED}-I_{OLED} characteristic of the organic EL element 42 has shifted as indicated by the broken line 202 in FIG. 18 but nevertheless the loss in the current I_{OLED} is not compensated for in the previously described manner. A broken line 303 represents the relationship between the data voltage DATA and the current I_{OLED} as observed when, in the latter case, the loss in the current I_{OLED} is compensated for.

Letting the voltage at the node N_{B} vary according to the increase in the voltage V_{F} is equivalent to adding (or subtracting) the increase in the voltage V_{F} to (or from) the data voltage DATA. Thus, in the first, second, and sixth embodiments, when, because of a time-related variation or the like, the relationship between the data voltage DATA and the current I_{OLED} has shifted from as indicated by the solid line 301 to as indicated by the broken line 302, it is compensated as indicated by the broken line 303.

Thanks to the compensation, even if a time-related variation or the like is present, when a data voltage DATA corresponding to the white level of gradation is written to a pixel, a current I_{OLED} corresponding to the white level of gradation flows therethrough so as to alleviate the loss of brightness. However, when a data voltage DATA corresponding to the black level of gradation is written to a pixel, exactly because of the same compensation, a current I_{OLED} higher than in the initial state flows therethrough. That is, when black needs to be displayed, a higher-than-adequate current I_{OLED} flows, resulting in so-called black level deterioration.

Hereinafter, as examples of configurations free from such black level deterioration, a seventh to a fifteenth embodiment of the present invention will be presented. First, a seventh embodiment of the present invention as applied to an organic EL display device will be described below.

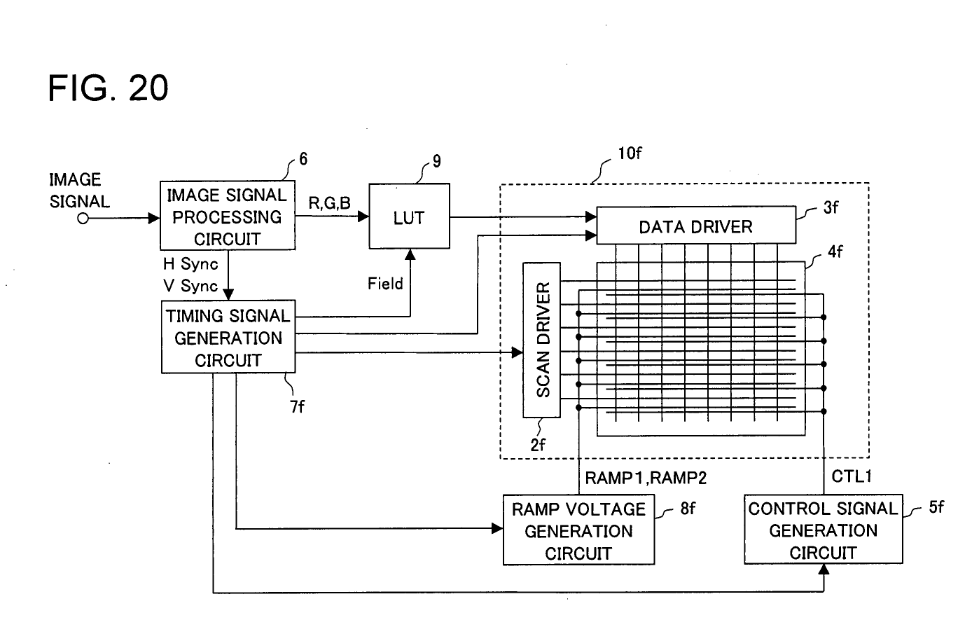

FIG. 20—Overall Block Diagram

FIG. 20 is a block diagram showing the overall configuration of the organic EL display device of a seventh embodiment of the present invention. As shown in FIG. 20, the organic EL display 10f has a display panel 4f composed of a plurality of pixels arrayed in a matrix, and this display panel 4f is connected to: a scan driver 2f that feeds a scan voltage to each pixel; a data driver 3f that feeds a data voltage to each pixel; a ramp voltage generation circuit 8f; and a control signal generation circuit 5f. The organic EL display device shown in FIG. 20 displays on the display panel 4f an image according to an image signal fed from an image source (external signal source) such as a television receiver (unillustrated).

The image signal fed from an image source such as a television receiver (unillustrated) is fed to an image signal processing circuit 6, where the image signal is subjected to necessary signal processing to produce image signals of three primary colors (RGB), namely red (R), green (G), and blue (B), which signals are then fed via a look-up table (hereinafter the “LUT”) 9 to the data driver 3f of the organic EL display 10f.

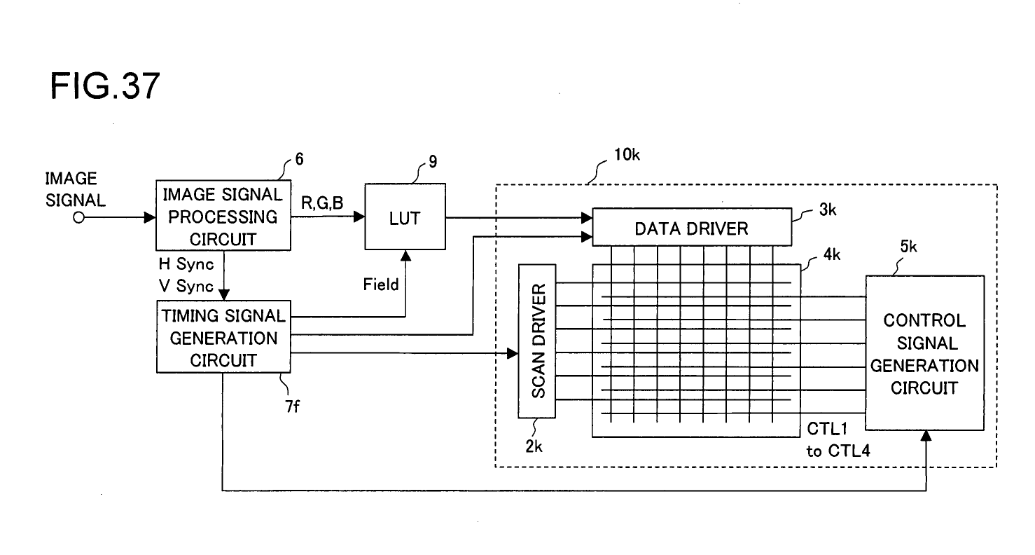

The image signal fed from an image source such as a television receiver (unillustrated) contains a gradation signal for image display on the display panel (the display panel 4f in FIG. 20, the display panel 4 in FIG. 1, the display panel 4e in FIG. 13, or the later-described display panel 4k in FIG. 37), and thus the image signals of three primary colors (RGB) outputted from the image signal processing circuit 6 contains the gradation signal.

The gradation signal specifies specific levels of gradation to be expressed at the individual pixels of the display panel (4f, 4, 4e, or 4k). When the gradation signal is configured as digital data consisting of a plurality of bits (for example, 10 bits), it can express gradation in multiple steps. The higher the level of the gradation signal outputted from the image signal processing circuit 6 (or the above-mentioned image source), the higher the corresponding level of gradation, and thus the higher the brightness at the corresponding pixel. The lowest level of the gradation signal outputted from the image signal processing circuit 6 (or the above-mentioned image source) corresponds to the black level of gradation with the lowest lightness, and the highest level of the gradation signal outputted from the image signal processing circuit 6 corresponds to the white level of gradation with the highest lightness. The above-described “relationship between the image signal, the gradation signal, the level of gradation, the brightness at the individual pixels, etc.” applies not only to this embodiment but to all the embodiments described in the present specification.

The image signal processing circuit 6 also produces a horizontal synchronizing signal Hsync and a vertical synchronizing signal Vsync, which are fed to a timing signal generation circuit 7f to produce timing signals, which are then fed to the scan driver 2f and the data driver 3f. In addition, a field signal coordinated with those timing signals is fed to an LUT 9. This field signal identifies whether the current field is a first or a second field. What a first and a second field denote will be described later.

The timing signal produced by the timing signal generation circuit 7f is fed also to the ramp voltage generation circuit 8f. Based on this timing signal, the ramp voltage generation circuit 8f produces ramp voltages RAMP1 and RAMP2 and feeds them to each pixel of the display panel 4f. As will be described later, the ramp voltages RAMP1 and RAMP2 are used to drive the organic EL display 10f.

The timing signal produced by the timing signal generation circuit 7f is fed also to the control signal generation circuit 5f. Based on this timing signal, the control signal generation circuit 5f produces a control signal CTL1 and feeds it to each pixel of the display panel 4f. As will be described later, the control signal CTL1 is used to drive the organic EL display 10f.

All the circuits, drivers, and organic EL display shown in FIG. 20 are connected to a power supply circuit (unillustrated).

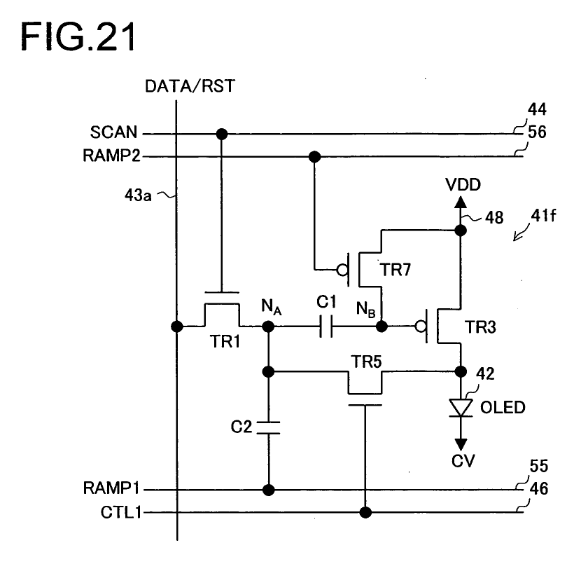

FIG. 21—Pixel Configuration

Next, the circuit configuration of each pixel 41f constituting the display panel 4f will be described with reference to FIG. 21. In FIG. 21, such elements as are found also in FIG. 2 are identified with common reference numerals and symbols, and no overlapping explanations will be repeated. Each pixel 41f is built with a pixel circuit including: an organic EL element (OLED) 42; a writing transistor TR1; a driving transistor TR3; an adjustment transistor TR5; a turning-off transistor TR7; a capacitor C1 (first capacitive element); and a capacitor C2 (second capacitive element). The driving transistor TR3 and the turning-off transistor TR7 are formed simultaneously on a single semiconductor substrate by a single process, and are formed close together within a single pixel 41f. Thus, the operation threshold voltages of the driving transistor TR3 and the turning-off transistor TR7 are approximately equal, being Vth.

Like the driving transistor TR3, the turning-off transistor TR7 is built as a P-channel MOS transistor formed as a thin-film transistor (TFT). Needless to say, possible modifications to the pixel 41f include one in which the N-channel MOS transistors are replaced with P-channel MOS transistors.

The first electrode (for example, source) of the writing transistor TR1 is connected to a data voltage line 43a to which a data voltage DATA is applied with predetermined timing and to which a reset voltage RST (this reset voltage RST has a previously set voltage) is applied with other predetermined timing. The second electrode (for example, drain) of the writing transistor TR1 is connected to one electrode of the capacitor C1. The gate of the writing transistor TR1 is connected to a scan voltage line 44 to which a scan voltage SCAN is applied.

The other electrode of the capacitor C1 is connected to the gate of the driving transistor TR3 and to the drain of the turning-off transistor TR7. A positive-side supply voltage VDD is applied via a power supply line 48 to the source of the driving transistor TR3 and to the source of the turning-off transistor TR7. In the pixel 41f, the node between the capacitor C1 and the second electrode of the writing transistor TR1 will be referred to as the node N_{A}, and the node between the capacitor C1 and the gate of the driving transistor TR3 will be referred to as the node N_{B}.

The first electrode (for example, drain) of the adjustment transistor TR5 is connected to the anode of the organic EL element 42 and to the drain of the driving transistor TR3. The second electrode (for example, source) of the adjustment transistor TR5 is connected to the node N_{A}. The gate of the adjustment transistor TR5 is connected to a control signal line 46 to which the control signal CTL1 is applied. One electrode of the capacitor C2 is connected to the node N_{A}, and the other electrode of the capacitor C2 is connected to a ramp voltage line 55 to which the ramp voltage RAMP1 is applied. The gate of the turning-off transistor TR7 is connected to a ramp voltage line 56 to which the ramp voltage RAMP2 is applied. A negative-side supply voltage CV is applied to the cathode of the organic EL element 42.

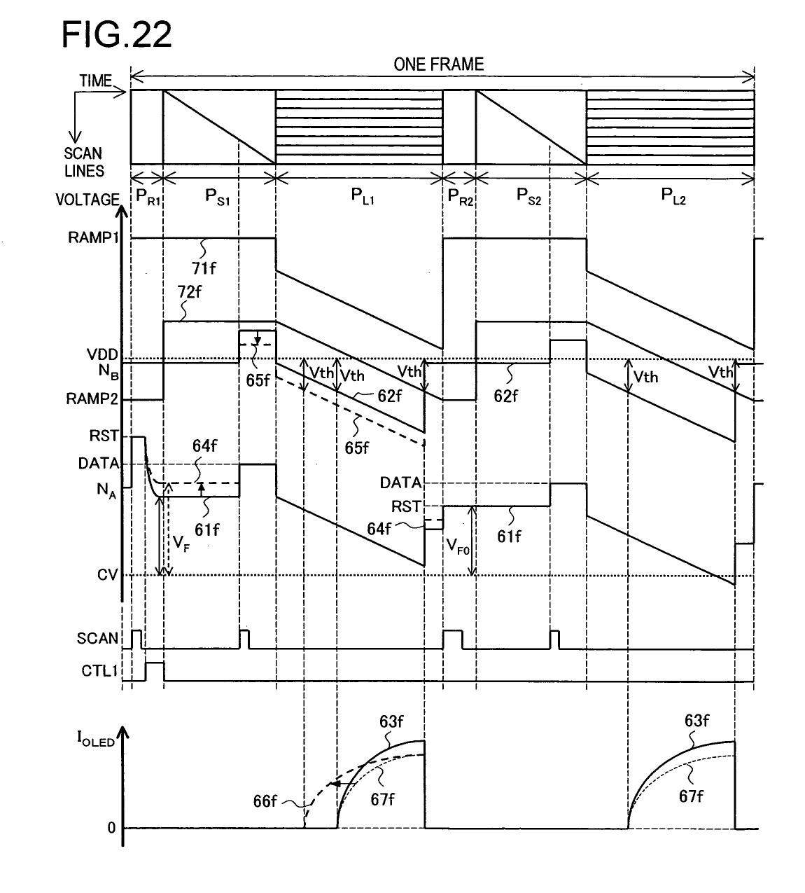

FIG. 22—Operation

Next, with reference to FIG. 22, the operation of the organic EL display device of the seventh embodiment will be described. FIG. 22 shows the voltages at relevant points in FIG. 21 and the current I_{OLED} through the organic EL element 42 as observed over one frame period.

The period for the display of one screen, that is, one frame period (the reciprocal of the frame frequency), consists of two fields, namely a first field and a second field. As shown in FIG. 22, the first field consists of a reset period P_{R1}, a scan period P_{S1}, and a light emission period P_{L1}, and the second field consists of a reset period P_{R2}, a scan period P_{S2}, and a light emission period P_{L2}.

During the scan period P_{S1} or P_{S2}, a high-level scan voltage SCAN is applied to one scan voltage line 44 after another so that a plurality of writing transistors TR1 connected to a given scan voltage line are tuned on at a time to permit data voltages DATA to be written to the corresponding pixels (of which each is like the pixel 41f). During the light emission period P_{L1} or P_{L2}, according to the data voltages DATA written during the scan period P_{S1} or P_{S2}, the corresponding organic EL elements 42 are made to emit light. During the reset period P_{R1} or P_{R2}, the variation in the operation threshold voltage (Vth) of the driving transistor (for example, the driving transistor TR3) and/or the variation in the light emission start electrode-to-electrode voltage V_{F} of the organic EL element 42 are compensated for.

Since the reset period P_{R1} and/or the scan period P_{S1} are periods during which the organic EL element 42 is made ready to emit light during the light emission period P_{L1}, those periods can be collectively referred to as the light emission preparation period in the first field. Since the reset period P_{R2} and/or the scan period P_{S2} are periods during which the organic EL element 42 is made ready to emit light during the light emission period P_{L2}, those periods can be collectively referred to as the light emission preparation period in the second field. The fact that one frame period consists of a first and a second field as described above applies also to the eighth to thirteenth and fifteenth to seventeenth embodiments described later.

In the seventh to twelfth embodiments, to solve the previously mentioned problem of black level deterioration, during, of the first and second fields, only the first field, the current I_{OLED} is compensated for a variation in the voltage V_{F}; moreover, the LUT 9 feeds the gradation signal to the data driver 3f after converting it according to the type of the current field in such a way that the relationship between the level of gradation specified by the gradation signal and the effective value of the current I_{OLED} is varied between in the first and second fields. How practical methods for realizing this will be made clear in the following description

When the kth (where k is a natural number) frame period ends, subsequently the (k+1)th frame begins, during the period of which the reset period P_{R1}, the scan period P_{S1}, the light emission period P_{L1}, the reset period P_{R2}, the scan period P_{S2}, and the light emission period P_{L2} occur in this order.

A solid line 71f represents the voltage waveform of the ramp voltage RAMP1 fed from the ramp voltage generation circuit 8f to the ramp voltage line 55. The ramp voltage RAMP1 remains fixed at a previously set initial voltage during the reset and scan periods of each field (that is, P_{R1}, P_{S1}, P_{R2}, and P_{S2}), and then decreases monotonically at a previously set variation rate (for example, −1 V per millisecond) during the light emission period of each field (that is, P_{L1} and P_{L2}). Then, during the reset period of each field (that is, P_{R1} and P_{R2}), the ramp voltage RAMP1 stops decreasing monotonically and turns back to the initial voltage.

A solid line 72f represents the voltage waveform of the ramp voltage RAMP2 fed from the ramp voltage generation circuit 8f to the ramp voltage line 56. The ramp voltage RAMP2 remains fixed at a voltage that keeps the turning-off transistor TR7 on during the reset period of each field (that is, P_{R1} and P_{R2}), and remains fixed at a voltage that keeps the turning-off transistor TR7 off during the scan period of each field (that is, P_{S1} and P_{S2}). During the light emission period of each field (that is, P_{L1} and P_{L2}), the ramp voltage RAMP2 decreases monotonically at a previously set variation rate (for example, −1 V per millisecond).

The variation rates at which the ramp voltages RAMP1 and RAMP2 vary during each light emission period are set, for example, equal. The lengths of the reset periods P_{R1} and P_{R2} are set, for example, equal. Likewise, the lengths of the scan periods P_{S1} and P_{S2} are set, for example, equal. Likewise, the lengths of the light emission periods P_{L1} and P_{L2} are set, for example, equal. Needless to say, the lengths of the periods of any of these pairs may be made different.

Solid lines 61f and 62f represent the voltage waveforms observed at the nodes N_{A} and N_{B}, respectively, when the V_{OLED}-I_{OLED} characteristic of the organic EL element 42 is as indicated by the solid line 201 in FIG. 18. A solid line 63f represents the waveform of the current I_{OLED} that flows through the organic EL element 42 when the V_{OLED}-I_{OLED} characteristic of the organic EL element 42 is as indicated by the solid line 201 in FIG. 18.

Broken lines 64f and 65f represent the voltage waveforms observed at the nodes N_{A} and N_{B}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66f represents the waveform of the current I_{OLED} that flows through the organic EL element 42 when the V_{OLED}-I_{OLED} characteristic of the organic EL element 42 has shifted as indicated by the broken line 202 in FIG. 18. It should be noted that, in the second field, the solid line 61f and the broken line 64f are identical and thus overlap each other and likewise the solid line 62f and the broken line 65f are identical and thus overlap each other.

A broken line 67f represents the waveform of the current I_{OLED} as observed when, in a case where a variation in the voltage V_{F} attributable to a time-related variation or the like in the organic EL element 42 is not fed back, the current I_{OLED} has decreased because of a time-related variation or the like. In the second field, the broken line 66f and the broken line 67f are identical and thus overlap each other.

The following description of the operation starts with the reset period P_{R1} of the kth frame period. When the (k−1)th light emission period P_{L2} (that is, the light emission period P_{L2} of the (k−1)th frame period) ends, the kth reset period P_{R1} (that is, the reset period P_{R1} in the kth frame period) begins, during which, first, the scan voltage SCAN is turned from low to high. At the moment, the reset voltage RST is being applied to the data voltage line 43a, and therefore the voltage at the node N_{A} is now equal to the reset voltage RST. This reset voltage RST is set to be significantly higher than the sum of the negative-side supply voltage CV and the voltage V_{F}. Moreover, as described previously, the ramp voltage RAMP2 is kept at a voltage that keeps the turning-off transistor TR7 on during each reset period (that is, P_{R1} and P_{R2}), and therefore, during each reset period, the voltage at the node N_{B} is equal to the positive-side supply voltage VDD. Moreover, while the scan voltage SCAN is high, the control signal CTL1 is kept low, so that the adjustment transistor TR5 remains off.

After the voltage at the node N_{A} becomes equal to the reset voltage RST, the scan voltage SCAN is turned low, and thus the writing transistor TR1 turns off. Subsequently, the control signal CTL1 is turned from low to high, so that the adjustment transistor TR5 turns on. This causes a current to flow from the node N_{A} via the adjustment transistor TR5 and the organic EL element 42 into the supply voltage CV. That is, part of the electric charge (positive electric charge) at the node N_{A}, which is now temporarily higher than the potential represented as (CV+V_{F}), is extracted via the adjustment transistor TR5 and the organic EL element 42, so that the voltage appearing at the node N_{A} stabilizes at a voltage (feedback voltage) higher than the supply voltage CV by the voltage V_{F}.

Then, when the potential at the node N_{A} has stabilized, the control signal CTL1 is turned low to turn the adjustment transistor TR5 off (bring it into a cut-off state). Now, the capacitor C1 holds a voltage (VDD−CV−V_{F}), that is, a voltage (held voltage) commensurate with the voltage V_{F}. Moreover, as will be understood from the V_{OLED}-I_{OLED} characteristic of the organic EL element 42 shown in FIG. 18, the voltage V_{F} as indicated by the broken line 64f, which represents the case where a time-related variation or the like is present, is higher than that as indicated by the solid line 61f.

Thereafter, the kth reset period P_{R1} ends, and subsequently the kth scan period P_{S1} (that is, the scan period P_{S1} of the kth frame period) begins. When the kth scan period P_{S1} begins, the potentials at the nodes N_{A} and N_{B} are kept at their respective potentials at the end of the kth reset period P_{R1}. Hence, (the voltage at the node N_{A} as indicated by the broken line 64f)>(the voltage at the node N_{A} as indicated by the solid line 61f). Incidentally, the control signal CTL1 is kept low during the scan period P_{S1}, the light emission period P_{L1}, the reset period P_{R2}, the scan period P_{S2}, and the light emission period P_{L2}.

During the scan period P_{S1}, when a high-level scan voltage SCAN is applied to a pixel 41f of interest, the writing transistor TR1 turns on. Now, the voltage at the node N_{A} rises to become equal to the data voltage DATA applied to the data voltage line 43a (that is, the data voltage DATA is written), and correspondingly, through the coupling provided by the capacitor C1, the voltage at the node N_{B} rises by the same voltage. Here, the voltage by which the voltages at the nodes N_{A} and N_{B} rise equals (DATA−V_{F}−CV). Thus, the voltage at the node N_{B} (that is, the gate voltage of the driving transistor TR3) equals (VDD−CV+DATA−V_{F}), that is, a voltage commensurate with the data voltage DATA and the voltage V_{F} (to put differently, a voltage commensurate with the data voltage DATA and the above-mentioned held voltage).

Here, since (the voltage V_{F} as indicated by the broken line 64f)>(the voltage V_{F} as indicated by the solid line 61f), once the data voltage DATA is written, the following relationship holds: (the voltage at the node N_{B} as indicated by the broken line 65f)<(the voltage at the node N_{B} as indicated by the solid line 62f).

After the data voltage DATA is written, the scan voltage SCAN applied to the pixel 41f of interest is turned back low. When data voltages are written to all the pixels 41f constituting the display panel 4f, the scan period P_{S1} ends, and the light emission period P_{L1} begins.

When the light emission period P_{L1} begins, the ramp voltage RAMP1 falls abruptly by a previously set voltage. The purpose is to maximize the proportion of the duration for which the organic EL element 42 actually emits light during the light emission period P_{L1}. This abrupt fall of the ramp voltage RAMP1 causes the potentials at the nodes N_{A} and N_{B} to fall by the same voltage. Thereafter, as described previously, the ramp voltages RAMP1 and RAMP2 decrease linearly at previously set fixed rates.

When the voltage at the node N_{B} becomes equal to or lower than the voltage (VDD−Vth), a current starts to flow through the organic EL element 42. Here, since, at the beginning of the light emission period P_{L1}, (the voltage at the node N_{B} as indicated by the broken line 65f)<(the voltage at the node N_{B} as indicated by the solid line 62f), light emission starts earlier in the case indicated by the broken line 65f. Then, the current that has started to flow through the organic EL element 42 during the light emission period increases gradually. Then, when the ramp voltage RAMP2 becomes equal to or lower than the voltage (VDD−Vth), the turning-off transistor TR7 turns on, and causes the voltage at the node N_{B} to rise to the positive-side supply voltage VDD. Correspondingly, the driving transistor TR3 turns off, and the organic EL element 42 stops emitting light.

After the end of the light emission, the light emission period P_{L1} ends, and the reset period P_{R2} of the second field begins. When the reset period P_{R2} starts, the ramp voltage RAMP1 is turned back to its initial voltage, and the scan voltage SCAN is turned high. At the moment, the reset voltage RST is being applied to the data voltage line 43a, and therefore the voltage at the node N_{A} is now equal to the reset voltage RST. The magnitude of the reset voltage RST applied to the data voltage line 43a during the reset period P_{R2} of the second field is different from that applied there in the reset period P_{R1} of the first field, and is set approximately equal to the sum of the negative-side supply voltage CV and the voltage V_{F} in the initial state (hereinafter referred to simply as the “voltage V_{F0}”). That is, the voltage V_{F0} is equal to the sum of the negative-side supply voltage CV and the voltage V_{F} observed when V_{OLED}-I_{OLED} characteristic of the organic EL element 42 is as indicated by the solid line 201 in FIG. 18.

Moreover, as described previously, the ramp voltage RAMP2 is kept at a voltage that keeps the turning-off transistor TR7 on during each reset period (that is, P_{R1} and P_{R2}), and therefore, during each reset period, the voltage at the node N_{B} is equal to the positive-side supply voltage VDD.

After the voltage at the node N_{A} becomes equal to the reset voltage RST, the scan voltage SCAN is turned low, and thus the writing transistor TR1 turns off. Whereas, in the first field, the control signal CTL1 is thereafter turned high to turn the adjustment transistor TR5 on, in the second field, the adjustment transistor TR5 is kept off. That is, in the second field, no voltage (feedback voltage) commensurate with the voltage V_{F} is transmitted to the capacitor C1.

Subsequent to the reset period P_{R2}, during the scan period P_{S2}, when a high-level scan voltage SCAN is applied to the pixel 41f of interest, the writing transistor TR1 turns on. Now, the voltage at the node N_{A} rises to become equal to the data voltage DATA applied to the data voltage line 43a (that is, the data voltage DATA is written), and correspondingly, through the coupling provided by the capacitor C1, the voltage at the node N_{B} rises by the same voltage. Here, it should be noted, though a detailed discussion will be given later, that the data voltage DATA written to each pixel in the second field is, in principle, different from that written thereto in the first field.

After the data voltage DATA is written, the scan voltage SCAN applied to the pixel 41f of interest is turned back low. When data voltages are written to all the pixels 41f constituting the display panel 4f, the scan period P_{S2} ends, and the light emission period P_{L2} begins.

When the light emission period P_{L2} begins, the ramp voltage RAMP1 falls abruptly by a previously set voltage. The purpose is to maximize the proportion of the duration for which the organic EL element 42 actually emits light during the light emission period P_{L2}. This abrupt fall of the ramp voltage RAMP1 causes the potentials at the nodes N_{A} and N_{B} to fall by the same voltage. Thereafter, as described previously, the ramp voltages RAMP1 and RAMP2 decrease linearly at previously set fixed rates.

When the voltage at the node N_{B} becomes equal to or lower than the voltage (VDD−Vth), a current starts to flow through the organic EL element 42, and this current then increases gradually during the light emission period P_{L2}. Then, when the ramp voltage RAMP2 becomes equal to or lower than the voltage (VDD−Vth), the turning-off transistor TR7 turns on, and causes the voltage at the node N_{B} to rise to the positive-side supply voltage VDD. Correspondingly, the driving transistor TR3 turns off, and the organic EL element 42 stops emitting light. After the end of the light emission, the light emission period P_{L2} ends, and the (k+1)th reset period P_{R1} begins, during which operations similar to those described above are repeated.

As described previously, the operation threshold voltages (Vth) of the driving transistor TR3 and the turning-off transistor TR7 are approximately equal. Thus, even if a fabrication-associated variation causes to deviate the time point at which the driving transistor TR3 turns on, it also causes to deviate, by the same length of time and in the same direction, the time point at which the turning-off transistor TR7 later turns the driving transistor TR3 off.

Thus, regardless of variations in the operation threshold voltages of the two transistors TR3 and TR7, the length of time after the driving transistor TR3 turns on until the turning-off transistor TR7 turns the driving transistor TR3 off remains accurately commensurate with the data voltage. In this way, basically, gradation is modulated by the light emission duration of the organic EL element 42 that varies according to the data voltage DATA.

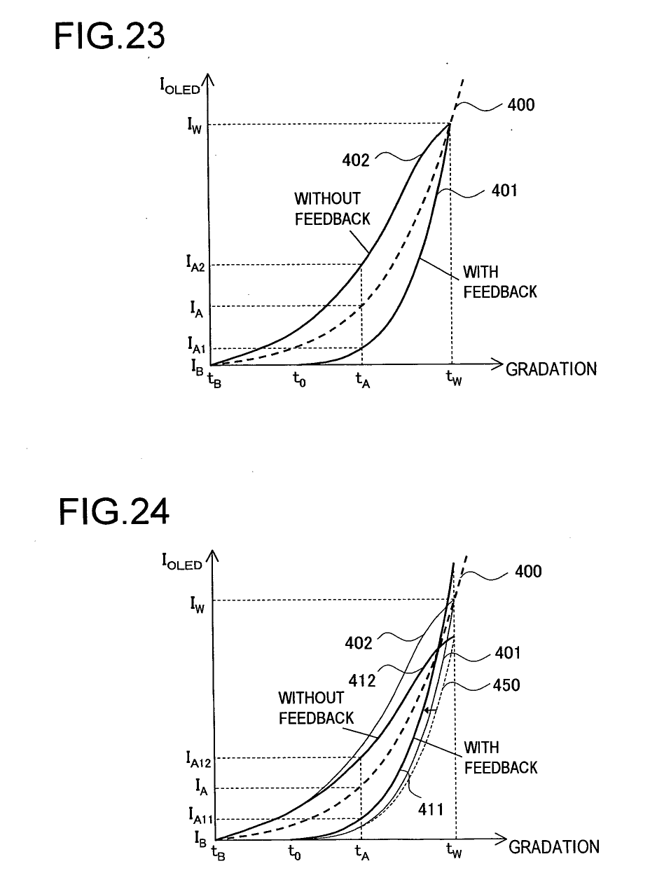

FIGS. 23 and 24—Function of the LUT

As described above, the current I_{OLED} is compensated for a variation in the voltage V_{F} only in the first field. Here, to overcome the previously described problem of black level deterioration, the data voltages DATA written in the first and second fields are made (in principle) different. Now, this will be described with reference to FIGS. 23 and 24 and other drawings. It should be understood that the configuration and operation of the LUT 9 and other circuit blocks described below with reference to FIGS. 23 to 27 are applicable to any of the eighth to twelfth and fifteenth to seventeenth embodiments described later.

In FIGS. 23 and 24, the horizontal axis represents the level of gradation specified by the gradation signal outputted from the image signal processing circuit 6 (or the image source mentioned earlier), and, along the horizontal axis, going rightward means moving to higher levels of gradation. The black level of gradation with the lowest lightness is represented by t_{B}, and the while level of gradation with the highest lightness is represented by t_{W}. The vertical axis represents the effective value of the current I_{OLED}.

A broken line 400 represents the curve of the ideal relationship between the level of gradation and the effective value of the current I_{OLED}, that is, the relationship between the level of gradation and the effective value of the current I_{OLED} as aimed at in an organic EL display device embodying the present invention. A solid line 401 represents the relationship between the level of gradation and the effective value of the current I_{OLED} in the first field when the V_{OLED}-I_{OLED} characteristic of the organic EL element 42 is as indicated by the solid line 201 in FIG. 18. A solid line 402 represents the relationship between the level of gradation and the effective value of the current I_{OLED} in the second field when the V_{OLED}-I_{OLED} characteristic of the organic EL element 42 is as indicated by the solid line 201 in FIG. 18.

The broken line 400 and the solid lines 401 and 402 cross one another at the white level t_{W} of gradation, and, on all of those lines 400, 401, and 402, the effective value of the current I_{OLED} corresponding to the white level t_{W} of gradation equals I_{W}. The broken line 400 and the solid line 402 cross each other at the black level t_{B} of gradation, and, on those two lines 400 and 402, the effective value of the current I_{OLED} corresponding to the black level t_{B} of gradation equals I_{B}.

At no intermediate level of gradation between the levels t_{B} and t_{W} do the broken and solid lines 400, 401, and 402 cross each other. For example, on the broken and solid lines 400, 401, and 402, the effective value of the current I_{OLED} corresponding to a given level t_{A} of gradation is I_{A}, I_{A1}, and I_{A2}, respectively, and these values fulfill the inequality “I_{A1<I}_{A}<I_{A2}”. Moreover, at any level of gradation between the black level t_{B} and a certain intermediate level t₀, the effective value of the current I_{OLED} in the first field remains equal to (or approximately equal to) I_{B}. As the level of gradation increases from the intermediate level t₀ to the white level t_{W}, the effective value of the current I_{OLED} represented by the solid line 401 increases exponentially to reach I_{W}.

Moreover, the relationship between the level of gradation and the effective value of the current I_{OLED} in each field is so set that, at all levels of gradation, the equation “I_{A}=(I_{A1}+I_{A2})/2” is fulfilled. That is, at all levels of gradation, the mean value of the effective value of the current I_{OLED} in the first field and the effective value of the current I_{OLED} in the second field lies on the curve represented by the broken line 400. I_{A} thus represents the value with reference to which to determine the effective value of the current I_{OLED} to feed in response to the received gradation signal, and can thus be called the reference current value.

The LUT 9 feeds the gradation signal to the data driver 3f after converting it according to the type of the current field in such a way that the above-described relationship between the level of gradation and the effective value of the current I_{OLED} is fulfilled. Now, this will be described more specifically with interest concentrated on one pixel. For example, when the level of gradation specified by the gradation signal received by the LUT 9 is a level t_{A}, the LUT 9 feeds the data driver 3f with a first converted gradation signal (a first compensated gradation signal) in the first field and with a second converted gradation signal (a second compensated gradation signal) in the second field in such a way that the effective value of the current I_{OLED} that flows through the organic EL element 42 during the light emission periods P_{L1} and P_{L2} of the first and second fields equals I_{A1} and I_{A2}, respectively. How to convert the received gradation signal into the first and second converted gradation signals is previously set.

Having received the first converted gradation signal, the data driver 3f sets the data voltage DATA to be fed to the pixel during the scan period P_{S1} of the first field equal to a first data voltage commensurate with the first converted gradation signal. The effective value of the current I_{OLED} in the pixel to which this first data voltage is written equals I_{A1}. Likewise, having received the second converted gradation signal, the data driver 3f sets the data voltage DATA to be fed to the pixel during the scan period P_{S2} of the second field equal to a second data voltage commensurate with the second converted gradation signal. The effective value of the current I_{OLED} in the pixel to which this second data voltage is written equals I_{A2}.

Consider now a case where a time-related variation or the like in the organic EL element 42 has caused an increase in the voltage V_{F} (see FIG. 24). If the variation in the voltage V_{F} attributable to a time-related variation or the like in the organic EL element 42 is not fed back at all, the time-related variation or the like causes the relationship between the level of gradation and the effective value of the current I_{OLED} as represented by the solid line 401 to shift as indicated by a broken line 450. In the first field, however, the variation is in fact fed back, so that the time-related variation or the like causes the relationship between the level of gradation and the effective value of the current I_{OLED} in the first field to shift from as indicated by the solid line 401 to as indicated by a solid line 411. That is, when the voltage V_{F} increases, the effective value of the current I_{OLED} that flows to correspond to a given level of gradation increases in the first field.

On the other hand, in the second field, the variation in the voltage V_{F} is not fed back. Thus, the time-related variation or the like causes the relationship between the level of gradation and the effective value of the current I_{OLED} to shift from as indicated by the solid line 402 to as indicated by a solid line 412. That is, when the voltage V_{F} increases, the effective value of the current I_{OLED} that flows to correspond to a given level of gradation decreases in the second field.

For example, the effective value of the current I_{OLED} corresponding to the level t_{A} of gradation is, on the solid lines 411 and 412, equal to I_{A11} and I_{A12}, respectively. This values, relative to the above-mentioned values I_{A1} and I_{A2}, fulfill the inequalities “I_{A1}<I_{A11}” and “I_{A2}>I_{A12}”. Moreover, with the time-related variation characteristics of the organic EL element 42 and other factors into consideration, the LUT 9 is so configured that, at all levels of gradation, the mean value of I_{A11} and I_{A12} is as nearly equal to I_{A} as possible (that is, to convert the received gradation signal appropriately into the above-mentioned first and second converted gradation signals).

When a time-related variation or the like in the organic EL element 42 causes an increase in the voltage V_{F}, in a range of comparatively high levels of gradation, the resulting decrease in the effective value of the current I_{OLED} is appropriately compensated for through the feedback of the variation in the voltage V_{F} in the first field. On the other hand, since the effective value of the current I_{OLED} in the first field increases exponentially from the intermediate level t₀ of gradation, even though the variation in the voltage V_{F} is fed back in the first field, no black level deterioration, like that indicated by the broken line 303 in FIG. 19, occurs.

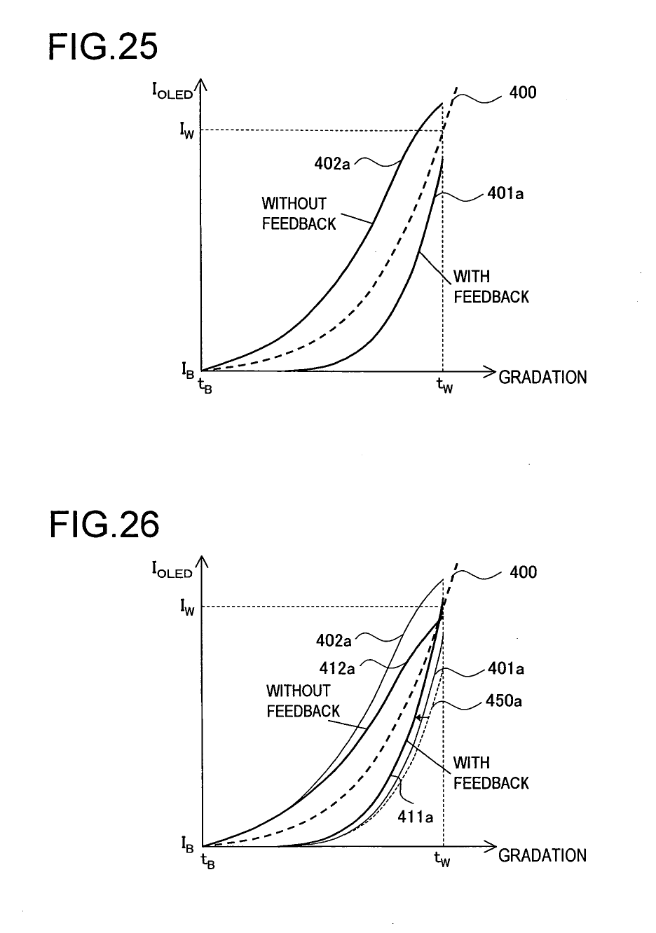

FIGS. 25 and 26—Reduction of Feedback

In a case where, with the relationship between the level of gradation and the effective value of the current I_{OLED} shown in FIGS. 23 and 24, the current I_{OLED} is compensated for excessively, that is, in a case where the feedback in response to a variation in the voltage V_{F} is excessive, the LUT 9 may be so modified as to realize the relationship between the level of gradation and the effective value of the current I_{OLED} shown in FIGS. 25 and 26 instead of that shown in FIGS. 23 and 24 (this modification will hereinafter be referred to as Modified Example 1).

In FIGS. 25 and 26, such solid and broken lines as are found also in FIGS. 23 and 24 are identified with common reference numerals, and no overlapping explanations will be repeated. Likewise, in FIGS. 25 and 26, such specific values as are found also in FIGS. 23 and 24 are identified with common reference symbols (t_{W}, etc.), and no overlapping explanations will be repeated. In FIGS. 25 and 26, the horizontal axis represents the level of gradation specified by the gradation signal outputted from the image signal processing circuit 6 (or the image source mentioned earlier), and, along the horizontal axis, going rightward means moving to higher levels of gradation. The vertical axis represents the effective value of the current I_{OLED}.

The solid line 401a is a modified version of the solid line 401, and represents the relationship between the level of gradation and the effective value of the current I_{OLED} in the first field when the V_{OLED}-I_{OLED} characteristic of the organic EL element 42 is as indicated by the solid line 201 in FIG. 18. The solid line 402a is a modified version of the solid line 402, and represents the relationship between the level of gradation and the effective value of the current I_{OLED} in the second field when the V_{OLED}-I_{OLED} characteristic of the organic EL element 42 is as indicated by the solid line 201 in FIG. 18.

The solid line 401a is so set that, at all levels of gradation, the current I_{OLED} thereon is smaller than that on the solid line 401. Likewise, the solid line 402a is so set that, at all levels of gradation, the current I_{OLED} thereon is greater than that on the solid line 402. Moreover, at all levels of gradation, the mean value of the effective value of the current I_{OLED} in the first field and the effective value of the current I_{OLED} in the second field lies on the curve represented by the broken line 400.

If the variation in the voltage V_{F} attributable to a time-related variation or the like in the organic EL element 42 is not fed back at all, the time-related variation or the like causes the relationship between the level of gradation and the effective value of the current I_{OLED} as represented by the solid line 401a to shift as indicated by a broken line 450a. In the first field, however, the variation is in fact fed back, so that the time-related variation or the like causes the relationship between the level of gradation and the effective value of the current I_{OLED} in the first field to shift from as indicated by the solid line 401a to as indicated by a solid line 411a.

On the other hand, in the second field, the variation in the voltage V_{F} is not fed back. Thus, the time-related variation or the like causes the relationship between the level of gradation and the effective value of the current I_{OLED} to shift from as indicated by the solid line 402a to as indicated by a solid line 412a. Moreover, with the time-related variation characteristics of the organic EL element 42 and other factors into consideration, the LUT 9 is so configured that, at all levels of gradation, the mean value of the effective value of the current I_{OLED} in the first field and the effective value of the current I_{OLED} in the second field lies, even in the presence of a time-related variation, on the curve represented by the broken line 400 (that is, to convert the received gradation signal appropriately into the above-mentioned first and second converted gradation signals).

Adopting Modified Example 1 described above helps reduce the magnitude by which the current I_{OLED} is compensated for through the feedback of the variation in the voltage V_{F}.

Overcompensation

In a case where the operating points at which the driving transistor TR3 (or the later-described transistor TR23) and the organic EL element 42 operate when displaying the white level of gradation are set within the linear region of the driving transistor TR3 in terms of its Vds-Id characteristics, as shown in FIG. 18, a drop in brightness accompanying a drop in the current I_{OLED} resulting from a variation in the voltage V_{F} may occur. A drop in brightness may also occur as a result of a drop in the light emission efficiency of the organic EL element 42 (that is, deterioration in the characteristics of the light-emitting material).

Such a drop in brightness resulting from a drop in light emission efficiency may be compensated for by configuring the LUT 9 (and the data driver 3f) and the ramp voltage generation circuit 8f in such a way that, at all levels of gradation or in a certain range of gradation, the inequality “I_{A}<(I_{A11}+I_{A12})/2” (see FIG. 24) fulfills. Conceptually, this means shifting the solid line 411 in FIG. 24 further leftward, that is, configuring the LUT 9 (and the data driver 3f) and the ramp voltage generation circuit 8f in such a way that, when the voltage V_{F} has increased as a result of a time-related variation or a drop in the operating ambient temperature, the effective value of the current I_{OLED} that flows to correspond to a given gradation signal becomes greater than before the increase in the voltage V_{F}. For the sake of convenience, this will be called “overcompensation”.

For example, in a case where the voltage V_{F} in the initial state (that is, voltage V_{F0}) equals 2.0 V and the effective value (the effective value in the entire frame) of the current I_{OLED} that flows to correspond to a given gradation signal in the initial state is assumed to be 1, a configuration is adopted with which, when the voltage V_{F} becomes equal to 2.2 V, the effective value (the effective value in the entire frame) of the current I_{OLED} that flows to correspond to the same gradation signal (provided that the ambient temperature remains fixed) becomes equal to 1.1.

The overcompensation described above can be realized by appropriately increasing the increase in the current I_{OLED} during the light emission period P_{L1} in response to an increase in the voltage V_{F}. That is, a configuration is adopted that permits the magnitude of the current I_{OLED} to vary sensitively in the light emission period P_{L1} in response to variations in the voltage V_{F}. For example, the overcompensation described above can be realized by appropriately setting the relationship between the variation rates of the ramp voltages RAMP1 and RAMP2 during the light emission periods (in particular, the light emission period P_{L1}), the data voltage DATA, and the voltage V_{F}. For example, in the waveform diagram of FIG. 22, making the variation rates of the ramp voltages RAMP1 and RAMP2 comparatively gentle permits an increase in the voltage V_{F} to have a comparatively great influence on the increase of the magnitude of the current I_{OLED} during the light emission period P_{L1}. The overcompensation described above can also be realized by making the proportion of the magnitude of current in the first field in the total magnitude of the current I_{OLED} comparatively larger (increasing it). This is because doing so makes comparatively great (increases) the magnitude by which the current I_{OLED} is compensated for through feedback commensurate with a variation in the voltage V_{F}. Overcompensation lets the overall current (power consumption) increase with time. This may be prevented by monitoring the overall current and decreasing the amplitude of the image signal or lowering the reset voltage RST in the second field so that the overall current (power consumption) does not vary with time.

When considered in FIG. 22 (see the waveform of the current I_{OLED}), overcompensation is equivalent to making the sum of the magnitude of the current I_{OLED} in the first field as represented by the broken line 66f and the magnitude of the current I_{OLED} in the second field as represented by the broken line 67f greater than the total magnitude of the current I_{OLED} in the first and second fields as represented by the solid line 63f.

Such overcompensation is effective in compensating for burn-in. This will now be explained. For example, consider an experiment in which, for a long period, only particular pixels (hereinafter the “test pixels”) are kept emitting light at the white level while all the other pixels are kept at the black level. In this case, the test pixels emit a significantly larger amount of light than the other pixels, and thus the test pixels exhibit a greater increase in the voltage V_{F} and a greater lowering in the light emission efficiency of the organic EL element.

Even though the increase in the voltage V_{F} is greater than in the other pixels, its influence is canceled through the above-described feedback of the variation in the voltage V_{F}. However, simply compensating for the decrease in the current I_{OLED} resulting from the variation in the voltage V_{F} does not completely eliminate burn-in. The reason is that, even when all the pixels are fed with the same gradation signal after the above-described experiment, because of the lowered in light emission efficiency, the test pixels alone emit light with lower brightness (this is generally called “burn-in”).

In such a case, performing overcompensation permits the current I_{OLED} to increase in such a way as to compensate for even a drop in brightness resulting from a drop in light emission efficiency. That is, burn-in is compensated for more effectively.

Even when overcompensation is performed, at any level of gradation between the black level t_{B} and a certain intermediate level t₀, the effective value of the current I_{OLED} in the first field remains equal to (or approximately equal to) I_{B}. Moreover, the effective value of the current I_{OLED} in the first field is made to rise exponentially from the intermediate level t₀, and thus no black level deterioration occurs.

The above-described overcompensation, which is effective in a case where the operating points at which the driving transistor TR3 (or the later-described transistor TR23) and the organic EL element 42 operate when displaying the white level of gradation are set within the linear region of the driving transistor TR3 (or the later-described transistor TR23) in terms of its Vds-Id characteristic, is also applicable to the eighth to thirteenth and fifteenth to seventeenth embodiments described later, though no overlapping explanations will be repeated in connection with those embodiments.

The above-described overcompensation is applicable even to the already-described first to sixth embodiment and to the later-described fourteenth embodiment (because, also in these embodiments, the variation of the voltage V_{F} is transmitted to the capacitor C1). Specifically, the data driver 3 (or the data driver 3e) and the ramp voltage generation circuit 8 may be so configured that, when the voltage V_{F} has increased as a result of a time-related variation or a drop in the operating ambient temperature, the effective value of the current I_{OLED} that flows to correspond to a given gradation signal becomes greater than before the increase in the voltage V_{F} (see FIGS. 1 and 13). When the above-described overcompensation is applied to the first to sixth and fourteenth embodiments, the increase in the current I_{OLED} during the light emission period in response to an increase in the voltage V_{F} is appropriately increased (for example, see FIG. 3). For example, in the waveform diagram of FIG. 3, making the variation rate of the ramp voltage RAMP comparatively gentle permits an increase in the voltage V_{F} to have a comparatively great influence on the increase of the effective value of the current I_{OLED} during the light emission period. When considered in FIG. 3 (see the waveform of the current I_{OLED}), overcompensation is equivalent to making the magnitude of the current I_{OLED} as represented by the broken line 66 greater than the magnitude of the current I_{OLED} as represented by the solid line 63.

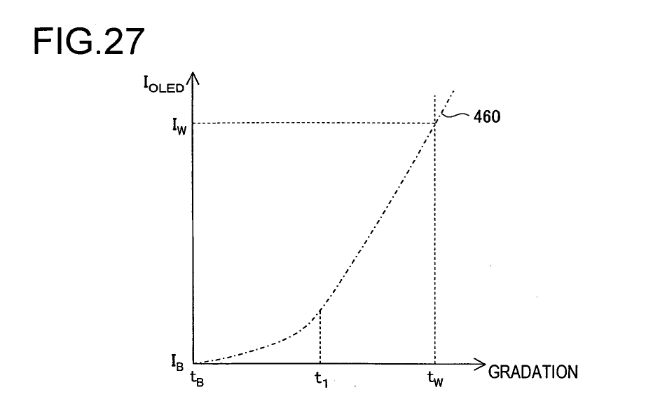

In a case where, as indicated by a dash-dot line 460 in FIG. 27, the effective value of the current I_{OLED} increases exponentially from the black level t_{B} of gradation to an intermediate level t₁ and then increases linearly from the intermediate level t₁ to the white level t_{W} of gradation (that is, in a case where a display panel 4f having such a characteristic is adopted), in the first field, the light emission of each pixel is controlled by exploiting only the exponential part of the characteristic. This also applies to the seventh to twelfth and fifteenth to seventeenth embodiments described later.

Feeding back an increase in the voltage V_{F} is equivalent to adding (or subtracting) the increase to (or from) the data voltage DATA, and is thus equivalent to shifting leftward the curve representing the relationship between the level of gradation and the effective value of the current I_{OLED}. If the curve so shifted is exponential, the feedback causes the current to increase comparatively greatly in a range of high levels of gradation but only slightly in a range of low levels of gradation, and thus causes no black level deterioration (lightening at low levels of gradation). Incidentally, in the second field, both the exponential and linear pars of the dash-dot line 460 can be used. This is because, in the first place, the second field, in which no feedback of an increase in the voltage V_{F} is performed, is free from black level deterioration.

The operating points at which the driving transistor TR3 (or the later-described transistor TR23) and the organic EL element 42 operate may be set within the saturation region of the driving transistor TR3 in terms of its Vds-Id characteristics. To put more precisely, for example, the operating points at which the driving transistor TR3 (or the later-described transistor TR23) and the organic EL element 42 operate to correspond to the white level of gradation may be set within the saturation region of the driving transistor TR3 in terms of its Vds-Id characteristics.

When those operation points are set in a high-voltage part of the saturation region of the Vds-Id characteristic (that is, a part thereof where Vds is comparatively high), although the current I_{OLED} no longer decreases in response to an increase in the voltage V_{F}, burn-in results from different degrees of lowering in light emission efficiency. With the configuration of this embodiment, however, an increase in the voltage V_{F} is added to the data voltage, and this alleviate the burn-in resulting from different degrees of lowering in light emission efficiency. These circumstances hold also in the already-described first to sixth embodiments and the later-described eighth to thirteenth embodiment. That is, the recent invention is useful as a measure against burn-in even when the driving transistor is operated in the saturation region.

### Eighth Embodiment

An eighth embodiment of the present invention as applied to an organic EL display device will be described below. The overall configuration of the organic EL display device of the eighth embodiment of the present invention is substantially the same as that shown in FIG. 20; therefore, no separate diagram is furnished in that aspect. Here, the individual circuit blocks constituting the organic EL display device are so modified as to realize, as desired in this embodiment, the operation described below.

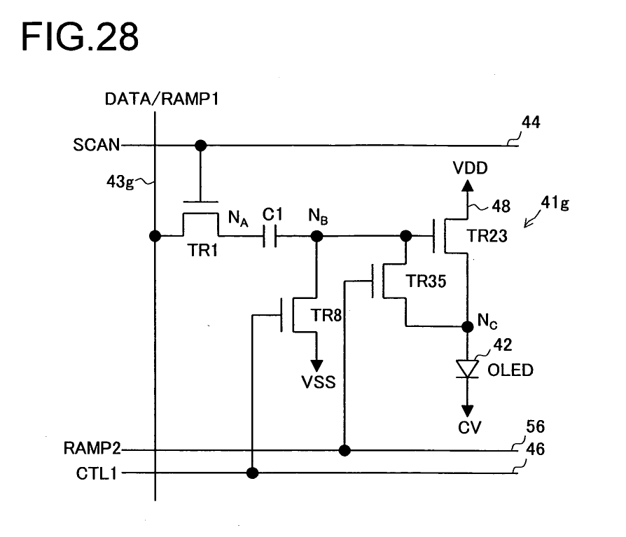

The display panel 4f is so modified that each pixel 41g constituting it is built with a pixel circuit configured as shown in FIG. 28. In FIG. 28, such elements as are found also in FIG. 21 are identified with common reference numerals and symbols, and no overlapping explanations will be repeated.

The circuit configuration of the pixel 41g will be described below. The pixel circuit constituting each pixel 41g includes: organic EL element 42; a writing transistor TR1; a driving transistor TR23, an adjustment transistor TR35; a clipping transistor TR8; and a capacitor C1 (first capacitive element). The driving transistor TR23 and the adjustment transistor TR35 are formed simultaneously on a single semiconductor substrate by a single process, and are formed close together within a single pixel 41g. Thus, the operation threshold voltages of the driving transistor TR23 and the adjustment transistor TR35 are approximately equal, being Vth. The driving transistor TR23, the adjustment transistor TR35, and the clipping transistor TR8 are built as N-channel MOS transistors formed as thin-film transistors (TFTs).

The first electrode (for example, source) of the writing transistor TR1 is connected to a data voltage line 43g to which a data voltage DATA from the data driver 3f or a ramp voltage RAMP 1 from the ramp voltage generation circuit 8f is applied. The second electrode (for example, drain) of the writing transistor TR1 is connected to one electrode of the capacitor C1. The gate of the writing transistor TR1 is connected to a scan voltage line 44 to which a scan voltage SCAN is applied.

The other electrode of the capacitor C1 is connected to the gate of the driving transistor TR23, to the drain of the adjustment transistor TR35, and to the drain of the clipping transistor TR8. A positive-side supply voltage VDD is applied via a power supply line 48 to the drain of the driving transistor TR23.

The source of the adjustment transistor TR35 is connected to the anode of the organic EL element 42 and to the source of the driving transistor TR23. The gate of the adjustment transistor TR35 is connected to a ramp voltage line 56 to which a ramp voltage RAMP2 from the ramp voltage generation circuit 8f is applied. In the pixel 41g, the node between the capacitor C1 and the second electrode of the writing transistor TR1 will be referred to as the node N_{A}, the node between the capacitor C1 and the gate of the driving transistor TR23 will be referred to as the node N_{B}, and the node between the source of the adjustment transistor TR35 and the anode of the organic EL element 42 will be referred to as the node N_{C}.

A supply voltage VSS higher than the negative-side supply voltage CV but lower than the positive-side supply voltage VDD is applied to the source of the clipping transistor TR8. The gate of the clipping transistor TR8 is connected to a control signal line 46 to which a control signal CTL1 is applied. A negative-side supply voltage CV is applied to the cathode of the organic EL element 42.

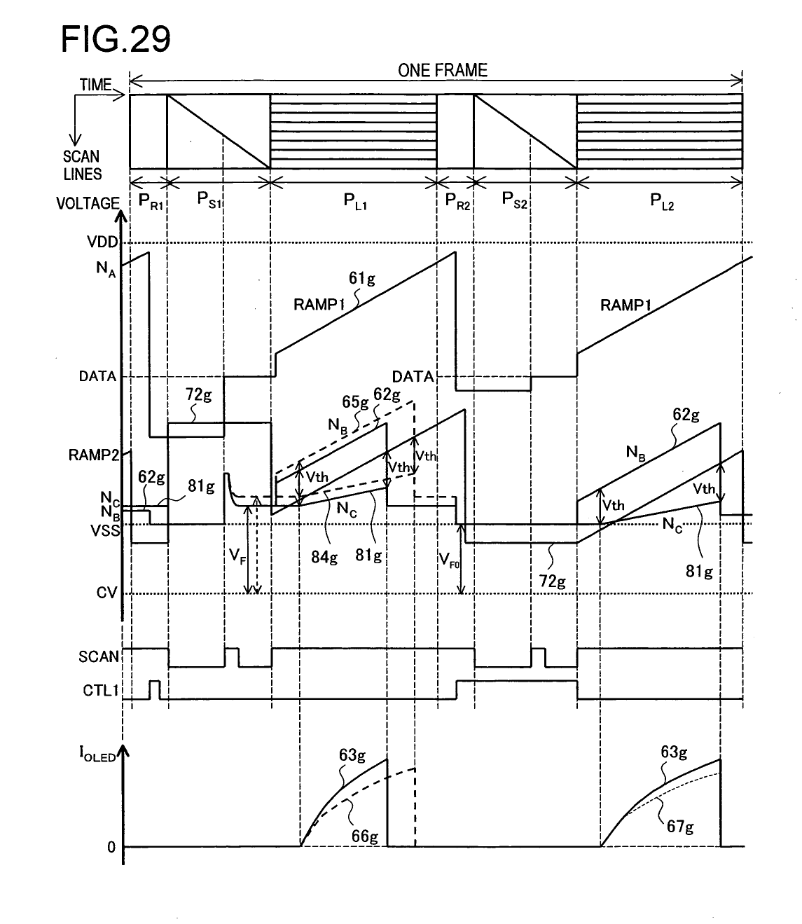

Now, with reference to FIG. 29, the operation of the organic EL display device of the eighth embodiment will be described. FIG. 29 shows the voltages at relevant points in FIG. 28 and the current I_{OLED} through the organic EL element 42 as observed over one frame period. The period for the display of one screen, that is, one frame period (the reciprocal of the frame frequency), consists of two fields, namely a first field and a second field. As in the seventh embodiment, the first field consists of a reset period P_{R1}, a scan period P_{S1}, and a light emission period P_{L1}, and the second field consists of a reset period P_{R2}, a scan period P_{S2}, and a light emission period P_{L2}.

Also in this embodiment, to solve the previously mentioned problem of black level deterioration, during, of the first and second fields, only the first field, the current I_{OLED} is compensated for a variation in the voltage V_{F}; moreover, the LUT 9 feeds the gradation signal to the data driver 3f after converting it into a first converted gradation signal corresponding to the first field and a second converted gradation signal corresponding to the second field in such a way that a relationship similar to that realized in the seventh embodiment (FIGS. 23 to 27) is realized between the level of gradation specified by the gradation signal and the effective value of the current I_{OLED}. Thus, advantages similar to those achieved in the seventh embodiment are achieved here.

A solid line 72g represents the voltage waveform of the ramp voltage RAMP2 fed from the ramp voltage generation circuit 8f to the ramp voltage line 56. The ramp voltage RAMP2 increases monotonically at a previously set variation rate (for example, 1 V per millisecond) during the light emission period of each field (that is, P_{L1} and P_{L2}). Then, during the reset period of each field (that is, P_{R1} and P_{R2}), the ramp voltage RAMP2 stops increasing monotonically and falls back to a previously set initial voltage.

Moreover, during the light emission period of each field, the ramp voltage RAMP1 is applied to the data voltage line 43g. The ramp voltage RAMP1 increases monotonically at a previously set variation rate (for example, 1 V per millisecond) during the light emission period of each field. Then, during the reset period of each field, the ramp voltage RAMP1 stops increasing monotonically and falls back to a previously set initial voltage. The variation rates at which the ramp voltages RAMP1 and RAMP2 vary during each light emission period are set, for example, equal. During the reset periods P_{R1} and P_{R2} and the light emission periods P_{L1} and P_{L2}, the ramp voltage RAMP1 is fed to the data voltage line 43g, and, during the scan periods P_{S1} and P_{S2}, the data voltage DATA is fed to the data voltage line 43g.

Solid lines 62g and 81g represent the voltage waveforms observed at the nodes N_{B} and N_{C}, respectively, when the V_{OLED}-I_{OLED} characteristic of the organic EL element 42 is as indicated by the solid line 201 in FIG. 18. A solid line 63g represents the waveform of the current I_{OLED} that flows through the organic EL element 42 when the V_{OLED}-I_{OLED} characteristic of the organic EL element 42 is as indicated by the solid line 201 in FIG. 18. A solid line 61g represents the voltage waveform at the node N_{A}.

Broken lines 65g and 84g represent the voltage waveforms observed at the nodes N_{B} and N_{C}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66g represents the waveform of the current I_{OLED} that flows through the organic EL element 42 when the V_{OLED}-I_{OLED} characteristic of the organic EL element 42 has shifted as indicated by the broken line 202 in FIG. 18.

During the scan period P_{S2} and the light emission period P_{L2} in the second field, the solid line 81g and the broken line 84g are identical and thus overlap each other, and the solid line 62g and the broken line 65g are identical and thus overlap each other. In the scan period P_{S1} in the first field, the solid line 81g and the solid line 62g are identical and thus overlap each other, and the broken line 84g and the broken line 65g are identical and thus overlap each other (the voltages at the nodes N_{B} and N_{C} are equal).

A broken line 67g represents the waveform of the current I_{OLED} as observed when, in a case where a variation in the voltage V_{F} attributable to a time-related variation or the like in the organic EL element 42 is not fed back, the current I_{OLED} has decreased because of a time-related variation or the like. In the second field, the broken line 66g and the broken line 67g are identical and thus overlap each other.

The following description of the operation starts with the reset period P_{R1} of the kth frame period. Starting in the (k−1)th light emission period P_{L2}, the scan voltage SCAN remains high during the kth reset period P_{R1}, and thus the writing transistor TR1 remains on. Moreover, during the reset period P_{R1}, the ramp voltage RAMP2 is fixed at a voltage that keeps the adjustment transistor TR35 off.

In addition, at the beginning of the reset period P_{R1}, a comparatively high voltage (the ramp voltage RAMP1) is applied to the data voltage line 43g, and, in the middle of the reset period P_{R1}, this voltage falls abruptly. This causes the voltage at the node N_{A} to fall abruptly. Here, the voltage at the node N_{A} obtained as a result of the fall in the ramp voltage RAMP1 is sufficiently low to permit the voltages at the nodes N_{B} and N_{C} to become equal to the voltage V_{F} during the scan period P_{S1}.

The abrupt fall in the voltage at the node N_{A} is transmitted via the capacitor C1 to the node N_{B}, and, while this transmission is taking place, the control signal CTL1 remains high to keep the clipping transistor TR8 on. This makes the voltage at the node N_{B} equal to the supply voltage VSS. At the end of the fall of the ramp voltage RAMP1, the control signal CTL1 turns low to turn the clipping transistor TR8 off. Subsequently, the scan voltage SCAN is turned low, and then the scan period P_{S1} begins. The clipping transistor TR8 is kept off during the scan period P_{S1} and the light emission period P_{L1}.

During the scan period P_{S1}, the ramp voltage RAMP 2 is kept at a comparatively high voltage (see the solid line 72g) that keeps the adjustment transistor TR35 on. Thus, during the scan period P_{S1}, the voltages at the nodes N_{B} and N_{C} are equal. Moreover, during the scan period P_{S1}, the data voltage DATA from the data driver 3f is fed to the data voltage line 43g.

As a high-level scan voltage is applied to one scan line after another, when a high-level scan voltage SCAN is applied to a pixel 41g of interest, the writing transistor TR1 turns on. Now, the voltage at the node N_{A} rises to become equal to the data voltage DATA supplied to the data voltage line 43g (that is, the data voltage DATA is written), and correspondingly, through the coupling provided by the capacitor C1, the voltage at the node N_{B} becomes ready to rise by the same voltage. In reality, however, since the adjustment transistor TR35 is on, the positive electric charge at the node N_{B} is extracted via the adjustment transistor TR35 and the organic EL element 42, and the voltages at the nodes N_{B} and N_{C} stabilize at a voltage (feedback voltage) higher than the supply voltage CV by the voltage V_{F}. Here, the relationship “(CV+V_{F})>VSS” holds. Now, the capacitor C1 holds a voltage (DATA−CV−V_{F}), that is a voltage (held voltage) commensurate with the voltage V_{F} and the data voltage DATA. Moreover, as will be understood from the V_{OLED}-I_{OLED} characteristic of the organic EL element 42 shown in FIG. 18, the voltage V_{F} indicated by the broken line 65g, which represents the case where a time-related variation or the like is present, is higher than that indicated by the solid line 62g.

The ramp voltage RAMP2 is turned to a voltage lower than (CV+V_{F}), and the adjustment transistor TR35 is turned off. During the light emission period P_{L1}, the ramp voltage RAMP1 is fed to the data voltage line 43g, and, as soon as the light emission period P_{L1} begins, the scan voltages for all the pixels are turned high. Thus, during the light emission period P_{L1}, the voltage at the node N_{A} is equal to ramp voltage RAMP1. Incidentally, the scan voltage SCAN is kept high until the end of the reset period P_{R2}.

When the light emission period P_{L1} begins, as a result of the ramp voltage RAMP 1, in place of the data voltage DATA, being applied to the data voltage line 43g, or as a result of the ramp voltage RAMP1 applied to the data voltage line 43g rising abruptly by a previously set voltage, the voltage at the node N_{A} rises abruptly. The purpose is to maximize the proportion of the duration for which the organic EL element 42 actually emits light during the light emission period P_{L1}. This abrupt rise of the voltage at the node N_{A} causes the voltage at the node N_{B} to rise by the same voltage (see the solid line 62g and the broken line 65g). Thereafter, as described previously, the ramp voltages RAMP1 and RAMP2 increase linearly at previously set fixed rates.

When the voltage at the node N_{B} becomes equal to the voltage (CV+V_{F}+Vth), a current start to flow through the organic EL element 42. The current that has started to flow through the organic EL element 42 during the light emission period P_{L1} then increases gradually. When the ramp voltage RAMP2 becomes equal to the sum of the voltage at the node N_{C} and the operation threshold voltage (Vth) of the adjustment transistor TR35, the adjustment transistor TR35 turns on, and the driving transistor TR23 turns off, causing the organic EL element 42 to stop emitting light. Since, at the beginning of the light emission period P_{L1}, (the voltages at the nodes N_{B} and N_{C} as indicated by the broken lines 65g and 84g)>(the voltages at the nodes N_{B} and N_{C} as indicated by the solid lines 62g and 81g), light emission ends later in the case indicated by the broken lines 65g and 84g. This, in the first field, compensates for the decrease in the current I_{OLED} resulting from an increase in the voltage V_{F}.

After the end of the light emission, while the voltages at the nodes N_{B} and N_{C} remains equal, the reset period P_{R2} of the second field begins. In the middle of the reset period P_{R2}, the ramp voltage RAMP1 falls abruptly, and the voltage at the node N_{A} also falls abruptly (see the solid line 61g).

The abrupt fall in the voltage at the node N_{A} is transmitted via the capacitor C1 to the node N_{B}, and, while this transmission is taking place, the control signal CTL1 remains high and thus the clipping transistor TR8 remains on. This makes the voltage at the node N_{B} equal to the supply voltage VSS. Meanwhile, the ramp voltage RAMP2, starting in the light emission period P_{L1}, keeps rising. This makes also the voltage at the node N_{C} equal to the supply voltage VSS. After the voltages at the nodes N_{B} and N_{C} become equal to the supply voltage VSS, the ramp voltage RAMP2 falls to a voltage that turns the adjustment transistor TR35 off. The control signal CTL1, which is turned high in the middle of the reset period P_{R2}, remains high until the end of the scan period P_{S2}, and is then turned low during the light emission period P_{L2}.

Here, the supply voltage VSS is set approximately equal to the sum of the supply voltage CV and the voltage V_{F} in the initial state (that is, the voltage V_{F0}). Moreover, during the scan period P_{S2}, the ramp voltage RAMP2 is kept a comparatively low voltage that keeps the adjustment transistor TR35 off. Thus, in the second field, no voltage (feedback voltage) commensurate with the voltage V_{F} is transmitted to the capacitor C1.

Subsequent to the reset period P_{R2}, during the scan period P_{S2}, when a high-level scan voltage SCAN is applied to the pixel 41g of interest, the writing transistor TR1 turns on. Now, the voltage at the node N_{A} rises to become equal to the data voltage DATA being supplied to the data voltage line 43g (that is, the data voltage DATA is written). Here, however, since the clipping transistor TR8 is on, the voltage at the node N_{B} is kept equal to VSS. Moreover, as in the seventh embodiment, the data voltage DATA written to each pixel in the second field is, in principle, different from that written thereto in the first field.

After the data voltage DATA is written, the scan voltage SCAN applied to the pixel 41g of interest is turned back low. When data voltages are written to all the pixels 41g constituting the display panel 4f, the scan period P_{S2} ends, and the light emission period P_{L2} begins.

During the light emission period P_{L2}, the ramp voltage RAMP1 is supplied to the data voltage line 43g, and, as soon as the light emission period P_{L2} begins, the scan voltages SCAN for all the pixels are turned high. Thus, during the light emission period P_{L2}, the voltage at the node N_{A} is equal to the ramp voltage RAMP1. Incidentally, the scan voltage SCAN is kept high until the end of the reset period P_{R1} of the (k+1)th frame.

When the light emission period P_{L2} begins, as a result of the ramp voltage RAMP 1, in place of the data voltage DATA, being applied to the data voltage line 43g, or as a result of the ramp voltage RAMP1 applied to the data voltage line 43g rising abruptly by a previously set voltage, the voltage at the node N_{A} rises abruptly. The purpose is to maximize the proportion of the duration for which the organic EL element 42 actually emits light during the light emission period P_{L2}. This abrupt rise of the voltage at the node N_{A} causes the voltage at the node N_{B} to rise by the same voltage (see the solid line 62g). Thereafter, as described previously, the ramp voltages RAMP1 and RAMP2 increase linearly at previously set fixed rates.

When the voltage at the node N_{B} becomes equal to the voltage (VSS+Vth), a current start to flow through the organic EL element 42. The current that has started to flow through the organic EL element 42 during the light emission period P_{L2} then increases gradually. When the ramp voltage RAMP2 becomes equal to the sum of the voltage at the node N_{C} and the operation threshold voltage (Vth) of the adjustment transistor TR35, the adjustment transistor TR35 turns on, and the driving transistor TR23 turns off, causing the organic EL element 42 to stop emitting light. After the end of the light emission, the light emission period P_{L2} ends, and the (k+1)th reset period P_{R1} begins, during which operations similar to those described above are repeated.

As described previously, the operation threshold voltages of the driving transistor TR23 and the adjustment transistor TR35 are approximately equal. Thus, variations in the operation threshold voltages of the two transistors TR23 and TR35 do not influence the light emission duration of the organic EL element 42. Moreover, the adjustment transistor TR35 also functions as a turning-off transistor.

### Ninth Embodiment

A ninth embodiment of the present invention as applied to an organic EL display device will be described below. The overall configuration of the organic EL display device of the ninth embodiment of the present invention is substantially the same as that shown in FIG. 20; therefore, no separate diagram is furnished in that aspect. Here, the individual circuit blocks constituting the organic EL display device are so modified as to realize, as desired in this embodiment, the operation described below.

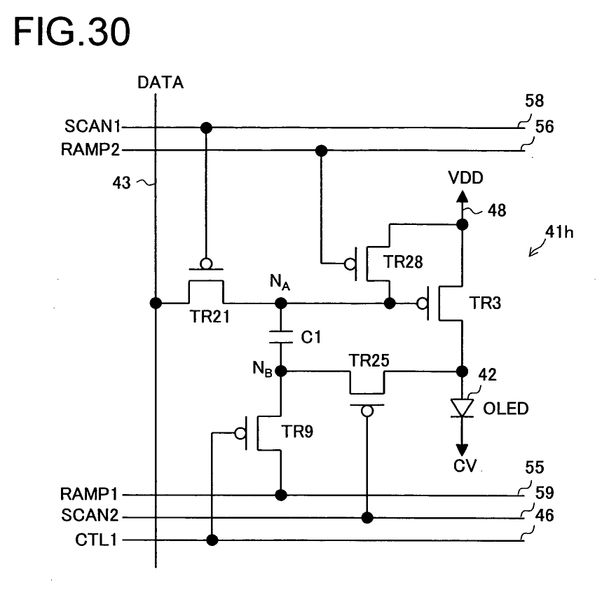

The display panel 4f is so modified that each pixel 41h constituting it is built with a pixel circuit configured as shown in FIG. 30. In FIG. 30, such elements as are found also in FIG. 21 are identified with common reference numerals and symbols, and no overlapping explanations will be repeated.

The circuit configuration of the pixel 41h will be described below. The pixel circuit constituting each pixel 41h includes: an organic EL element 42; a writing transistor TR21; a driving transistor TR3; an adjustment transistor TR25, a turning-off transistor TR28; a transistor TR9; and a capacitor C1 (first capacitive element). The driving transistor TR3 and the turning-off transistor TR28 are formed simultaneously on a single semiconductor substrate by a single process, and are formed close together within a single pixel 41h. Thus, the operation threshold voltages of the driving transistor TR3 and the turning-off transistor TR28 are approximately equal, being Vth.

The writing transistor TR21, the adjustment transistor TR25, the turning-off transistor TR28, and the transistor TR9 are, like the driving transistor TR3, built as P-channel MOS transistors formed as thin-film transistors (TFTs). In this embodiment the scan driver 2f feeds each pixel with two scan voltages SCAN1 and SCAN2. When the scan voltage SCAN 1 is low or high, the writing transistor TR21 is on or off, respectively. When the scan voltage SCAN2 is low or high, the adjustment transistor TR25 is on or off, respectively.

The first electrode (for example, source) of the writing transistor TR21 is connected to a data voltage line 43 to which a data voltage DATA from the data driver 3f is applied. The second electrode (for example, drain) of the writing transistor TR21 is connected to one electrode of the capacitor C1, to the gate of the driving transistor TR3, and to the drain of the turning-off transistor TR28. The gate of the writing transistor TR21 is connected to a scan voltage line 58 to which the scan voltage SCAN1 is applied.

The first electrode (for example, source) of the adjustment transistor TR25 is connected to the drain of the driving transistor TR3 and to the anode of the organic EL element 42. The second electrode (for example, drain) of the adjustment transistor TR25 is connected to the other electrode of the capacitor C1 and to the first electrode (for example, source) of the transistor TR9. The gate of the adjustment transistor TR25 is connected to a scan voltage line 59 to which the scan voltage SCAN2 is applied. A positive-side supply voltage VDD is applied via a power supply line 48 to the sources of the driving transistor TR3 and the turning-off transistor TR28. The gate of the turning-off transistor TR28 is connected to a ramp voltage line 56 to which a ramp voltage RAMP2 from the ramp voltage generation circuit 8f is applied. The second electrode (for example, drain) of the transistor TR9 is connected to a ramp voltage line 55 to which a ramp voltage RAMP1 from the ramp voltage generation circuit 8f is applied. The gate of the transistor TR9 is connected to a control signal line 46 to which a control signal CTL1 is applied. A negative-side supply voltage CV is applied to the cathode of the organic EL element 42.

In the pixel 41h, the node between the second electrode of the writing transistor TR21 and one electrode of the capacitor C1 will be referred to as the node N_{A}, and the node between the second electrode of the adjustment transistor TR25 and the other electrode of the capacitor C1 will be referred to as the node N_{B}.

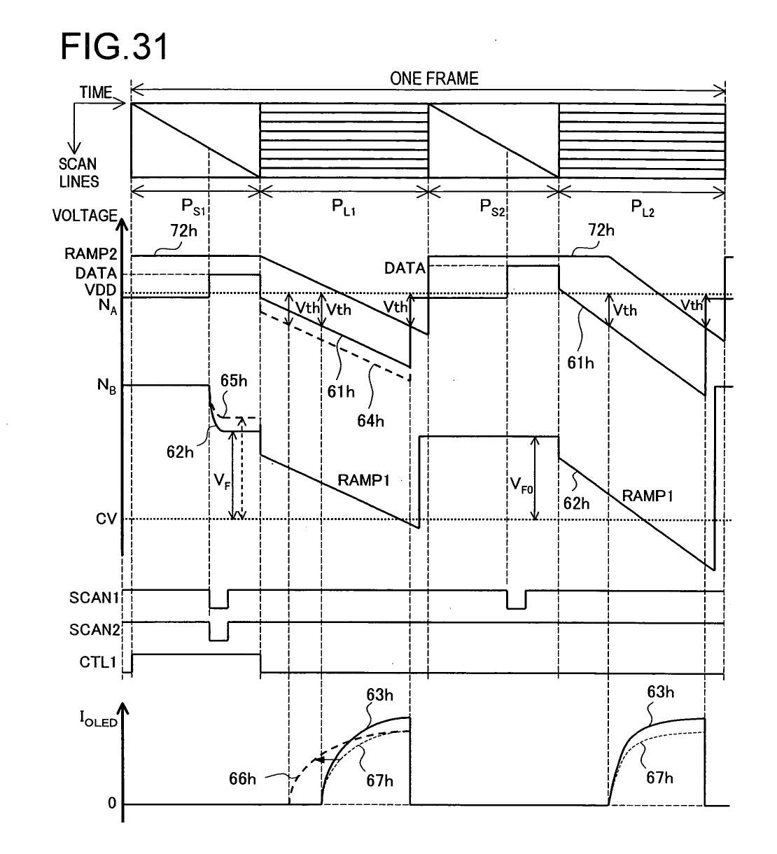

Now, with reference to FIG. 31, the operation of the organic EL display device of the ninth embodiment will be described. FIG. 31 shows the voltages at relevant points in FIG. 30 and the current I_{OLED} through the organic EL element 42 as observed over one frame period. The period for the display of one screen, that is, one frame period (the reciprocal of the frame frequency), consists of two fields, namely a first field and a second field. As shown in FIG. 31, the first field consists of a scan period P_{S1} and a light emission period P_{L1}, and the second field consists of a scan period P_{S2} and a light emission period P_{L2}.

Since the scan period P_{S1} is a period during which the organic EL element 42 is made ready to emit light during the light emission period P_{L1}, it can be called a light emission preparation period in the first field. Since the scan period P_{S2} is a period during which the organic EL element 42 is made ready to emit light during the light emission period P_{L2}, it can be called a light emission preparation period in the second field.

Also in this embodiment, to solve the previously mentioned problem of black level deterioration, during, of the first and second fields, only the first field, the current I_{OLED} is compensated for a variation in the voltage V_{F}; moreover, the LUT 9 feeds the gradation signal to the data driver 3f after converting it into a first converted gradation signal corresponding to the first field and a second converted gradation signal corresponding to the second field in such a way that a relationship similar to that realized in the seventh embodiment (FIGS. 23 to 27) is realized between the level of gradation specified by the gradation signal and the effective value of the current I_{OLED} Thus, advantages similar to those achieved in the seventh embodiment are achieved here.

When the kth (where k is a natural number) frame period ends, subsequently the (k+1)th frame begins, during the period of which the scan period P_{S1}, the light emission period P_{L1}, the scan period P_{S2}, and the light emission period P_{L2} occur in this order.

A solid line 72h represents the voltage waveform of the ramp voltage RAMP2 fed from the ramp voltage generation circuit 8f to the ramp voltage line 56. The ramp voltage RAMP2 is fixed at a previously set initial voltage during the scan period P_{S1} of the first field, and then decreases monotonically at a previously set variation rate (for example, −1 V per millisecond) during the light emission period P_{L1}. Then, during the scan period P_{S2} of the second field, the ramp voltage RAMP2 stops decreasing monotonically and turns back to the initial voltage. After having turned back to the initial voltage, the ramp voltage RAMP2 starts to decrease monotonically again in the middle of the light emission period P_{L2}, and then turns back to the initial voltage at the end of the light emission period P_{L2}. Here, the rate at which the ramp voltage RAMP2 decreases monotonically is greater during the light emission period P_{L2} than in the light emission period P_{L1}.

Likewise, the other ramp voltage RAMP1 decreases monotonically during each light emission period. The variation rates of the ramp voltages RAMP1 and RAMP2 during each light emission period is set, for example, equal. The lengths of the scan periods P_{S1} and P_{S2} are set, for example, equal. Likewise, the lengths of the light emission periods P_{L1} and P_{L2} are set, for example, equal. Needless to say, the lengths of the periods of either of these pairs may be made different.

Solid lines 61h and 62h represent the voltage waveforms observed at the nodes N_{A} and N_{B}, respectively, when the V_{OLED}-I_{OLED} characteristic of the organic EL element 42 is as indicated by the solid line 201 in FIG. 18. A solid line 63h represents the waveform of the current I_{OLED} that flows through the organic EL element 42 when the V_{OLED}-I_{OLED} characteristic of the organic EL element 42 is as indicated by the solid line 201 in FIG. 18.

Broken lines 64h and 65h represent the voltage waveforms observed at the nodes N_{A} and N_{B}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66h represents the waveform of the current I_{OLED} that flows through the organic EL element 42 when the V_{OLED}-I_{OLED} characteristic of the organic EL element 42 has shifted as indicated by the broken line 202 in FIG. 18. It should be noted that, in the second field, the solid line 61h and the broken line 64h are identical and thus overlap each other and likewise the solid line 62h and the broken line 65h are identical and thus overlap each other. Moreover, during the light emission period P_{L1}, the solid line 62h and the broken line 65h are identical and thus overlap each other.

A broken line 67h represents the waveform of the current I_{OLED} as observed when, in a case where a variation in the voltage V_{F} attributable to a time-related variation or the like in the organic EL element 42 is not fed back, the current I_{OLED} has decreased because of a time-related variation or the like. In the second field, the broken line 66h and the broken line 67h are identical and thus overlap each other.

The control signal CTL1 remains high during the scan period P_{S1}, and remains low during the scan period P_{S2} and the light emission period P_{L1} and P_{L2}. Thus, during the scan period P_{S2} and the light emission period P_{L1} and P_{L2}, the voltage at the node N_{B} is equal to the ramp voltage RAMP 1.

The following description of the operation starts with the scan period P_{S1} of the kth frame period. During the light emission period P_{L2} of the (k−1)th frame, the ramp voltage RAMP1 ends as a comparatively high voltage, and this comparatively high voltage is held at the node N_{B} when the scan period P_{S1} of the kth frame period starts. The voltage held here is higher than (CV+V_{F}).

During the kth scan period P_{S1}, a low-level scan voltage SCAN1 is applied to one scan line after another, and, when a low-level scan voltage SCAN1 is applied to a pixel 41h of interest, the writing transistor TR21 turns on. This causes the voltage at the node N_{A} to rise to become equal to the data voltage DATA fed to the data voltage line 43 (that is, the data voltage DATA is written). Moreover, at the same time that the scan voltage SCAN1 turns low, the scan voltage SCAN2 is also turned low. As a result, part of the electric charge (positive electric charge) at the node N_{B}, at which the potential is now temporarily higher than the potential represented by (CV+V_{F}), is extracted through the adjustment transistor TR25 and the organic EL element 42, and thus the voltage appearing at the node N_{B} stabilizes at a voltage (feedback voltage) higher than the supply voltage CV by the voltage V_{F}.

When the potential at the node N_{B} stabilizes, the scan voltage SCAN2 is turned high to turn the adjustment transistor TR25 off. Now, the capacitor C1 holds the voltage (DATA−CV−V_{F}), that is, a voltage (held voltage) commensurate with the data voltage DATA and the voltage V_{F}. Moreover, as will be understood from the V_{OLED}-I_{OLED} characteristic of the organic EL element 42 shown in FIG. 18, the voltage V_{F} indicated by the broken line 65h, which represents the case where a time-related variation or the like is present, is higher than that indicated by the solid line 62h. Moreover, at the same time that the scan voltage SCAN2 turns high, the scan voltage SCAN1 is turned high. Thereafter, the scan voltages SCAN1 and SCAN2 are kept high until the end of the light emission period P_{L1}. When data voltages are written to all the pixels 41h constituting the display panel 4f, the scan period P_{S1} ends, and the light emission period P_{L1} begins.

When the light emission period P_{L1} begins, the control signal CTL1 is turned low to turn the transistor TR9 on, and thus the ramp voltage RAMP1 is applied to the node N_{B}. As a result of the ramp voltage RAMP1 being applied to the node N_{B}, or as a result of, at the same time that the transistor TR9 is turned on, the ramp voltage RAMP1 falling abruptly by a previously set voltage, the voltage at the node N_{B} falls abruptly. The fall of the voltage at the node N_{B} causes the voltage at the node N_{A} to fall by the same voltage. Here, since (the voltage V_{F} as indicated by the broken line 65h)>(the voltage V_{F} as indicated by the solid line 62h), the following relationship holds: (the voltage at the node N_{A} as indicated by the broken line 64h)<(the voltage at the node N_{A} as indicated by the solid line 61h).

Here, since (the voltage at the node N_{A} as indicated by the broken line 64h)<(the voltage at the node N_{A} as indicated by the solid line 61h), light emission starts earlier in the case indicated by the broken line 64h. The current that has started to flow through the organic EL element 42 during the light emission period P_{L1} then increases gradually. Then, when the ramp voltage RAMP2 becomes equal to or lower than the voltage (VDD−Vth), the turning-off transistor TR28 turns on, and causes the voltage at the node N_{A} to rise to the positive-side supply voltage VDD. This turns the driving transistor TR3 off, and thus causes the organic EL element 42 to stop emitting light.

Thereafter, as described previously, the ramp voltages RAMP1 and RAMP2 decreases linearly at the previously set fixed rates. When the voltage at the node N_{A} becomes equal to or lower than the voltage (VDD−Vth), a current starts to flow through the organic EL element 42. Here, since, at the beginning of the light emission period P_{L1}, (the voltage at the node N_{A} as indicated by the broken line 64h)<(the voltage at the node N_{A} as indicated by the solid line 61h), light emission starts earlier in the case indicated by the broken line 64h. The current that has started to flow through th organic EL element 42 during the light emission period P_{L1} then increases gradually. Then, when the ramp voltage RAMP2 becomes equal to or lower than the voltage (VDD−Vth), the turning-off transistor TR28 turns on, and thus causes the voltage at the node N_{A} to rise to the positive-side supply voltage VDD. This causes the driving transistor TR3 to turn off, and thus causes the organic EL element 42 to stop emitting light.

After the end of the light emission, the ramp voltage RAMP1 rises abruptly to a predetermined voltage. This voltage is set approximately equal to the sum of the negative-side supply voltage CV and the voltage V_{F} in the initial state (that is, the voltage V_{F0}). Thereafter, the light emission period P_{L1} ends, and the scan period P_{S2} of the second field begins.

During the scan period P_{S2}, when a low-level scan voltage SCAN1 is applied to the pixel 41h of interest, the writing transistor TR21 turns on. Now, the voltage at the node N_{A} rises to become equal to the data voltage DATA being applied to the data voltage line 43 (that is, the data voltage DATA is written). Here, unlike in the first filed, the scan voltage SCAN2 is not turned low but kept high. Thus, no voltage (feedback voltage) commensurate with the voltage V_{F} is transmitted to the capacitor C1. Moreover, as in the seventh embodiment, the data voltage DATA written to each pixel in the second field is, in principle, different from that written thereto in the first field.

After the data voltage DATA is written, the scan voltage SCAN applied to the pixel 41h of interest is turned back high. When data voltages are written to all the pixels 41h constituting the display panel 4f, the scan period P_{S2} ends, and the light emission period P_{L2} begins. When the light emission period P_{L2} begins, the ramp voltage RAMP1 falls abruptly by a previously set voltage, and this causes the voltages at the nodes N_{A} and N_{B} to fall by the same voltage. Thereafter, as described previously, the ramp voltages RAMP1 and RAMP2 decrease linearly at previously set fixed variation rates.

When the voltage at the node N_{A} becomes equal to or lower than the voltage (VDD−Vth), a current starts to flow through the organic EL element 42, and this current increases gradually during the light emission period P_{L2}. Moreover, as indicated by the solid line 72h, the ramp voltage RAMP2 starts to decrease monotonically again in the middle of the light emission period P_{L2}. Then, when the ramp voltage RAMP2 becomes equal to or lower than the voltage (VDD−Vth), the turning-off transistor TR28 turns on, and thus causes the voltage at the node N_{A} to rise to the positive-side supply voltage VDD. This turns the driving transistor TR3 off, and thus causes the organic EL element 42 to stop emitting light. After the end of the light emission, the ramp voltage RAMP1 increases to a comparatively high voltage as described previously. When the light emission period P_{L2} ends, the (k+1)th scan period P_{S1} begins, during which operations similar to those described above are repeated.

As described previously, the operation threshold voltages (Vth) of the driving transistor TR3 and the turning-off transistor TR28 are approximately equal. Thus, variations in the operation threshold voltages of the two transistors TR3 and TR28 do not influence the light emission duration of the organic EL element 42.

In a case where the driving transistor TR3 is of a P-channel type, because of the characteristics thereof, the more abruptly the ramp voltage RAMP1 is changed, and thus the faster a current is made to rise, the larger the amount of light obtained. However, changing the ramp voltage RAMP1 abruptly to make a current to flow early in the first field leads, through the feedback of a variation in the voltage V_{F}, to black level deterioration. To avoid this, in this embodiment, the ramp voltage RAMP1 is changed abruptly only in the second field.

### Tenth Embodiment

A tenth embodiment of the present invention as applied to an organic EL display device will be described below. The overall configuration of the organic EL display device of the tenth embodiment of the present invention is substantially the same as that shown in FIG. 20; therefore, no separate diagram is furnished in that aspect. Here, the individual circuit blocks constituting the organic EL display device are so modified as to realize, as desired in this embodiment, the operation described below.

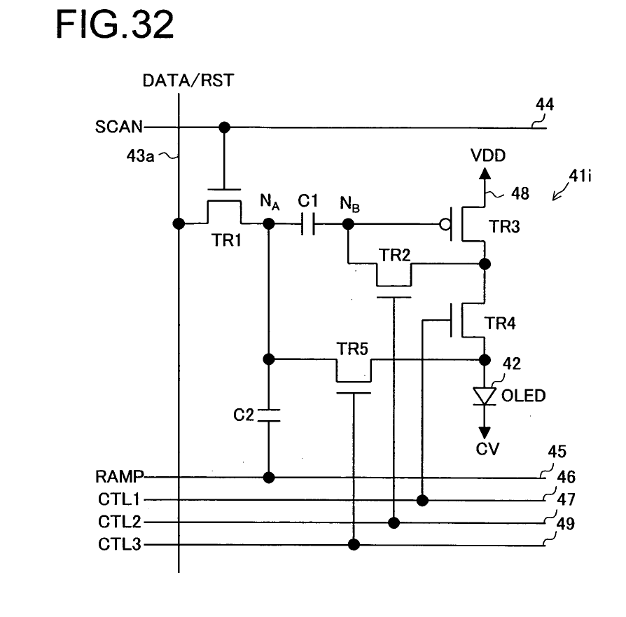

The display panel 4f is so modified that each pixel 41i constituting it is built with a pixel circuit configured as shown in FIG. 32. In FIG. 32, such elements as are found also in FIGS. 2 and 21 are identified with common reference numerals and symbols, and no overlapping explanations will be repeated. In this embodiment, the control signal generation circuit 5f feeds each pixel 41i not only with a control signal CTL1 but also with control signals CTL2 and CTL3. In this embodiment, the ramp voltage generation circuit 8f feeds the pixel 41i with a ramp voltage RAMP.

The circuit configuration of the pixel 41i is similar to that of the pixel 41 shown in FIG. 2. The pixel 41i (the pixel circuit of the pixel 41i) differs from the pixel 41 (the pixel circuit of the pixel 41) shown in FIG. 2 in the following respects: the first electrode (for example, the source) of the writing transistor TR1 is connected to a data voltage line 43a to which a data voltage DATA is applied with predetermined timing and to which a reset voltage RST (this reset voltage RST has a previously set voltage) is applied with other predetermined timing; and the gate of the adjustment transistor TR5 is connected not to the control signal line 47 but to a control signal line 49 to which the control signal CTL3 is applied. Otherwise, the configuration here is identical with that of the pixel 41, and therefore no description will be given of common features. The control signal CTL2 is fed to the gate of the threshold value compensation transistor TR2.

When the scan voltage SCAN fed to the scan voltage line 44 is low or high, the writing transistor TR1 is off or on, respectively. When the control signal CTL1 is low or high, the on/off transistor TR4 is off or on, respectively. When the control signal CTL2 is low or high, the threshold value compensation transistor TR2 is off or on, respectively. When the control signal CTL3 is low or high, the adjustment transistor TR5 is off or on, respectively.

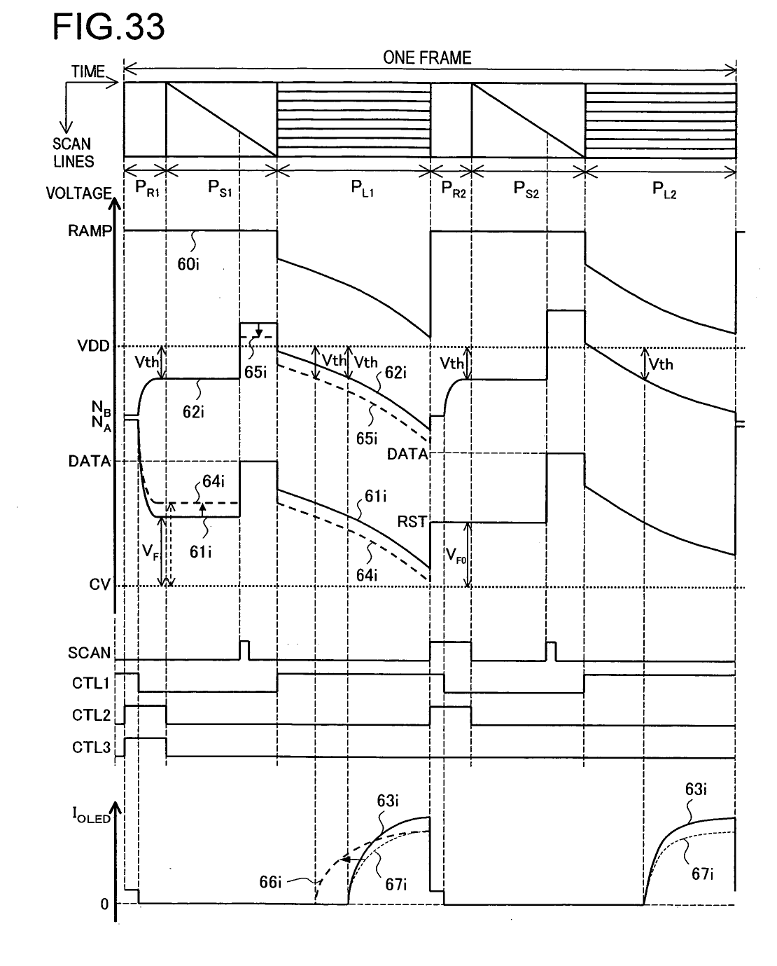

Now, with reference to FIG. 33, the operation of the organic EL display device of the tenth embodiment will be described. FIG. 33 shows the voltages at relevant points in FIG. 32 and the current I_{OLED} through the organic EL element 42 as observed over one frame period. The period for the display of one screen, that is, one frame period (the reciprocal of the frame frequency), consists of two fields, namely a first field and a second field. As in the seventh embodiment, the first field consists of a reset period P_{R1}, a scan period P_{S1}, and a light emission period P_{L1}, and the second field consists of a reset period P_{R1}, a scan period P_{S2}, and a light emission period P_{L2}.

Also in this embodiment, to solve the previously mentioned problem of black level deterioration, during, of the first and second fields, only the first field, the current I_{OLED} is compensated for a variation in the voltage V_{F}; moreover, the LUT 9 feeds the gradation signal to the data driver 3f after converting it into a first converted gradation signal corresponding to the first field and a second converted gradation signal corresponding to the second field in such a way that a relationship similar to that realized in the seventh embodiment (FIGS. 23 to 27) is realized between the level of gradation specified by the gradation signal and the effective value of the current I_{OLED}. Thus, advantages similar to those achieved in the seventh embodiment are achieved here.

A solid line 60i represents the voltage waveform of the ramp voltage RAMP fed from the ramp voltage generation circuit 8f to the ramp voltage line 45. The ramp voltage RAMP is kept fixed at a previously set initial voltage during the reset period and scan period of each field (that is, P_{R1}, R_{S1}, P_{R2}, and P_{S2}), and decreases at previously set variation rates during the light emission period of each field (that is, P_{L1} and P_{L2}). Then, during the reset period of each field (that is, P_{R1} and P_{R2}), the ramp voltage RAMP stops decreasing, and turns back to the initial voltage.

Solid lines 61i and 62i represent the voltage waveforms observed at the nodes N_{A} and N_{B}, respectively, when the V_{OLED}-I_{OLED} characteristic of the organic EL element 42 is as indicated by the solid line 201 in FIG. 18. A solid line 63i represents the waveform of the current I_{OLED} that flows through the organic EL element 42 when the V_{OLED}-I_{OLED} characteristic of the organic EL element 42 is as indicated by the solid line 201 in FIG. 18.

Broken lines 64i and 65i represent the voltage waveforms observed at the nodes N_{A} and N_{B}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66i represents the waveform of the current I_{OLED} that flows through the organic EL element 42 when the V_{OLED}-I_{OLED} characteristic of the organic EL element 42 has shifted as indicated by the broken line 202 in FIG. 18. It should be noted that, in the second field, the broken line 61i and the broken line 64i are identical and thus overlap each other and likewise the solid line 62i and the broken line 65i are identical and thus overlap each other.

A broken line 67i represents the waveform of the current I_{OLED} as observed when, in a case where a variation in the voltage V_{F} attributable to a time-related variation or the like in the organic EL element 42 is not fed back, the current I_{OLED} has decreased because of a time-related variation or the like. In the second field, the broken line 66i and the broken line 67i are identical and thus overlap each other.

The scan voltage SCAN is kept low during each light emission period (that is, P_{L1} and P_{L2}) and during the reset period P_{R1}, and is kept high during the reset period P_{R2}. The control signal CTL1 is kept low during each scan period (that is, P_{S1} and P_{S2}), and is kept high during each light emission period. The control signal CTL2 is kept low during each scan period and during each light emission period, and is kept high during each reset period (that is, P_{R1} and P_{R2}). The control signal CTL3 is kept high during the reset period P_{R1}, and is kept low otherwise. The reset voltage RST(=(CV+V_{F0})) is applied to the data voltage line 43a only during the reset period P_{R2} of the second field, and the data voltage DATA from the data driver 3f is applied thereto otherwise.

The following description of the operation starts with the reset period P_{R1} of the kth frame period. During the reset period P_{R1} of the first field, a voltage program driving method is used, so that the variation in the operation threshold voltage Vth of the driving transistor TR3 is absorbed. Specifically, during the reset period P_{R1}, while the control signals CTL2 and CTL3 are kept high, the control signal CTL1 is first kept high and is then turned low. This makes the voltages at the nodes N_{A} and N_{B} equal to (CV+V_{F}) and (VDD−Vth), respectively. Now, the capacitor C1 holds a voltage represented as (VDD−CV−Vth−V_{F}). Moreover, as will be understood from the V_{OLED}-I_{OLED} characteristic of the organic EL element 42 shown in FIG. 18, the voltage V_{F} indicated by the broken line 64i, which represents the case where a time-related variation or the like is present, is higher than that indicated by the solid line 61i.

After the reset period P_{R1} ends, during the scan period P_{S1}, when a high-level scan voltage SCAN is applied to a pixel 41iof interest, the writing transistor TR1 turns on. Now, the voltage at the node N_{A} rises to become equal to the data voltage DATA fed to the data voltage line 43a (that is, the data voltage DATA is written), and corresponding, through the coupling provided by the capacitor C1, the voltage at the node N_{B} rises by the same voltage. Here, the voltage by which the voltages at the nodes N_{A} and N_{B} rise equals (DATA−V_{F}−CV). Thus, the voltage at the node N_{B} (that is, the gate voltage of the driving transistor TR3) equals (VDD−CV+DATA−V_{F}−Vth).

Here, since (the voltage V_{F} as indicated by the broken line 64i)>(the voltage V_{F} as indicated by the solid line 61i), once the data voltage DATA is written, the following relationship holds: (the voltage at the node N_{B} as indicated by the broken line 65i)<(the voltage at the node N_{B} as indicated by the solid line 62i). After the data voltage DATA is written, the scan voltage SCAN applied to the pixel 41iof interest is turned back low. When data voltages are written to all the pixels 41i constituting the display panel 4f, the scan period P_{S1} ends, and the light emission period P_{L1} begins.

When the light emission period P_{L1} begins, the ramp voltage RAMP falls abruptly by a previously set voltage. The purpose is to maximize the proportion of the duration for which the organic EL element 42 actually emits light during the light emission period P_{L1}. This abrupt fall of the ramp voltage RAMP causes the potentials at the nodes N_{A} and N_{B} to fall by the same voltage. Thereafter, as described previously, the ramp voltage RAMP decreases at the previously set variation rate.

When the voltage at the node N_{B} becomes equal to or lower than the voltage (VDD−Vth), a current starts to flow through the organic EL element 42. Here, since, at the beginning of the light emission period P_{L1}, (the voltage at the node N_{B} as indicated by the broken line 65i)<(the voltage at the node N_{B} as indicated by the solid line 62i), light emission starts earlier in the case indicated by the broken line 65i. Moreover, the current that has started to flow through the organic EL element 42 during the light emission period P_{L1} increases gradually.

At the transition from the light emission period P_{L1} to the reset period P_{R2}, the scan voltage SCAN and the control signal CTL2 are turned high. Starting in the light emission period P_{L1}, the control signal CTL1 is kept high until a midpoint during the reset period P_{R2}. At the midpoint, the control signal CTL1 is turned low. During the reset period P_{R2}, since the reset voltage RST is fed to the data voltage line 43a, the voltage at the node N_{A} equals the reset voltage RST. This reset voltage RST is set approximately equal to the sum of the negative-side supply voltage CV and the voltage V_{F} in the initial state (that is, the voltage V_{F0}). At the end of the reset period P_{R2}, the voltage at the node N_{B} equals (VDD−Vth), and the scan voltage SCAN and the control signal CTL2 are turned low.

Subsequent to the reset period P_{R}₂, during the scan period P_{S2}, when a high-level scan voltage SCAN is applied to the pixel 41iof interest, the writing transistor TR1 turns on. Now, the voltage at the node N_{A} rises to become equal to the data voltage DATA fed to the data voltage line 43a (that is, the data voltage DATA is written). Moreover, as in the seventh embodiment, the data voltage DATA written to each pixel in the second field is, in principle, different from that written thereto in the first field.

After the data voltage DATA is written, the scan voltage SCAN applied to the pixel 41iof interest is turned back low. When data voltages are written to all the pixels 41i constituting the display panel 4f, the scan period P_{S2} ends, and the light emission period P_{L2} begins. When the light emission period P_{L2} begins, as at the beginning of the light emission period P_{L1}, the ramp voltage RAMP falls abruptly by a previously set voltage. This abrupt fall of the ramp voltage RAMP causes the potentials at the nodes N_{A} and N_{B} to fall by the same voltage. Thereafter, as described previously, the ramp voltage RAMP decreases at the previously set variation rate.

During the light emission period P_{L2}, when the voltage at the node N_{B} becomes equal to or lower than the voltage (VDD−Vth), a current starts to flow through the organic EL element 42. At the transition from the light emission period P_{L2} to the reset period P_{R1} of the next frame, the ramp voltage RAMP is turned back to the initial voltage, and then, in the next frame, operations similar to those described above are repeated.

Unlike the seventh to ninth embodiments, this embodiment adopts a method of absorbing the variation in the operation threshold voltage of the driving transistor TR3 by the use of the threshold value compensation transistor TR2. Thus as indicated by the solid line 60i in FIG. 33, during each light emission period, the variation rate of the ramp voltage RAMP can be varied with time. That is, the ramp voltage RAMP may be given a desired curvature to conform to the gamma characteristic of the display panel 4f. This applies also to other configuration (for example, the first and second embodiments) where the variation in the operation threshold voltage of the driving transistor is absorbed by the use of the threshold value compensation transistor.

For example, even in a case where a display panel 4f is adopted that has such a characteristics that, as indicated by a dash-dot line 460 in FIG. 27, the effective value of the current I_{OLED} increases exponentially from the black level t_{B} of gradation to an intermediate level t₁ and then increases linearly from the intermediate level t₁ to the white level t_{W} of gradation, by given the ramp voltage RAMP an appropriate curvature, it is possible to obtain a characteristic in which the effective value of the current I_{OLED} increases exponentially from the black level t_{B} of gradation to the white level t_{W} of gradation (that is, it is possible to convert a characteristic as indicated by the dash-dot line 460 in FIG. 27 to a characteristic as indicated by the broken line 400 in FIG. 23).

A practical example of this is indicated by the solid line 60i in FIG. 33. During the light emission period P_{L1} of the first field, the ramp voltage RAMP decreases at an increasingly high variation rate toward the reset period P_{R2}. That is, during the light emission period P_{L1}, the variation rate of the ramp voltage RAMP is higher in the latter part of the period than in the first part thereof. On the other hand, during the light emission period P_{L2} of the second field, the ramp voltage RAMP decreases at an increasingly low variation rate toward the reset period P_{R1} of the next frame. That is, during the light emission period P_{L2}, the variation rate of the ramp voltage RAMP is lower in the latter part of the period than in the first part thereof.

It should be understood, however, that, in this embodiment, it is not essential to vary with time the variation rate of the ramp voltage RAMP. That is, as in the seventh to ninth embodiments, the variation rate of the ramp voltage RAMP during each light emission period may be kept fixed.

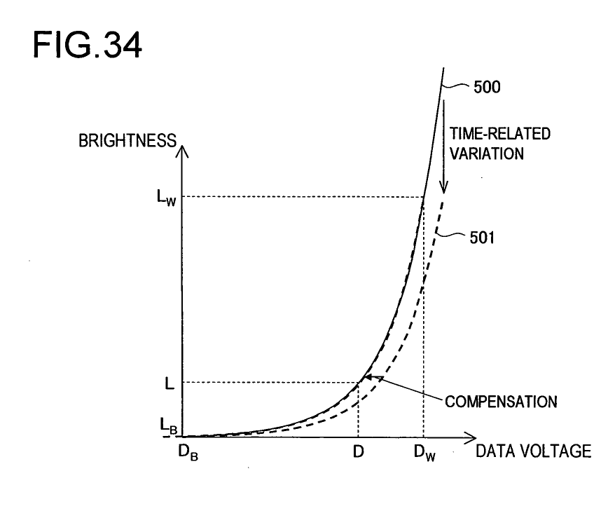

FIG. 34—RAMP Curvature

It is now clear that, by adopting a configuration where the variation in the operation threshold voltage of the driving transistor is absorbed by the use of the threshold value compensation transistor, it is possible to give the ramp voltage RAMP a desired curvature. With this understanding, the first or second embodiment described earlier can be modified as described below (this modification will hereinafter be referred to as Modified Example 2). FIG. 34 is a diagram illustrating Modified Example 2. The following description of Modified Example 2 deals with, of the first and second embodiments, only the first embodiment, but it should be understood that Modified Example 2 applies to the second embodiment as well.

In FIG. 34, the horizontal axis represents the data voltage fed from the data driver 3 to each pixel, and the vertical axis represents the brightness obtained as a result of the organic EL element 42 of each pixel emitting light according to the data voltage fed thereto. As will be understood from the description given earlier (refer to the seventh embodiment), the organic EL display device of the first (or second) embodiment displays an image by receiving a gradation signal (contained in an image signal) from an image source such as a television receiver (unillustrated). Thus, the level of gradation to be expressed at each pixel of the display panel 4 is specified by the gradation signal. The data driver 3 determines, for each pixel, the magnitude of the data voltage corresponding to the gradation signal fed from the image source (image signal processing circuit 6), and feeds the resulting data voltages to the individual pixels during the scan period (see FIGS. 1 to 3).

When a given gradation signal is fed to the data driver 3, the resulting data voltage has a magnitude corresponding to the level of gradation specified by the gradation signal. Let this magnitude be D (see FIG. 34). When a data voltage with a magnitude D is fed to a pixel 41 in its initial state, the organic EL element 42 emits light with brightness commensurate with the data voltage. Let this brightness be L. When the level of gradation specified by the gradation signal fed to the data driver 3 is the black or white level, the data voltage fed to a pixel 41 has a magnitude D_{B} or D_{W}, respectively. When a data voltage with a magnitude D_{B} or D_{W} is fed to a pixel 41 in its initial state, the organic EL element 42 emits light with brightness L_{B} or L_{W}, respectively. Moreover, let x=D−D_{B} and let y=L−L_{B}+1.

In this case, the variation rate of the ramp voltage RAMP during the light emission period is so set (that is, the ramp voltage RAMP is given such a curvature) as to fulfill formula (1) below in the initial state, and so is the conversion relationship between the gradation signal and the data voltage in the data driver 3. A solid line 500 in FIG. 34 represents the curve fulfilling formula (1) below.
y=a^{x} (1)

Here, “a” represents a constant that is set previously in the design stage of the organic EL display device and that fulfills a>1. For example, “a” is set equal to 2. Then, let “b” represent the degree of deterioration attributable to a time-related variation in the organic EL element 42. In the initial state, the degree of deterioration equals “1”. In a case where, as in the example of the conventional configuration shown in FIG. 16, the voltage V_{F} is not fed back, the degree of deterioration when the brightness corresponding to a given data voltage becomes ½, ⅓, ¼, . . . is assumed to be 2, 3, 4, . . . , respectively.

While, in the initial state, the relationship between “y” and “x” fulfills formula (1) above, when a time-related variation occurs in the organic EL element 42 in a case where the voltage V_{F} is not fed back, the relationship comes to fulfill formula (2) below. A broken line 501 in FIG. 34 represents the curve that fulfills formula (2) below.
y=a^{x}/b (2)

When a time-related variation occurs in the organic EL element 42, the brightness thereof diminishes not only because of a “drop in the current I_{OLED} resulting from an increase in the voltage V_{F}” but also because of a “drop in light emission efficiency”. The proportion of a drop in brightness attributable to a “drop in light emission efficiency” is equal at all levels of gradation. By contrast, in a case where the operating points of the driving transistor TR3 and the organic EL element 42 corresponding to the white level of gradation lie within the linear region of the Vds-Id characteristic of the driving transistor TR3, the proportion of a drop in brightness attributable to a “drop in the current I_{OLED} resulting from an increase in the voltage V_{F}” varies from one level of gradation to another.

Formula (2) above holds on the assumption that the proportion of a drop in brightness is equal at all levels of gradation; that is, when the proportion of a drop in brightness varies from one level of gradation to another, formula (2) above does not hold. Thus, for formula (2) above to hold, the operating points of the driving transistor TR3 and the organic EL element 42 corresponding to the white level of gradation need to be set within the saturation region of the Vds-Id characteristic of the driving transistor TR3.

In the first (or second) embodiment of the present invention, the voltage V_{F} is fed back so that, as described earlier, the driving transistor TR3 drives the organic EL element 42 with a voltage commensurate with the data voltage, the voltage V_{F}, and the operation threshold voltage Vth of the driving transistor. Feeding back the voltage V_{F} in this way is equivalent to adding to (or subtracting from) the data voltage the variation in the voltage V_{F} relative to its magnitude in the initial state, that is, a voltage represented as c=(V_{F}−V_{F0}). As described earlier, V_{F0} represents the V_{F} in the initial state.

That is, in the first embodiment as modified like Modified Example 2, while, in the initial state, the relationship between “x” and “y” fulfills formula (1) above, when a time-related variation occurs in the organic EL element 42, the relationship comes to fulfill formula (3

) below.
y=a^{(x+c)}/b=a^{x}·a^{c}/b (3)

In Modified Example 2, the configuration is so designed as to fulfill the formula “b=a^{c}”. That is, the value of “a” is determined according to the characteristics (time-related variation characteristics) of the organic EL element 42, the characteristics of the driving transistor TR3, and other factors in such a way as to fulfill the formula “b=a^{c}”. Consequently, formula (3) is identical with formula (1) above in the initial state.

That is, with Modified Example 2, it is possible to cancel a drop in brightness resulting from a “drop in light emission efficiency” (burn-in is compensated for) without the need to dividing a frame into two fields as in the tenth embodiment. It is also possible to avoid black level deterioration.

Moreover, in Modified Example 2, although it is preferable, from the viewpoint of alleviating black level deterioration, that the operating points of the driving transistor TR3 and the organic EL element 42 corresponding to the white level of gradation be set within the saturation region of the Vds-Id characteristic of the driving transistor TR3, those operating points may be set within the linear region of the Vds-Id characteristic of the driving transistor TR3. Even in this case, the variation rate of the ramp voltage RAMP during the light emission period is so set (the ramp voltage RAMP is given such a curvature) that formula (1) holds in the initial state, and so is the conversion relationship between the gradation signal and the data voltage in the data driver 3. In a case where the operating points corresponding to the white level lie within the linear region, however, when a time-related variation occurs in the organic EL element 42, formula (3) above does not hold in strict terms, resulting in slight black level deterioration.

The “initial state” denotes the state of the pixel 41 at the time of (or immediately after) its fabrication or at the time of its shipment. Making the organic EL element 42 emit light for a duration of the order of minutes to hours causes hardly any variation in the V_{EL}-I characteristic. Accordingly, the “initial state” includes any state in which the degree of deterioration of the organic EL element 42 relative to its state at the time of its fabrication or shipment can be ignored.

### Eleventh Embodiment

An eleventh embodiment of the present invention as applied to an organic EL display device will be described below. The overall configuration of the organic EL display device of the eleventh embodiment of the present invention is substantially the same as that shown in FIG. 20; therefore, no separate diagram is furnished in that aspect (it should however be noted that the ramp voltage generation circuit 8f is unnecessary here). Here, the individual circuit blocks constituting the organic EL display device are so modified as to realize, as desired in this embodiment, the operation described below.

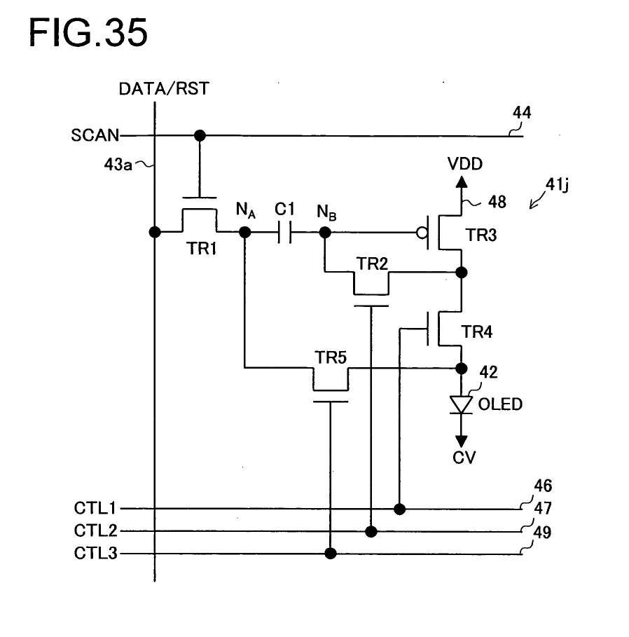

The display panel 4f is so modified that each pixel 41j constituting it is built with a pixel circuit configured as shown in FIG. 35. In FIG. 35, such elements as are found also in FIGS. 2, 21, and 32 are identified with common reference numerals and symbols, and no overlapping explanations will be repeated. In this embodiment, the control signal generation circuit 5f feeds each pixel 41j not only with a control signal CTL1 but also with control signals CTL2 and CTL3. In this embodiment, the display panel 4f is of a so-called analog drive type, and therefore no ramp voltage is fed to each pixel. This is the reason that the ramp voltage generation circuit 8f is unnecessary in this embodiment.

The circuit configuration of the pixel 41j is similar to that of the pixel 41i shown in FIG. 32. The pixel 41j (the pixel circuit of the pixel 41j) shown in FIG. 35 differs from the pixel 41i(the pixel circuit of the pixel 41i) shown in FIG. 32 in that the former lacks the capacitor C2 provided in the latter. Otherwise, the pixels of this and the tenth embodiments are identically configured, and therefore no overlapping explanations will be repeated.

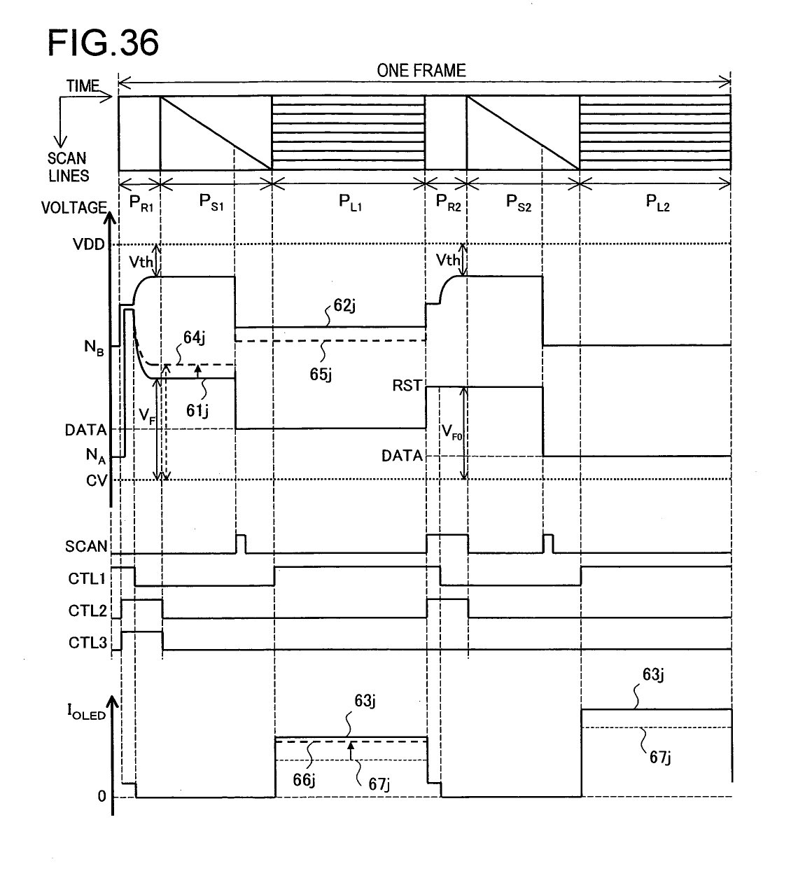

Now, with reference to FIG. 36, the operation of the organic EL display device of the eleventh embodiment will be described. FIG. 36 shows the voltages at relevant points in FIG. 35 and the current I_{OLED} through the organic EL element 42 as observed over one frame period. The period for the display of one screen, that is, one frame period (the reciprocal of the frame frequency), consists of two fields, namely a first field and a second field. As in the seventh embodiment, the first field consists of a reset period P_{R1}, a scan period P_{S1}, and a light emission period P_{L1}, and the second field consists of a reset period P_{R2}, a scan period P_{S2}, and a light emission period P_{L2}.

Also in this embodiment, to solve the previously mentioned problem of black level deterioration, during, of the first and second fields, only the first field, the current I_{OLED} is compensated for a variation in the voltage V_{F}; moreover, the LUT 9 feeds the gradation signal to the data driver 3f after converting it into a first converted gradation signal corresponding to the first field and a second converted gradation signal corresponding to the second field in such a way that a relationship similar to that realized in the seventh embodiment (FIGS. 23 to 27) is realized between the level of gradation specified by the gradation signal and the effective value of the current I_{OLED}. Thus, advantages similar to those achieved in the seventh embodiment are achieved here.

Solid lines 61j and 62j represent the voltage waveforms observed at the nodes N_{A} and N_{B}, respectively, when the V_{OLED}-I_{OLED} characteristic of the organic EL element 42 is as indicated by the solid line 201 in FIG. 18. A solid line 63j represents the waveform of the current I_{OLED} that flows through the organic EL element 42 when the V_{OLED}-I_{OLED} characteristic of the organic EL element 42 is as indicated by the solid line 201 in FIG. 18.

Broken lines 64j and 65j represent the voltage waveforms observed at the nodes N_{A} and N_{B}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66j represents the waveform of the current I_{OLED} that flows through the organic EL element 42 when the V_{OLED}-I_{OLED} characteristic of the organic EL element 42 has shifted as indicated by the broken line 202 in FIG. 18. It should be noted that, in the second field, the solid line 61j and the broken line 64j are identical and thus overlap each other and likewise the solid line 62j and the broken line 65j are identical and thus overlap each other.

A broken line 67j represents the waveform of the current I_{OLED} as observed when, in a case where a variation in the voltage V_{F} attributable to a time-related variation or the like in the organic EL element 42 is not fed back, the current I_{OLED} has decreased because of a time-related variation or the like. In the second field, the broken line 66j and the broken line 67j are identical and thus overlap each other.

How the scan voltage SCAN and the control signals CTL1, CTL2, and CTL3 change their levels during each field (P_{R1}, P_{S1}, P_{L1}, P_{R2}, P_{S2}, and P_{L2}) is the same as in FIG. 33. The reset voltage RST (described in connection with the tenth embodiment) is applied to the data voltage line 43a only during the reset period P_{R2} of the second field, and otherwise the data voltage DATA from the data driver 3f is applied thereto.

Thus, as in the tenth embodiment shown in FIG. 33, during the reset period P_{R1}, the voltages at the nodes N_{A} and N_{B} equal (CV+V_{F}) and (VDD−Vth), respectively, and, after the data voltage DATA is written during the scan period P_{S1}, (the voltage at the node N_{B} as indicated by the broken line 65j)<(the voltage at the node N_{B} as indicated by the solid line 62j). After the data voltage DATA is written, the scan voltage SCAN applied to the pixel 41j of interest is turned back low, and, when data voltages are written to al the pixels 41j constituting the display panel 4f, the scan period P_{S1} ends, and the light emission period P_{L1} begins.

The voltage at the node N_{B} at the end of the scan period P_{S1} is kept during the light emission period P_{L1}, and thus the current I_{OLED}, which would be as indicated by the broken line 67j if the variation in the voltage V_{F} were not fed back, is compensated as indicated by the broken line 66j.

At the transition from the light emission period P_{L1} to the reset period P_{R2}, the scan voltage SCAN and the control signal CTL2 are turned high. Moreover, starting with the light emission period P_{L1}, the control signal CTL1 is kept high until a midpoint during the reset period P_{R2}, when the control signal CTL1 is turned low. During the reset period P_{R2}, since the reset voltage RST is fed to the data voltage line 43a, the voltage at the node N_{B} equals the reset voltage RST. This reset voltage RST is set approximately equal to the sum of the negative-side supply voltage CV and the voltage V_{F} in the initial state (that is, the voltage V_{F0}). Moreover, at the end of the reset period P_{R2}, the voltage at the node N_{B} equals (VDD−Vth).

Subsequent to the reset period P_{R2}, during the scan period P_{S2}, when a high-level scan voltage SCAN is applied to the pixel 41j of interest, the writing transistor TR1 turns on. Now, the voltage at the node N_{A} rises to become equal to the data voltage DATA fed to the data voltage line 43a (that is, the data voltage DATA is written). Moreover, as in the seventh embodiment, the data voltage DATA written to each pixel in the second field is, in principle, different from that written thereto in the first field.

After the data voltage DATA is written, the scan voltage SCAN applied to the pixel 41j of interest is turned back low. When data voltages are written to all the pixels 41j constituting the display panel 4f, the scan period P_{S2} ends, and the light emission period P_{L2} begins. The voltage at the node N_{B} at the end of the scan period P_{S2} is kept during the light emission period P_{L2}, and light is emitted according to that voltage. When the light emission period P_{L2} ends, then, in the next frame, operations similar to those described above are repeated.

### Twelfth Embodiment

A twelfth embodiment of the present invention as applied to an organic EL display device will be described below. FIG. 37 is a block diagram showing the overall configuration of the organic EL display device of the twelfth embodiment of the present invention. As shown in FIG. 37, the organic EL display 10k has a display panel 4k composed of a plurality of pixels arrayed in a matrix, and this display panel 4k is connected to: a scan driver 2k that feeds a scan voltage to each pixel; a data driver 3k that feeds a data voltage to each pixel; and a control signal generation circuit 5k. In this embodiment, the display panel 4k is of a so-called analog drive type, and thus does not require a ramp voltage generation circuit.

The organic EL display device shown in FIG. 37 displays on the display panel 4k an image according to an image signal fed from an image source (external signal source) such as a television receiver (unillustrated). The image signal processing circuit 6, the timing signal generation circuit 7f, and the LUT 9 shown in FIG. 37 are the same as those shown in FIG. 20.

The image signal fed from an image source such as a television receiver (unillustrated) is fed to an image signal processing circuit 6, where the image signal is subjected to necessary signal processing to produce image signals of three primary colors (RGB), namely red (R), green (G), and blue (B), which signals are then fed via the LUT 9 to the data driver 3k of the organic EL display 10k.

The image signal processing circuit 6 also produces a horizontal synchronizing signal Hsync and a vertical synchronizing signal Vsync, which are fed to a timing signal generation circuit 7f to produce timing signals, which are then fed to the scan driver 2k and the data driver 3k. In addition, a field signal coordinated with those timing signals is fed to an LUT 9. This field signal identifies whether the current field is a first or a second field.

The timing signal produced by the timing signal generation circuit 7f is fed also to the control signal generation circuit 5k. Based on this timing signal, the control signal generation circuit 5k produces control signals CTL1, CTL2, CTL3, and CTL4, and feeds them to each pixel of the display panel 4k. These control signals CTL1 to CTL4 are used to drive the organic EL display 10k.

All the circuits, drivers, and organic EL display shown in FIG. 37 are connected to a power supply circuit (unillustrated).

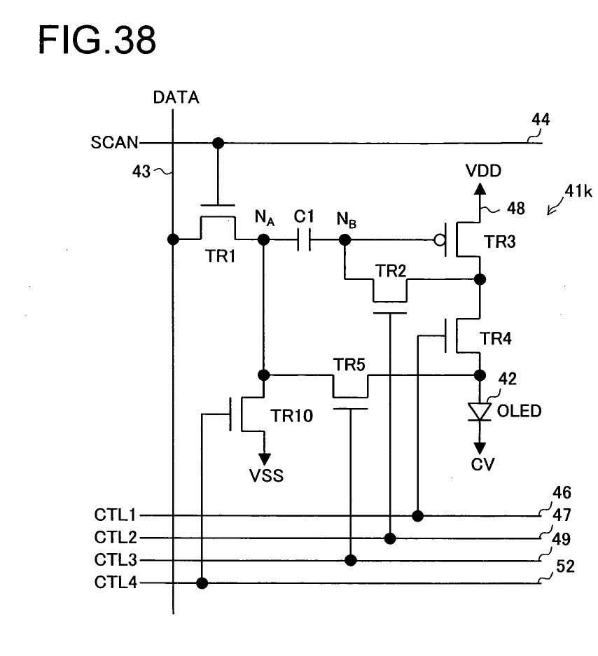

Next, the circuit configuration of each pixel 41k constituting the display panel 4k will be described with reference to FIG. 38. The circuit configuration of the pixel 41k shown in FIG. 38 is similar to that of the pixel 41j shown in FIG. 35. In FIG. 38, such elements as are found also in FIGS. 2 and 35 are identified with common reference numerals and symbols. The pixel 41k (the pixel circuit of the pixel 41k) shown in FIG. 38 differs from the pixel 41j (the pixel circuit of the pixel 41j) shown in FIG. 35 in the following respects: the first electrode (for example, source) of the writing transistor TR1 is connected to a data voltage line 43 to which a data voltage DATA from the data driver 3k is applied; and a resetting transistor TR10 is additionally provided that is built as an N-channel MOS transistor. Otherwise, the pixels of this and the eleventh embodiments are identically configured, and therefore no overlapping explanations will be repeated.

The drain of the resetting transistor TR10 is connected to the node N_{A}. The gate of the resetting transistor TR10 is connected to a control signal line 52 to which the control signal CTL4 is applied. When the control signal CTL4 is low or high, the resetting transistor TR10 is off or on, respectively. A supply voltage VSS that is higher than the negative-side supply voltage CV but lower than the positive-side supply voltage VDD is applied to the source of the resetting transistor TR10. The supply voltage VSS is set approximately equal to the sum of the negative-side supply voltage CV and the voltage V_{F} in the initial state (that is, the voltage V_{F0}).

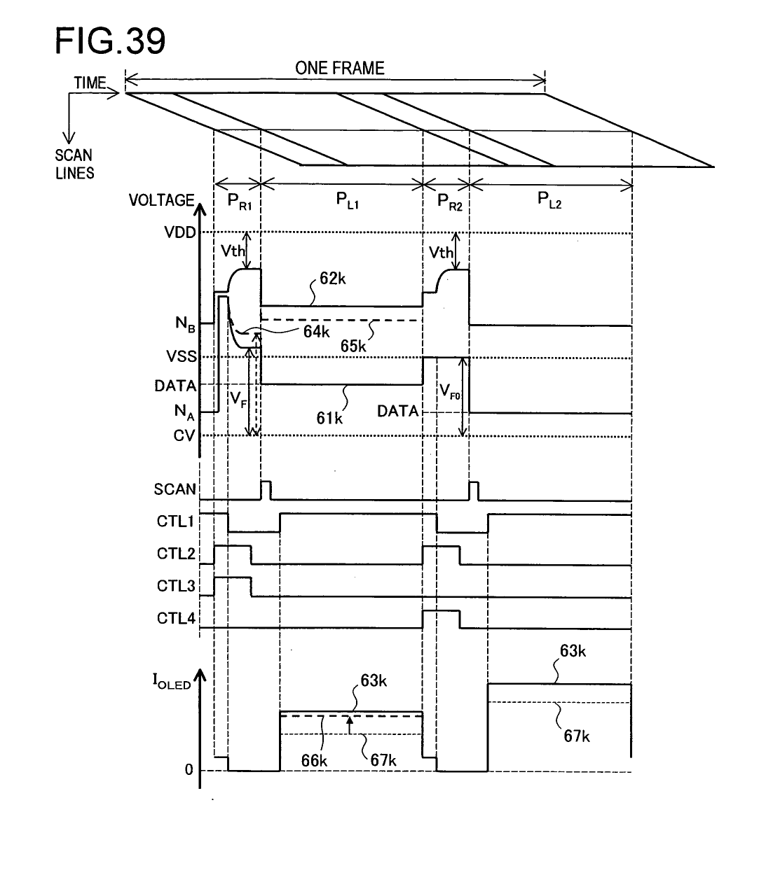

Now, with reference to FIG. 39, the operation of the organic EL display device of the twelfth embodiment will be described. FIG. 39 shows the voltages at relevant points in FIG. 38 and the current I_{OLED} through the organic EL element 42 as observed over one frame period. The period for the display of one screen, that is, one frame period (the reciprocal of the frame frequency), consists of two fields, namely a first field and a second field. As shown in FIG. 39, the first field consists of a reset period P_{R1} and a light emission period P_{L1}, and the second field consists of a reset period P_{R2} and a light emission period P_{L2}.

Since the reset period P_{R1} is a period during which the organic EL element 42 is made ready to emit light during the light emission period P_{L1}, it can be called a light emission preparation period in the first field. Since the reset period P_{R2} is a period during which the organic EL element 42 is made ready to emit light during the light emission period P_{L2}, it can be called a light emission preparation period in the second field.

Each one frame period begins and ends with different timing from one scan line to the next; that is, the beginning and end of one frame period occur first for the first scan line, then for the second scan line, . . . , and then for the nth scan line (where n represents the number of scan lines), with a predetermined time interval secured in between. FIG. 39 shows, for a given scan line of interest among the total of n scan lines, the voltage at relevant points in FIG. 38 etc.

For a given scan line, the reset period P_{R1}, the light emission period P_{L1}, the reset period P_{R2}, and the light emission period P_{L2} occur in this order and, at the end of the kth (where k is a natural number) frame period, then subsequently the (k+1)th frame period begins, during the period of which the reset period P_{R1}, the light emission period P_{L1}, the reset period P_{R2}, and the light emission period P_{L2} occur in this order. Thus, superficially, this embodiment appears to involve no scan period. In substance, however, as will be made clear in the following description, at the beginning of each light emission period, a scan voltage SCAN is turned high to write a data voltage DATA to a pixel. Thus, this embodiment can also be considered to have a scan period incorporated into each light emission period.

Also in this embodiment, to solve the previously mentioned problem of black level deterioration, during, of the first and second fields, only the first field, the current I_{OLED} is compensated for a variation in the voltage V_{F}; moreover, the LUT 9 feeds the gradation signal to the data driver 3f after converting it into a first converted gradation signal corresponding to the first field and a second converted gradation signal corresponding to the second field in such a way that a relationship similar to that realized in the seventh embodiment (FIGS. 23 to 27) is realized between the level of gradation specified by the gradation signal and the effective value of the current I_{OLED} Thus, advantages similar to those achieved in the seventh embodiment are achieved here.

Solid lines 61k and 62k represent the voltage waveforms observed at the nodes N_{A} and N_{B}, respectively, when the V_{OLED}-I_{OLED} characteristic of the organic EL element 42 is as indicated by the solid line 201 in FIG. 18. A solid line 63k represents the waveform of the current I_{OLED} that flows through the organic EL element 42 when the V_{OLED}-I_{OLED} characteristic of the organic EL element 42 is as indicated by the solid line 201 in FIG. 18.

Broken lines 64k and 65k represent the voltage waveforms observed at the nodes N_{A} and N_{B}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66k represents the waveform of the current I_{OLED} that flows through the organic EL element 42 when the V_{OLED}-I_{OLED} characteristic of the organic EL element 42 has shifted as indicated by the broken line 202 in FIG. 18. It should be noted that, in the second field, the solid line 61k and the broken line 64k are identical and thus overlap each other and likewise the solid line 62k and the broken line 65k are identical and thus overlap each other.

A broken line 67k represents the waveform of the current I_{OLED} as observed when, in a case where a variation in the voltage V_{F} attributable to a time-related variation or the like in the organic EL element 42 is not fed back, the current I_{OLED} has decreased because of a time-related variation or the like. In the second field, the broken line 66k and the broken line 67k are identical and thus overlap each other.

During the reset period P_{R1}, the light emission period P_{L1}, and the light emission period P_{L2}, the control signal CTL4 is kept low so that, in those periods, the resetting transistor TR10 remains off. The operations performed during the reset period P_{R1} in the first field are the same as those performed during the reset period P_{R1} in FIG. 33. Thus, at the end of the reset period P_{R1}, the voltages at the nodes N_{A} and N_{B} equal (CV+V_{F}) and (VDD−Vth), respectively. Incidentally, during each reset period (P_{R1} and P_{R2}), the scan voltage SCAN is kept low.

When the light emission period P_{L1} begins, the scan voltage SCAN is turned high to turn the writing transistor TR1 on. At the moment, a data voltage DATA from the data driver 3k is being fed to the data voltage line 43, and therefore the voltage at the node N_{A} now falls to become equal to the data voltage DATA. Correspondingly, through the coupling provided by the capacitor C1, the voltage at the node N_{B} falls by the same voltage. After the data voltage DATA is written to the node N_{A}, the scan voltage SCAN is turned low, and subsequently the control signal CTL1 is turned high to cause the organic EL element 42 to start to emit light. Here, because of the difference in the voltage V_{F}, (the voltage at the node N_{B} as indicated by the broken line 65k)<(the voltage at the node N_{B} as indicated by the solid line 62k). Thus, the current I_{OLED}, which would be as indicated by the broken line 67k if the variation in the voltage V_{F} were not fed back, is compensated as indicated by the broken line 66k.

The operations performed n the second field are as follows. At the beginning of the reset period P_{R2} in the second field, the control signals CTL1 to CTL4 are high, high, low, and high, respectively. At a midpoint during the reset period P_{R2}, the control signal CTL1 is turned low, and, when the voltage at the node N_{B} stabilizes at (VDD−Vth), the control signals CTL2 and CTL4 are turned low. Thus, at the end of the reset period P_{R2}, the voltages at the nodes N_{A} and N_{B} equal VSS and (VDD−Vth), respectively. That is, in the second field, no voltage (feedback voltage) commensurate with the voltage V_{F} is transmitted to the capacitor C1.

When the light emission period P_{L2} begins, the scan voltage SCAN is turned high to turn the writing transistor TR1 on. At the moment, a data voltage DATA from the data driver 3k is being fed to the data voltage line 43, and thus the voltage at the node N_{A} now falls to become equal to the data voltage DATA. Correspondingly, through the coupling provided by the capacitor C1, the voltage at the node N_{B} falls by the same voltage. Moreover, as in the seventh embodiment, the data voltage DATA written to each pixel in the second field is, in principle, different from that written thereto in the first field. After the data voltage DATA is written to the node N_{A}, the scan voltage SCAN is turned low, and subsequently the control signal CTL1 is turned high to cause the organic EL element 42 to start to emit light. When the light emission period P_{L2} ends, the reset period P_{R1} of the next frame begins, during which the control signals CTL2 and CTL3 are turned high.

The circuit configuration of each pixel in the twelfth embodiment, though slightly more complicate than that in the eleventh embodiment, helps make the light emission duration longer than in the eleventh embodiment.

### Thirteenth Embodiment

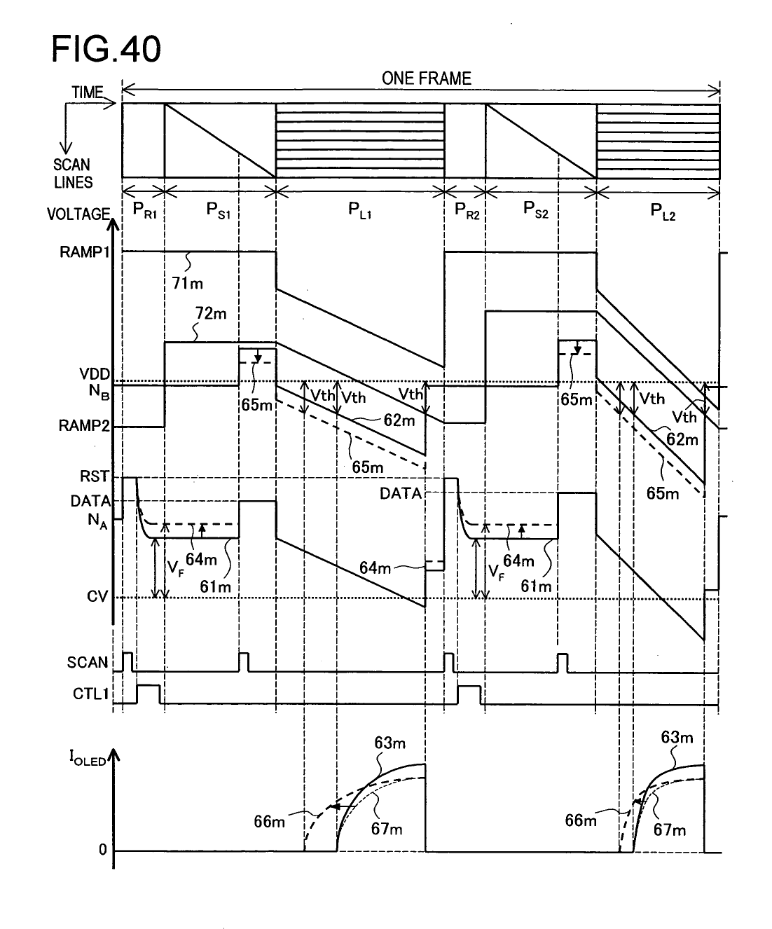

Next, as a modified example of the seventh embodiment, a thirteenth embodiment of the present invention as applied to an organic EL display device will be described. The overall configuration of the organic EL display device of this embodiment and the circuit configuration of each pixel constituting it are the same as that shown in the block diagram of FIG. 20 and that of the pixel 41f shown in the circuit configuration diagram of FIG. 21. Here, however, the operations performed to solve the problem of black level deterioration is different from in the seventh embodiment. Now, these operations will be described with reference to FIG. 40. FIG. 40 shows the voltages at relevant points in the pixel 41f of this embodiment and the current I_{OLED} through the organic EL element 42 as observed over one frame period.

The period for the display of one screen, that is, one frame period (the reciprocal of the frame frequency), consists of two fields, namely a first field and a second field. As in the seventh embodiment, the first field consists of a reset period P_{R1}, a scan period P_{S1}, and a light emission period P_{L1}, and the second field consists of a reset period P_{R1}, a scan period P_{S2}, and a light emission period P_{L2}.

A solid line 71m represents the voltage waveform of the ramp voltage RAMP1 fed from the ramp voltage generation circuit 8f to the ramp voltage line 55. The ramp voltage RAMP1 remains fixed at a previously set initial voltage during the reset and scan periods of each field (that is, P_{R1}, P_{S1}, P_{R2}, and P_{S2}), and then decreases monotonically at a previously set variation rate during the light emission period of each field (that is, P_{L1} and P_{L2}). Then, during the reset period of each field (that is, P_{R1} and P_{R2}), the ramp voltage RAMP1 stops decreasing monotonically and turns back to the initial voltage.

A solid line 72m represents the voltage waveform of the ramp voltage RAMP2 fed from the ramp voltage generation circuit 8f to the ramp voltage line 56. The ramp voltage RAMP2 remains fixed at a voltage that keeps the turning-off transistor TR7 on during the reset period of each field (that is, P_{R1} and P_{R2}), and remains fixed at a voltage that keeps the turning-off transistor TR7 off during the scan period of each field (that is, P_{S1} and P_{S2}). During the light emission period of each field (that is, P_{L1} and P_{L2}), the ramp voltage RAMP2 decreases monotonically at a previously set variation rate.

The variation rate of the ramp voltage RAMP1 during the light emission period P_{L2} of the second field is set higher than that during the light emission period P_{L1} of the first field. Likewise, the variation rate of the ramp voltage RAMP2 during the light emission period P_{L2} of the second field is set higher than that during the light emission period P_{L1} of the first field. The variation rates of the ramp voltages RAMP1 and RAMP2 during each light emission period are set, for example, equal. The lengths of the reset periods P_{R1} and P_{R2} are set, for example, equal. Likewise, the lengths of the scan periods P_{S1} and P_{S2} are set, for example, equal. Needless to say, the lengths of the periods of either of these pairs may be made different. On the other hand, the length of the light emission period P_{L1} is set greater than that of the light emission period P_{L2}. A modification, however, is possible in which the lengths of those periods are made equal.

In the thirteenth embodiment, the organic EL element 42 is driven according to the variation in the voltage V_{F} both in the first and second fields. To solve the earlier described problem of black level deterioration, however, the LUT 9 feeds the gradation signal to the data driver 3f after converting it according to the type of the current field (that is, after converting it into a first and a second converted gradation signal) in such a way that, in the first field, a first data voltage that represents as a data voltage the high-gradation side of the gradation signal (that is, a first data voltage corresponding to the high-gradation side of the gradation signal) is fed to each pixel and, in the second field, a second data voltage that represents as a data voltage the low-gradation side of the gradation signal (that is, a second data voltage corresponding to the low-gradation side of the gradation signal) is fed to each pixel. In addition, the slopes of the ramp voltages in the second field are made steeper (than in the first field).

Solid lines 61m and 62m represent the voltage waveforms observed at the nodes N_{A} and N_{B}, respectively, when the V_{OLED}-I_{OLED} characteristic of the organic EL element 42 is as indicated by the solid line 201 in FIG. 18. A solid line 63m represents the waveform of the current I_{OLED} that flows through the organic EL element 42 when the V_{OLED}-I_{OLED} characteristic of the organic EL element 42 is as indicated by the solid line 201 in FIG. 18.

Broken lines 64m and 65m represent the voltage waveforms observed at the nodes N_{A} and N_{B}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66m represents the waveform of the current I_{OLED} that flows through the organic EL element 42 when the V_{OLED}-I_{OLED} characteristic of the organic EL element 42 has shifted as indicated by the broken line 202 in FIG. 18.

A broken line 67m represents the waveform of the current I_{OLED} as observed when, in a case where a variation in the voltage V_{F} attributable to a time-related variation or the like in the organic EL element 42 is not fed back, the current I_{OLED} has decreased because of a time-related variation or the like.

The operations performed by the individual circuit blocks during the reset period P_{R1} are the same as in the seventh embodiment. Thus, at the end of the reset period P_{R1}, the voltages at the nodes N_{A} and N_{B} equal (CV+V_{F}) and VDD, respectively. Moreover, the operations performed by the individual circuit blocks during the reset period P_{R2} of the second field are the same as those in the reset period P_{R1}. Moreover, the reset voltage RST fed to the data voltage line 43a during each reset period is set sufficiently higher than (CV+V_{F}) during both the reset periods P_{R1} and P_{R2}.

Thus, during the reset period of both the first and second fields, a voltage (feedback voltage) commensurate with the voltage V_{F} is transmitted to the capacitor C1, so that, at the end of each reset period, the capacitor C1 holds a voltage (VDD−CV−V_{F}), that is, a voltage (held voltage) commensurate with the voltage V_{F}. Moreover, as will be understood from the V_{OLED}-I_{OLED} characteristic of the organic EL element 42 shown in FIG. 18, the voltage V_{F} indicated by the broken line 64m, which represents the case where a time-related variation or the like is present, is higher than that indicated by the solid line 61m. Thus, at the beginning of each scan period, (the voltage at the node N_{A} as indicated by the broken line 64m)<(the voltage at the node N_{A} as indicated by the solid line 61m). Incidentally, the control signal CTL1 is kept low during each scan period and during each light emission period.

During each scan period, when a high-level scan voltage SCAN is applied to a pixel 41m of interest, the writing transistor TR1 turns on. Now, the voltage at the node N_{A} rises to become equal to the data voltage DATA applied to the data voltage line 43a (that is, the data voltage DATA is written), and correspondingly, through the coupling provided by the capacitor C1, the voltage at the node N_{B} rises by the same voltage. Here, the voltage by which the voltages at the nodes N_{A} and N_{B} rise equals (DATA−V_{F}−CV). Thus, the voltage at the node N_{B} (that is, the gate voltage of the driving transistor TR3) equals (VDD−CV+DATA−V_{F}), that is, a voltage commensurate with the data voltage DATA and the voltage V_{F} (that is, a voltage commensurate with the data voltage DATA and the above-mentioned held voltage).

Here, since (the voltage V_{F} as indicated by the broken line 64m)>(the voltage V_{F} as indicated by the solid line 61m), once the data voltage DATA is written, the following relationship holds: (the voltage at the node N_{B} as indicated by the broken line 65m)<(the voltage at the node N_{B} as indicated by the solid line 62m).

After the data voltage DATA is written, the scan voltage SCAN applied to the pixel 41f of interest is turned back low. In each field, when data voltages are written to all the pixels 41f constituting the display panel 4f, the scan period ends, and the subsequent light emission period begins.

In each field, when the light emission period begins, the ramp voltage RAMP1 falls abruptly by a previously set voltage. The purpose is to maximize the proportion of the duration for which the organic EL element 42 actually emits light during each light emission period. This abrupt fall of the ramp voltage RAMP1 causes the potentials at the nodes N_{A} and N_{B} to fall by the same voltage. Thereafter, the ramp voltage RAMP1 decreases linearly at the previously set fixed rate that is made different between in the first and second fields as described previously. Moreover, in each field, when the light emission period begins, the ramp voltage RAMP2 also decreases linearly at the previously set fixed rate that is made different between in the first and second fields as described previously.

In each light emission period, when the voltage at the node N_{B} becomes equal to or lower than the voltage (VDD−Vth), a current starts to flow through the organic EL element 42. Here, since, at the beginning of each light emission period, (the voltage at the node N_{B} as indicated by the broken line 65m)<(the voltage at the node N_{B} as indicated by the solid line 62m), light emission starts earlier in the case indicated by the broken line 65m. Then, the current that has started to flow through the organic EL element 42 during each light emission period increases gradually. Then, in each light emission period, when the ramp voltage RAMP2 becomes equal to or lower than the voltage (VDD−Vth), the turning-off transistor TR7 turns on, and causes the voltage at the node N_{B} to rise to the positive-side supply voltage VDD. Correspondingly, the driving transistor TR3 turns off, and the organic EL element 42 stops emitting light.

In the first field, the slopes of the ramp voltages (RAMP1 and RAMP2) during the light emission period P_{L1} are comparatively gentle. Thus, a variation in the voltage V_{F} produces a comparatively large variation in the current I_{OLED}. That is, in response to a variation in the voltage V_{F}, the effective value of the current I_{OLED} during the light emission period P_{L1} increases or decreases sensitively. Thus, in the first field, high-gradation-side data is, as data voltages DATA, fed to each pixel. This is because, as will be understood from FIG. 19 and other figures, a drop in the current I_{OLED} resulting from a time-related variation or the like is more notable in the high-gradation side.

On the other hand, in the second field, the slopes of the ramp voltages (RAMP1 and RAMP2) during the light emission period P_{L2} are comparatively steep. Thus, a variation in the voltage V_{F} only slightly influences the magnitude of the current I_{OLED} That is, in response to a variation in the voltage V_{F}, the effective value of the current I_{OLED} during the light emission period P_{L2} increases or decreases insensitively. Thus, in the second field, the low-gradation-side data is, as data voltages DATA, fed to each pixel. The purpose is to alleviate black level deterioration resulting from excessive feedback of a variation in the voltage V_{F} in the low-gradation side.

Certainly, through these operations, black level deterioration is alleviated. However, though only to a small degree, the variation in the voltage V_{F} is fed back also in the second field. Thus, in suppressing black level deterioration, the seventh to twelfth embodiments described previously are more effective.

Now, a practical example will be described of how the LUT 9 converts the gradation signal according to the type of the current field. Consider, for example, a case where the gradation signal fed to the LUT 9 takes one of the values in the range from 0 to 255, and that, the greater the number, the higher the level of gradation. The following description concentrates on one given pixel.

For example, when the value of a gradation signal fed to the LUT 9 lies in a low-gradation range, namely in the range from 0 to 50, such a data voltage is written to the target pixel during each scan period as causes the organic EL element 42 to emit light only in the second field so that the brightness (current I_{OLED}) corresponding to that gradation signal is obtained through light emission in the second field alone. By contrast, when the value of a gradation signal fed to the LUT 9 lies in a high-gradation range, namely in the range from 150 to 255, such a data voltage is written to the target pixel during each scan period as causes the organic EL element 42 to emit light only in the first field so that the brightness (current I_{OLED}) corresponding to that gradation signal is obtained through light emission in the first field alone.

When the value of a gradation signal fed to the LUT 9 lies in the intermediate range, namely in the range from 51 to 149, such a data voltage is written to the target pixel during each scan period as causes the organic EL element 42 to emit light both in the first and second fields so that the brightness (current I_{OLED}) corresponding to that gradation signal is obtained through light emission both in the first and second fields. That is, for intermediate levels of gradation, light emission is distributed between the first and second fields.

Operating as described above, the LUT 9 converts the gradation signal fed thereto according to the type of the current field and then feeds the result to the data driver 3f. Specifically, the LUT 9 feeds the data driver 3f with a first converted gradation signal (a first compensated gradation signal) in the first field and with a second converted gradation signal (a second compensated gradation signal) in the second field. How the fed gradation signal is converted into the first and second converted gradation signal is prescribed.

When the data driver 3f receives a first converted gradation signal, it sets the data voltage DATA to be fed to a pixel during the scan period P_{S1} equal to a first data voltage commensurate with the first converted gradation signal. Likewise, when the data driver 3f receives a second converted gradation signal, it sets the data voltage DATA to be fed to a pixel during the scan period P_{S2} equal to a second data voltage commensurate with the second converted gradation signal.

Light emission at intermediate levels of gradation does not necessarily have to be distributed between the first and second fields. Alternatively, for example, when the value of a gradation signal fed to the LUT 9 lies in a low-gradation range, namely in the range from 0 to 120, such a data voltage is written to the target pixel during each scan period as causes the organic EL element 42 to emit light only in the second field and, when the value of a gradation signal fed to the LUT 9 lies in a high-gradation range, namely in the range from 120 to 255, such a data voltage is written to the target pixel during each scan period as causes the organic EL element 42 to emit light only in the first field.

Although the thirteenth embodiment has been described above as a modified example of the seventh embodiment, the thirteenth embodiment may also be combined with any of the already-described eighth to tenth embodiments and the later-described fifteenth to seventeenth embodiments. Specifically, the method of “making the LUT 9 feed the gradation signal to the data driver 3f after converting it according to the type of the current field in such a way that, in the first field, a first data voltage that represents as a data voltage the high-gradation side of the gradation signal is fed to each pixel and, in the second field, a second data voltage that represents as a data voltage the low-gradation side of the gradation signal is fed to each pixel and in addition making the slopes of the ramp voltages in the second field steeper (than in the first field)” may be applied to the already-described eighth to tenth embodiments and the later-described fifteenth to seventeenth embodiments. Needless to say, in this case, during the reset period or scan period of both the first and second fields, a voltage commensurate with the voltage V_{F} is held in the capacitor C1.

### Fourteenth Embodiment

A fourteenth embodiment of the present invention as applied to an organic EL display device will be described below. The overall configuration of the organic EL display device of the fourteenth embodiment of the present invention is substantially the same as that shown in FIG. 1 (the first embodiment); therefore, no separate diagram is furnished in that aspect, and the following description places emphasis on differences from the first embodiment.

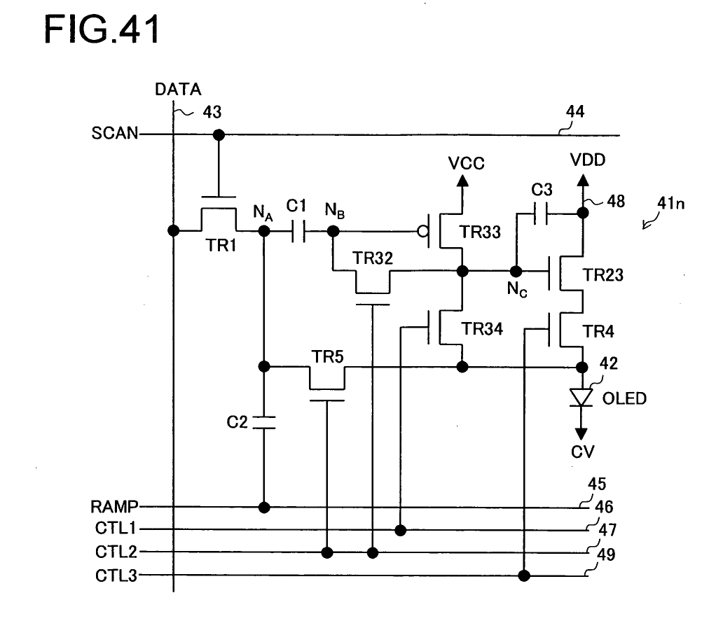

The display panel 4 is so modified that each pixel 41n constituting it is configured as shown in FIG. 41. In FIG. 41, such elements as are found also in FIGS. 2 and 28 are identified with common reference numerals and symbols, and no overlapping explanations will be repeated. Moreover, as compared with in the first embodiment, the control signal generation circuit 5 is so modified as to feed each pixel 41n with, in addition to the control signals CTL1 and CTL2, a control signal CTL3. Moreover, the individual circuit blocks constituting the organic EL display device are so modified as to realize the operation described below.

The circuit configuration of the pixel 41n will be described below. The pixel circuit constituting each pixel 41n includes: an organic EL element (OLED) 42; a writing transistor TR1; a driving transistor TR23 that drives, according to the voltage fed to the gate (control electrode) thereof, the organic EL element 42; an on/off transistor TR4; an adjustment transistor TR5; a capacitor C1 (first capacitive element); a capacitor C2 (second capacitive element); a switching transistor TR33 that controls the turning on and off of the driving transistor TR23; a threshold value compensation transistor TR32 that compensates for a variation in the operation threshold voltage (Vth) of the switching transistor TR33; an on/off transistor TR34; and a capacitor C3.

The threshold value compensation transistor TR32 and the on/off transistor TR34 are N-channel MOS transistors formed as thin-film transistors (TFTs). The switching transistor TR33 is a P-channel MOS transistor formed as a thin-film transistor.

The first electrode (for example, source) of the writing transistor TR1 is connected to a data voltage line 43 to which a data voltage DATA is applied with predetermined timing. The second electrode (for example, drain) of the writing transistor TR1 is connected to one electrode of the capacitor C1. The gate of the writing transistor TR1 is connected to a scan voltage line 44 to which a scan voltage SCAN is applied. The first electrode (for example, source) of the threshold value compensation transistor TR32 is connected to the other electrode of the capacitor C1 and to the gate of the switching transistor TR33. The second electrode (for example, drain) of the threshold value compensation transistor TR32 is connected to the drain of the switching transistor TR33 and to the drain of the on/off transistor TR34. The gate of the threshold value compensation transistor TR32 is connected to a control signal line 47 to which the control signal CTL2 is applied.

In the pixel 41n, the node between the capacitor C1 and the second electrode of the writing transistor TR1 will be referred to as the node N_{A}, the node between the capacitor C1 and the gate of the switching transistor TR33 will be referred to as the node N_{B}, and the node between the drain of the switching transistor TR33 and the drain of the on/off transistor TR34 will be referred to as the node N_{C}.

A positive-side supply voltage VDD is applied to the drain of the driving transistor TR23, and this drain is connected via the capacitor C3 to the gate of the driving transistor TR23 itself. The source of the driving transistor TR23 is connected to the drain of the on/off transistor TR4. The gate of the driving transistor TR23 is connected to the node N_{C}.

The source of the on/off transistor TR4 is connected to the anode of the organic EL element 42. The gate of the on/off transistor TR4 is connected to a control signal line 49 to which the control signal CTL3 is applied. The source of the on/off transistor TR34 is connected to the anode of the organic EL element 42. The gate of the on/off transistor TR34 is connected to a control signal line 46 to which the control signal CTL1 is applied. A negative-side supply voltage CV is applied to the cathode of the organic EL element 42. Moreover, a supply voltage VCC that is higher than the supply voltage VDD is applied to the source of the switching transistor TR33.

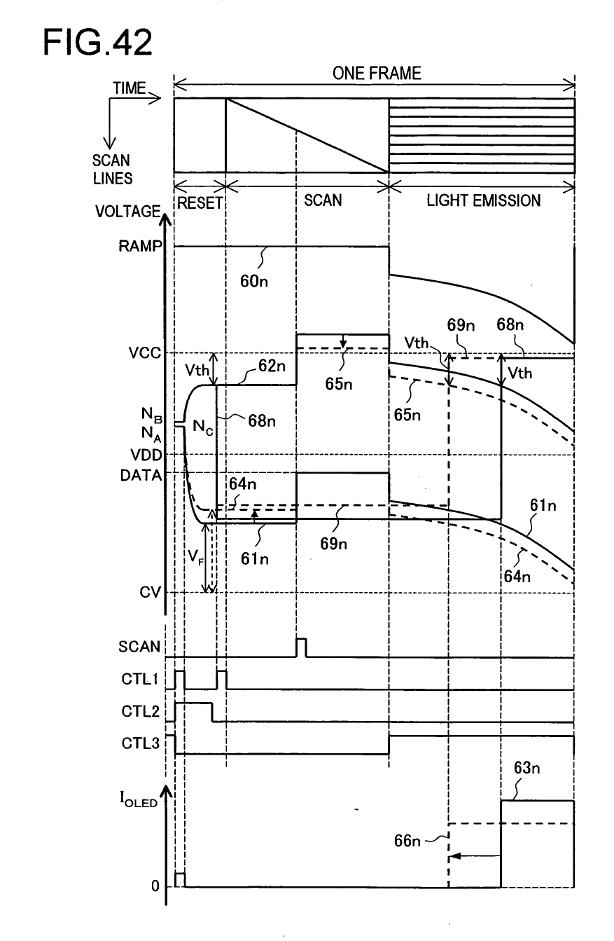

The first electrode (for example, source) of the adjustment transistor TR5 is connected to the anode of the organic EL element 42. The second electrode (for example, drain) of the adjustment transistor TR5 is connected to the node N_{A}. The gate of the adjustment transistor TR5 is connected to the control signal line 47. One electrode of the capacitor C2 is connected to the node N_{A}. The other electrode of the capacitor C2 is connected to a ramp voltage line 45 to which a ramp voltage RAMP is fed. [04761 FIG. 42 shows the voltages at relevant points in FIG. 41 and the current I_{OLED} through the organic EL element 42 as observed over one frame period. In FIG. 42, such elements as are found also in FIG. 3 are identified with common reference numerals and symbols, and no overlapping explanations will be repeated.

As shown in FIG. 42, the period for the display of one screen, that is, one frame period (the reciprocal of the frame frequency), consists of a reset period, a scan period, and a light emission period. During the reset period, the variation in the operation threshold voltage (Vth) of the switching transistor TR33 and the variation in the light emission start electrode-to-electrode voltage V_{F} of the organic EL element 42 are compensated for. During the scan period, a high-level scan voltage SCAN is applied to one scan voltage line 44 after another so that a plurality of writing transistors TR1 connected to a given scan voltage line are tuned on at a time to permit data voltages DATA to be written to the corresponding pixels. During the light emission period, according to the data voltages DATA written during the scan period, the corresponding organic EL elements 42 are made to emit light. Since the reset period and/or the scan period are periods during which the organic EL element 42 is made ready to emit light during the light emission period, those periods can be collectively referred to as a light emission preparation period.

The reset period, the scan period, and the light emission period occur in this order, and, at the end of the kth (where k is a natural number) frame period, then subsequently the (k+1)th frame period begins, during the period of which the reset period, the scan period, and the light emission period occur in this order.

A solid line 60n represents the voltage waveform of the ramp voltage RAMP fed from the ramp voltage generation circuit 8 to the ramp voltage line 45. The ramp voltage RAMP remains fixed at a previously set initial voltage during the reset period and the scan period. Then, at the transition from the scan period to the light emission period, the ramp voltage RAMP falls abruptly and thereafter decreases at a previously set variation rate. Then, at the transition form the light emission period to the reset period of the next frame, the ramp voltage RAMP stops decreasing and turns back to the initial voltage.

Solid lines 61n, 62n, and 68n represent the voltage waveforms observed at the nodes N_{A}, N_{B}, and N_{C}, respectively, when the V_{OLED}-I_{OLED} characteristic of the organic EL element 42 is as indicated by the solid line 201 in FIG. 18. A solid line 63n represents the waveform of the current I_{OLED} that flows through the organic EL element 42 when the V_{OLED}-I_{OLED} characteristic of the organic EL element 42 is as indicated by the solid line 201 in FIG. 18.

Broken lines 64n, 65n, and 69n represent the voltage waveforms observed at the nodes N_{A}, N_{B}, and N_{C}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66n represents the waveform of the current I_{OLED} that flows through the organic EL element 42 when the V_{OLED}-I_{OLED} characteristic of the organic EL element 42 has shifted as indicated by the broken line 202 in FIG. 18.

First, at the end of the (k−1)th frame period, the control signal CTL3 is turned from high to low, and then, during the kth reset period (that is, the reset period in the kth frame period), the control signals CTL1 and CTL2, which both have thus far been low, are simultaneously turned high. This turns the threshold value compensation transistor TR32, the on/off transistor TR34, and the adjustment transistor TR5 on (bring them into a conducting state), and thus the differential voltage (VCC−CV) between the supply voltages VCC and CV is distributed between the electrode-to-electrode voltage V_{OLED} of the organic EL element 42 and the drain-to-source Vds(=Vgs) of the switching transistor TR33. Consequently, now, the voltage appearing at the nodes N_{A}, N_{B}, and N_{C} are higher than the supply voltage CV by the voltage distributed as the anode-to-cathode voltage of the organic EL element 42. Moreover, now, a small current flows through the organic EL element 42.

Consequently, of the control signals CTL1 and CTL2, which both have thus far been high, only the control signal CTL1 is turned low, so that the on/off transistor TR34 turns off. Now, a current flows from the supply voltage VCC via the switching transistor TR33 and the threshold value compensation transistor TR32 into the node N_{B}, and thus the node N_{B} (and the node N_{C}) is charged up to a voltage lower than the supply voltage VCC by the operation threshold voltage (Vth) of the switching transistor TR33. Moreover, now, a current flows from the node N_{A} via the adjustment transistor TR5 and the organic EL element 42 into the negative-side supply voltage CV. That is, part of the electric charge (positive electric charge) at the node N_{A}, at which the potential is now temporarily high than the potential expressed as (CV+V_{F}), is extracted via the adjustment transistor TR5 and the organic EL element 42, and thus the voltage appearing at the node N_{A} stabilizes at a voltage higher than the supply voltage CV by the light emission start electrode-to-electrode voltage V_{F} of the organic EL element 42.

Then, when the potentials at the nodes N_{A}, N_{B}, and N_{C} stabilize, the control signal CTL2 is turned low to turn the threshold value compensation transistor TR32 and the adjustment transistor TR5 off (bring them into a cut-off state). Now, the capacitor C1 holds a voltage expressed as (VCC−CV−Vth−V_{F}).

Thereafter, the control signal CTL1 is turned from low to high. This causes part of the electric charge (positive electric charge) at the node N_{C} to be extracted via the on/off transistor TR34 and the organic EL element 42, and thus the voltage appearing at the node N_{C} becomes, as at the node N_{A}, equal to (CV+V_{F}), turning the driving transistor TR23 off. Thereafter, the control signal CTL1 is turned back low, and the scan period begins. The control signals CTL1 and CTL2 are kept low during the scan period and the light emission period, and the control signal CTL3 is kept low and high during the scan period and the light emission period, respectively. Incidentally, during the reset period, the scan voltage SCAN is kept low.

Moreover, as will be understood from the V_{OLED}-I_{OLED} characteristic of the organic EL element 42 shown in FIG. 18, the voltages V_{F} indicated by the broken lines 64n and 69n, that is, the voltages V_{F} observed in the presence of a time-related variation or the like, are higher than the voltages V_{F} indicated by the solid lines 61n and 68n. Thus, at the beginning of the scan period, (the voltage at the node N_{A} as indicated by the broken line 64n)>(the voltage at the node N_{A} as indicated by the solid line 61n) and (the voltage at the node N_{c} as indicated by the broken line 69n)>(the voltage at the node N_{c} as indicated by the solid line 68n).

During the scan period, when a high-level scan voltage SCAN is applied to a pixel 41n of interest, the writing transistor TR1 turns on. Now, the voltage at the node N_{A} rises to become equal to the data voltage DATA applied to the data voltage line 43 (that is, the data voltage DATA is written), and correspondingly, through the coupling provided by the capacitor C1, the voltage at the node N_{B} rises by the same voltage. Here, the voltage by which the voltages at the nodes N_{A} and N_{B} rise equals (DATA−V_{F}−CV). Thus, the voltage at the node N_{B} equals (VCC−CV+DATA−V_{F}−Vth).

Here, since (the voltage V_{F} as indicated by the broken line 64n)>(the voltage V_{F} as indicated by the solid line 61n), once the data voltage DATA is written, the following relationship holds: (the voltage at the node N_{B} as indicated by the broken line 65n)<(the voltage at the node N_{B} as indicated by the solid line 62n).

After the data voltage DATA is written, the scan voltage SCAN applied to the pixel 41n of interest is turned back low. When data voltages are written to all the pixels 41n constituting the display panel 4, the scan period ends, and the light emission period begins.

When the light emission period begins, the control signal CTL3 is turned high so that the on/off transistor TR4 turns on, and in addition the ramp voltage RAMP falls abruptly from the initial voltage by a predetermined voltage. This fall of the ramp voltage RAMP causes the voltages at the nodes N_{A} and N_{B} to fall by the same voltage. Here, it is assumed that, immediately after the fall of the ramp voltage RAMP, the voltage at the node N_{B} is higher than (VCC−Vth). Thereafter, as described above, the ramp voltage RAMP decreases at the previously set variation rate, and, with this decrease, the voltages at the nodes N_{A} and N_{B} decrease.

When the voltage at the node N_{B} becomes equal to or lower than (VCC−Vth), the switching transistor TR33 turns on and causes the voltage at the node N_{C} approximately equal to the supply voltage VCC. This turns the driving transistor TR23 on, and thus a current starts to flow through the organic EL element 42. Here, since, at the beginning of the light emission period, (the voltage at the node N_{B} as indicated by the broken line 65n)<(the voltage at the node N_{B} as indicated by the solid line 62n), light emission starts earlier in the case indicated by the broken line 65n (broken line 69n).

Moreover, during the light emission period, the ramp voltage RAMP continues to decrease. Thus, the gate voltage of the driving transistor TR23 (that is, the voltage at the node N_{C}) is kept equal to VCC. Hence, as shown in FIG. 42, the current waveform of the organic EL element 42 is square. At the end of the light emission period, the control signal CTL3 is turned low so that the organic EL element 42 stop emitting light, and then the next frame period begins.

If, as in the conventional configuration, the variation in the voltage V_{F} attributable to a time-related variation or the like in the organic EL element 42 is not fed back at all, the time-related variation or the like causes the current I_{OLED}, which should be as indicated by the solid line 63n, to diminish, resulting in significantly lower brightness for a given data voltage DATA (while the duration of actual light emission remains unchanged). In this embodiment, however, even when a time-related variation or the like is present, the current I_{OLED} behaves as indicated by the broken line 66n, and thus the duration of actual light emission is extended, with the result that the loss in the current I_{OLED} (the loss in brightness) is compensated for. Moreover, thanks to the use of the voltage program driving method, the brightness of the organic EL element 42 is not influenced by a variation in the operation threshold voltage (Vth) of the switching transistor TR33.

No voltage program driving method is adopted for the purpose of eliminating the influence of a variation in the operation threshold voltage of the driving transistor TR23. Instead, such influence is eliminated by a method whereby, when the driving transistor TR23 is turned on during the light emission period, the operating point of the driving transistor TR23 is set within the linear region and the gate-to-source voltage of the driving transistor TR23 is made sufficiently high.

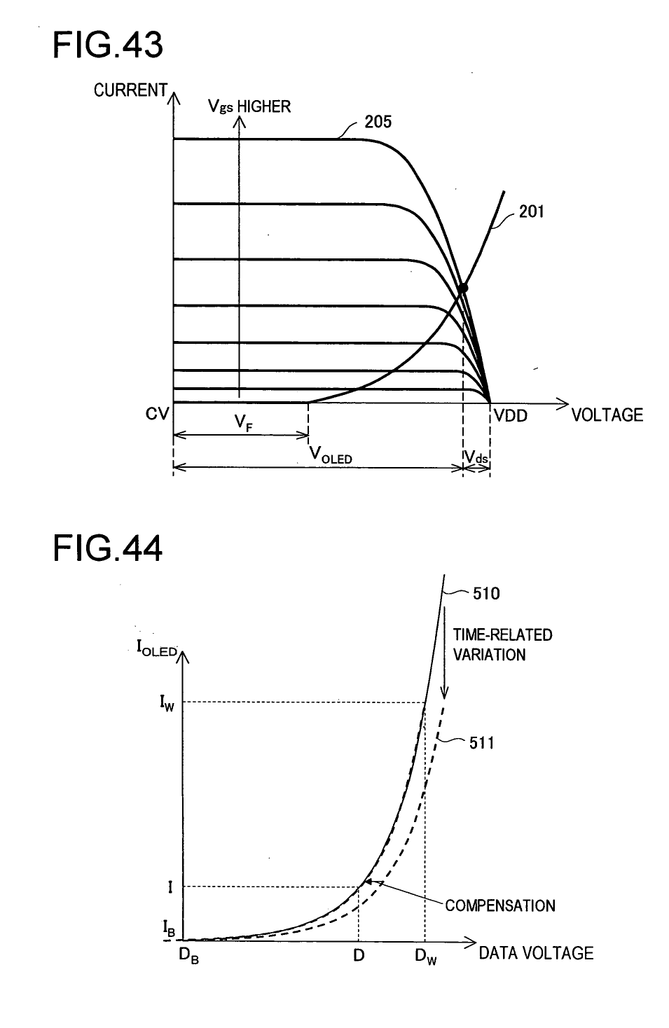

Now, this method will be described with reference to FIG. 43. FIG. 43 shows the Vds-Id characteristic of the driving transistor TR23 and the V_{OLED}-I_{OLED} characteristic. In FIG. 43, such elements as are found also in FIG. 18 are identified with common reference numerals and symbols, and no overlapping explanations will be repeated. Here, it is assumed that, as mentioned above, the operating point of the driving transistor TR23 when it is turned on during the light emission period lies within the linear region.

Solid lines 205 each represent the Vds-Id characteristic of the driving transistor TR23 as observed when the gate-to-source voltage (Vgs) thereof is kept at a given fixed voltage. As will be understood from FIG. 43, the higher the gate-to-source voltage, the less sensitive to the variation of the gate-to-source voltage the variation of the operating point of the driving transistor TR23 becomes. To put differently, the magnitude of the current I_{OLED} during the light emission period is hardly influenced by the variation in the operation threshold voltage of the driving transistor TR23.

Moreover, since the operating point of the driving transistor TR23 is within the linear region, very little electric power turns out to be ineffective at all levels of gradation. This helps reduce power consumption. Moreover, as shown in FIG. 42, the current waveform of the organic EL element 42 during the light emission period is square. This helps keep the maximum value of the current I_{OLED} (peak current magnitude) lower than in the first embodiment. Keeping the peak current magnitude low helps reduce the variation of the supply voltage VDD, and thus helps reduce the current capacity of the power supply circuit (unillustrated) that supplies the supply voltage VDD.

Moreover, in this embodiment, the variation in the operation threshold voltage of the switching transistor TR33 is absorbed by the use of the threshold value compensation transistor TR32. Thus, as indicated by the solid line 60n in FIG. 42, during the light emission period, the variation rate of the ramp voltage RAMP can be varied with time. That is, the ramp voltage RAMP can be given a desired curvature according to the gamma characteristic of the display panel 4.

A practical example of this is indicated by the solid line 60n in FIG. 42. During the light emission period, as time passes, the variation rate at which the ramp voltage RAMP decreases gradually increases. That is, the variation rate of the ramp voltage RAMP is higher in the latter part of the light emission period than in the first part thereof.

In this embodiment, it is not essential to make the variation rate of the ramp voltage RAMP vary with time. In other words, during the light emission period, the variation rate of the ramp voltage RAMP may be kept fixed.

Moreover, in this embodiment, since the current waveform of the organic EL element 42 during the light emission period is square, a time-related variation causes the current I_{OLED} to drop equally at all levels of gradation. That is, as explained previously with reference to FIG. 19, compensating the current I_{OLED} for a variation in the voltage V_{F} may result in black level deterioration. To avoid this, with consideration given to the fact that the ramp voltage RAMP can be given a desired curvature, the relationship between the data voltage and the current I_{OLED} may be set as shown in FIG. 44.

In FIG. 44, the horizontal axis represents the data voltage fed from the data driver 3 to each pixel, and the vertical axis represents the effective value of the current I_{OLED} that flows through the organic EL element 42 to correspond to the data voltage fed. In FIG. 44, as compared with FIG. 34, the “brightness” in the latter is replaced with “the effective value of the current I_{OLED}”.

When a given gradation signal is fed to the data driver 3, the resulting data voltage has a magnitude corresponding to the level of gradation specified by the gradation signal. Let this magnitude be D. When a data voltage with a magnitude D is fed to a pixel in its initial state, a current I_{OLED} commensurate with the data voltage flows through the organic EL element 42. Let the effective value of this current be I. When the level of gradation specified by the gradation signal fed to the data driver 3 is the black or white level, the data voltage fed to a pixel has a magnitude D_{B} or D_{W}, respectively. When a data voltage with a magnitude D_{B} or D_{W} is fed to a pixel 41 in its initial state, a current whose effective value is I_{B} or I_{W}, respectively, flows to correspond to the data voltage. Moreover, let x=D−D_{B} and let y_{I}=I−I_{B}+.

In this case, the variation rate of the ramp voltage RAMP during the light emission period is so set (that is, the ramp voltage RAMP is given such a curvature) as to fulfill formula (4) below in the initial state. A solid line 510 in FIG. 44 represents the curve fulfilling formula (4) below. While, in the initial state, the relationship between “y_{I}” and “x” fulfills formula (4), when a time-related variation occurs in the organic EL element 42 in a case where the voltage V_{F} is not fed back, the relationship comes to fulfill formula (5) below. A broken line 511 in FIG. 44 represents the curve that fulfills formula (5) below. Here, the variables “a” and “b” used in formulae (4) and (5) below are the same as those used in the description of the tenth embodiment given earlier and in formula (1) and (2) noted earlier.
y_{I}=a^{x} (4)
y_{I}=a^{x}/b (5)

In the fourteenth embodiment, since the current waveform of the organic EL element 42 during the light emission period is square, a time-related variation causes the effective value of the current I_{OLED} to drop equally at all levels of gradation. Thus, in the fourteenth embodiment, formula (5) above holds on the assumption that the proportion of the drop in the effective value of the current I_{OLED} is equal at all levels of gradation.

By contrast, in a case where the voltage V_{F} is fed back, the relationship between y_{I} and x, which fulfills formula (4) above in the initial state, comes to fulfill, when a time-related variation occurs in the organic EL element 42, formula (6) below. Here, “c” in formula (6) below is the same variable as that used in formula (3) noted earlier in connection with the tenth embodiment.
y_{I}=a ^{(x+c)}/b=a^{x}·a^{c}/b (6)

Here, the configuration needs to be so designed as to fulfill the formula “b=a^{c}”. That is, the value of “a” is determined according to the characteristics (time-related variation characteristics) of the organic EL element 42, the characteristics of the driving transistor TR23, and other factors in such a way as to fulfill the formula “b=a^{c}”. This makes formula (6) identical with formula (4) above in the initial state, and thus the drop in the effective value of the current I_{OLED} resulting form a time-related variation or the like is (ideally) completely compensated for. Since the current waveform of the organic EL element 42 is square, even when a time-related variation or the like occurs, the relationship between the data voltage and the effective value of the current I_{OLED} (that is, the curvature of the gamma characteristic) does not change. Needless to say, this can be achieved without black level deterioration. Incidentally, the gamma characteristic expressed by formula (4) above is deviated from the reference gamma characteristic of a display (with a gamma value of 2.2), and therefore it is necessary to perform gamma conversion in an external circuit (for example, within the image signal processing circuit 6 shown in FIG. 1).

### Fifteenth Embodiment

A fifteenth embodiment of the present invention as applied to an organic EL display device will be described below. The overall configuration of the organic EL display device of the fifteenth embodiment of the present invention is similar to that shown in FIG. 20 corresponding to the seventh embodiment, and therefore no separate diagram is furnished in this aspect. The individual circuit blocks constituting the organic EL display device are so modified as to realize, as desired in this embodiment, the operation described below.

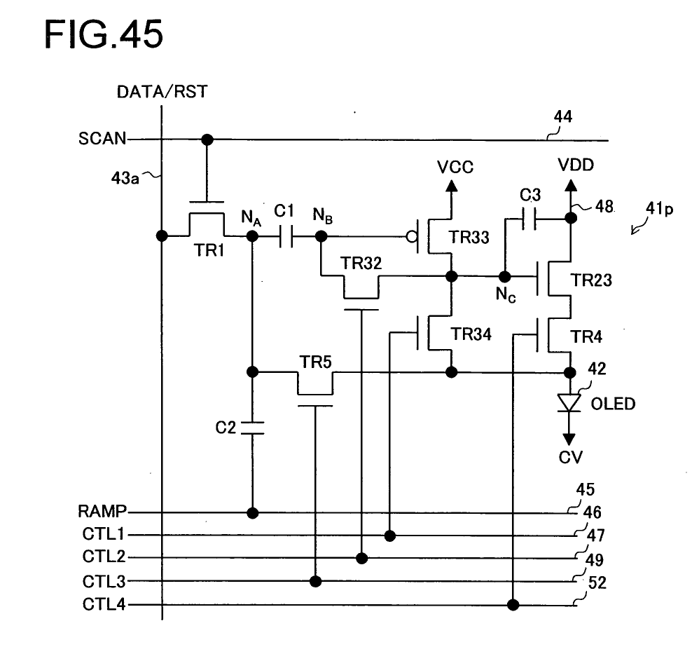

In this embodiment, the display panel 4f is so modified that each pixel 41p constituting it is built with a pixel circuit configured as shown in FIG. 45. In this embodiment, the ramp voltage generation circuit 8f generates a ramp voltage RAMP and feeds it to the display panel 4f, and the control signal generation circuit 5f feeds control signals CTL1, CTL2, CTL3, and CTL4 to each pixel constituting the display panel 4f. The pixel 41p shown in FIG. 45 is similar to the pixel 41n shown in FIG. 41. In FIG. 45, such elements as are found also in FIGS. 21, 38, and 41 are identified with common reference numerals and symbols, and no overlapping explanations will be repeated.

The pixel 41p (the pixel circuit of the pixel 41p) differs from the pixel 41n (the pixel circuit of the pixel 41n) shown in FIG. 41 in the following respects: the first electrode of the writing transistor TR1 is connected to a data voltage line 43a to which a data voltage DATA is applied with predetermined timing and to which a reset voltage RST (this reset voltage RST has a previously set voltage) is applied with other predetermined timing; the gate of the adjustment transistor TR5 is connected to a control signal line 49 to which the control signal CTL3 is fed from the control signal generation circuit 5f; and the gate of the on/off transistor TR4 is connected to a control signal line 52 to which the control signal CTL4 is fed from the control signal generation circuit 5f. Otherwise, the pixels of this and the fourteenth embodiments are identically configured.

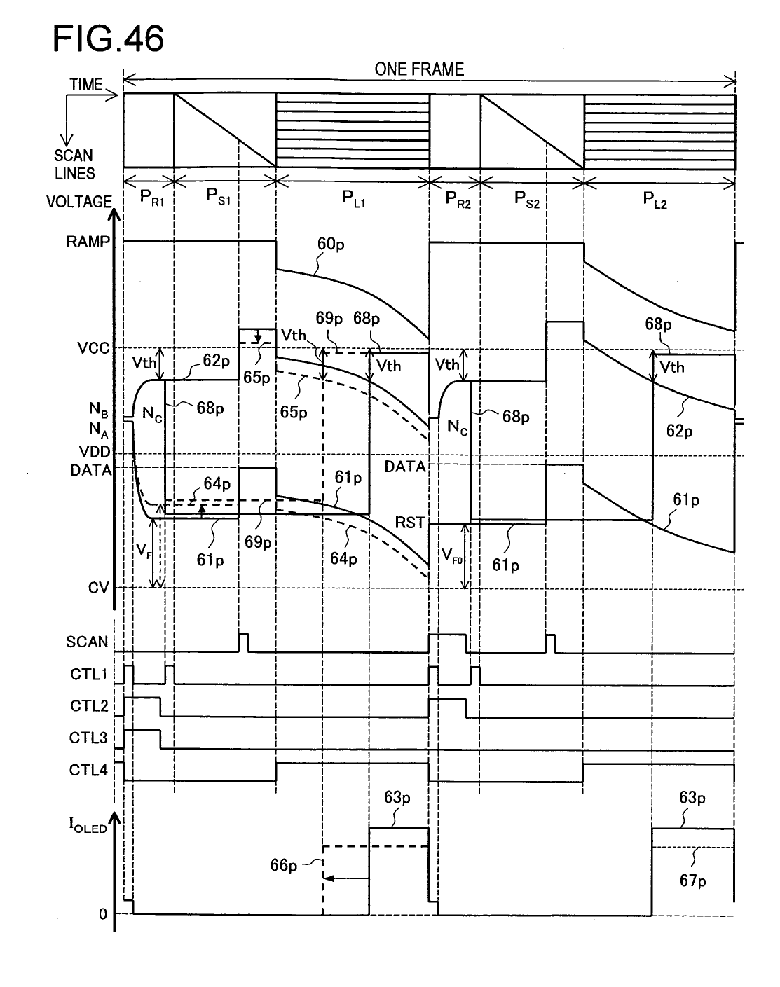

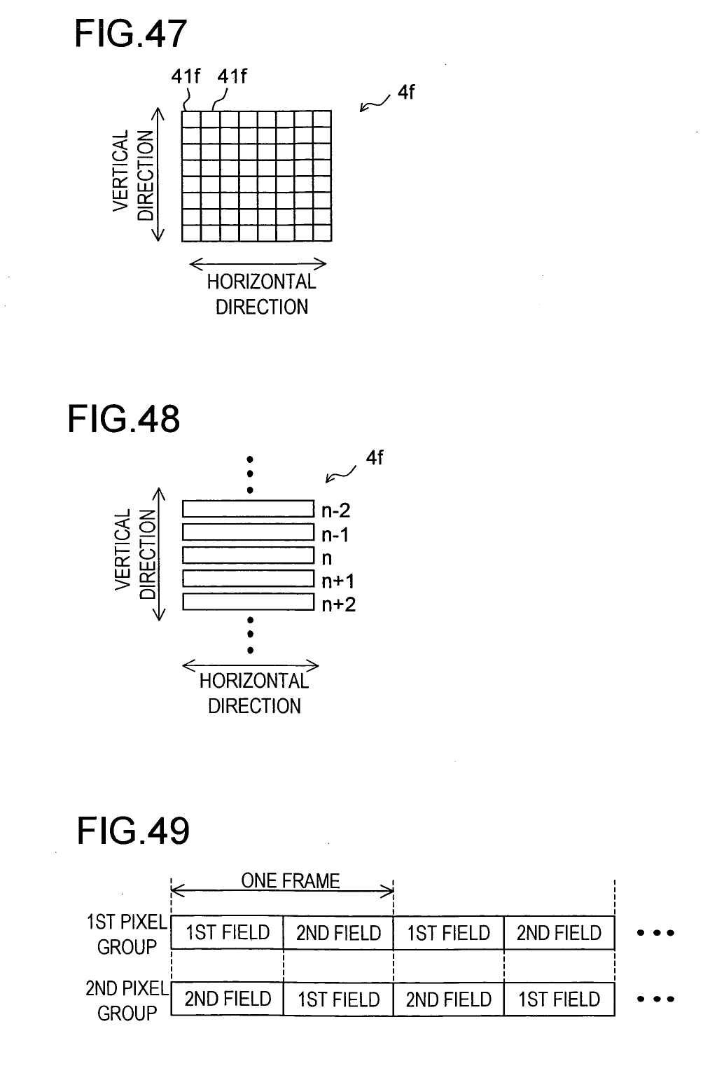

Now, with reference to FIG. 46, the operation of the organic EL display device of the fifteenth embodiment will be described. FIG. 46 shows the voltages at relevant points in FIG. 45 and the current I_{OLED} through the organic EL element 42 as observed over one frame period. The period for the display of one screen, that is, one frame period (the reciprocal of the frame frequency), consists of two fields, namely a first field and a second field. As in the seventh embodiment, the first field consists of a reset period P_{R1}, a scan period P_{S1}, and a light emission period P_{L1}, and the second field consists of a reset period P_{R2}, a scan period P_{S2}, and a light emission period P_{L2}.

Also in this embodiment, to solve the previously mentioned problem of black level deterioration, during, of the first and second fields, only the first field, the current I_{OLED} is compensated for a variation in the voltage V_{F}; moreover, the LUT 9 feeds the gradation signal to the data driver 3f after converting it into a first converted gradation signal corresponding to the first field and a second converted gradation signal corresponding to the second field in such a way that a relationship similar to that realized in the seventh embodiment (FIGS. 23 to 27) is realized between the level of gradation specified by the gradation signal and the effective value of the current I_{OLED}. Thus, advantages similar to those achieved in the seventh embodiment are achieved here.

A solid line 60p represents the voltage waveform of the ramp voltage RAMP fed from the ramp voltage generation circuit 8f to the ramp voltage line 45. The ramp voltage RAMP remains fixed at a previously set initial voltage during the reset and scan periods of each field (that is, P_{R1}, P_{S1}, P_{R2}, and P_{S2}), and then decreases at a previously set variation rate during the light emission period of each field (that is, P_{L1} and P_{L2}). Then, during the reset period of each field (that is, P_{R1} and P_{R2}), the ramp voltage RAMP stops decreasing and turns back to the initial voltage.

Solid lines 61p, 62p, and 68p represent the voltage waveforms observed at the nodes N_{A}, N_{B}, and N_{C}, respectively, when the V_{OLED}-I_{OLED} characteristic of the organic EL element 42 is as indicated by the solid line 201 in FIG. 18. A solid line 63p represents the waveform of the current I_{OLED} that flows through the organic EL element 42 when the V_{OLED}-I_{OLED} characteristic of the organic EL element 42 is as indicated by the solid line 201 in FIG. 18.

Broken lines 64p, 65p, and 69p represent the voltage waveforms observed at the nodes N_{A}, N_{B}, and N_{C}, respectively, when, because of a time-related variation in the organic EL element 42 or because of a drop in the operating ambient temperature, the V_{OLED}-I_{OLED} characteristic of the organic EL element 42 has shifted as indicated by the broken line 202 in FIG. 18. Likewise, the broken line 66p represents the waveform of the current I_{OLED} that flows through the organic EL element 42 when the V_{OLED}-I_{OLED} characteristic of the organic EL element 42 has shifted as indicated by the broken line 202 in FIG. 18. It should be noted that, in the second field, the solid line 61p and the broken line 64p are identical and thus overlap each other, the solid line 62p and the broken line 65p are identical and thus overlap each other, and the solid line 68p and the broken line 69p are identical and thus overlap each other.

A broken line 67p represents the waveform of the current I_{OLED} as observed when, in a case where a variation in the voltage V_{F} attributable to a time-related variation or the like in the organic EL element 42 is not fed back, the current I_{OLED} has decreased because of a time-related variation or the like. In the second field, the broken line 66p and the broken line 67p are identical and thus overlap each other.

The scan voltage SCAN is kept low during each light emission period (that is, P_{L1} and P_{L2}) and during the reset period P_{R1}. The control voltages CTL1, CTL2, and CTL3 are kept low during each scan period (that is, P_{S1} and P_{S2}) and during each light emission period (that is, P_{L1} and P_{L2}). The control signal CTL3 is kept low also during the reset period P_{R2}. The control signal CTL4 is kept low during each reset period (that is, P_{R1} and P_{R2}) and during each scan period (that is, P_{S1} and P_{S2}), and is kept high during each light emission period (that is, P_{L1} and P_{L2}). The reset voltage RST(=CV+V_{F0}) is applied to the data voltage line 43a only during the reset period P_{R2}, and otherwise the data voltage DATA from the data driver 3f is applied thereto.

The following description of the operation starts with the reset period P_{R1} of the kth frame period. The operations performed in the first field are similar to those performed in one frame in the fourteenth embodiment. When the reset period P_{R1} begins, the CTL1, CTL2, and CTL3 are turned from low to high, and the control signal CTL4 is turned from high to low. Thereafter, first, only the control signal CTL1 is turned back low. After the voltage at the node N_{A} stabilizes at (CV+V_{F}) and the voltages at the nodes N_{B} and N_{C} stabilize at (VCC−Vth), the control signals CTL2 and CTL3 are turned back low. Thereafter, the control signal CTL1 is kept high for a predetermined period, the voltage at the node N_{C} is made equal to (CV+V_{F}), and then the scan period P_{S1} begins.

The variation of the ramp voltage RAMP during the scan period P_{S1} and the light emission period P_{L1}, the operation of the individual transistors provided in the pixel 41p, and the variation of the voltages at the nodes N_{A}, N_{B}, and N_{C} are the same as those during the scan period and the light emission period in the fourteenth embodiment. It should be noted, however, that, in the fifteenth embodiment, to keep the on/off transistor TR4 on and the adjustment transistor TR5 off during the light emission period P_{L1}, the control voltages CTL3 and CTL4 are kept low and high, respectively, during the light emission period P_{L1}.

At the transition from the light emission period P_{L1} to the reset period P_{R2}, the control signal CTL4 is turned low to stop light emission, and the scan voltage SCAN is turned high. As described previously, during the reset period P_{R2}, the reset voltage RST is fed to the data voltage line 43a, and thus the voltage at the node N_{A} is approximately equal to the reset voltage RST. The reset voltage RST is set to be approximately equal to the sum of the negative-side supply voltage CV and the voltage V_{F} in the initial state (that is, V_{F0}).

Moreover, at the transition from the light emission period P_{L1} to the reset period P_{R2}, the control signals CTL1 and CTL2 are turned high. This causes a current to flow from the supply voltage VCC via the switching transistor TR33 and the on/off transistor TR34 to the organic EL element 42, making the voltages at the nodes N_{B} and N_{C} equal to a voltage higher than the supply voltage CV by the voltage distributed as the anode-to-cathode voltage of the organic EL element 42. Thereafter, the control signal CTL1 is turned low, and then, when the voltages at the nodes N_{B} and N_{C} stabilize at (VCC−Vth), the control signal CTL2 also is turned low. Approximately at the same time that the control signal CTL2 is turned low, the scan voltage SCAN is turned low. Thereafter, the control signal CTL1 is kept high for a predetermined period, the voltage at the node N_{C} is made equal to (CV+V_{F}), and then the scan period P_{S2} begins.

Except for the difference in the variation rate of the ramp voltage RAMP, the operations performed during the scan period P_{S2} and the light emission period P_{L2} are the same as those performed during the scan period P_{S1} and the light emission period P_{L1}. During the reset period P_{R2}, however, no voltage commensurate with the voltage V_{F} is held in the capacitor C1, and therefore no compensation is made for a drop in the current I_{OLED} resulting form a time-related variation or the like. At the transition from the light emission period P_{L2} to the reset period P_{R1} of the next frame, the ramp voltage RAMP is turned back to the initial voltage, and, in the next frame, operations similar to those described above are repeated.

Also in this embodiment, as in the fourteenth embodiment, when the driving transistor TR23 is turned on during each light emission period, the operating point of the driving transistor TR23 is set within the linear region, and the gate-to-source voltage of the driving transistor TR23 is made sufficiently high.

This embodiment corresponds to a combination of the fourteenth embodiment with, for example, the tenth embodiment, and is thus expected to offer advantages similar to those achieved by the fourteenth embodiment; moreover, it offers the benefit of, as described above in connection with a comparison between, on one hand, FIGS. 23 and 24 and, on the other hand, FIGS. 25 and 26, freely varying the degree of feedback according to the variation in the voltage V_{F}. While a configuration, like that of the fourteenth embodiment, where frames are not divided, may suffer from black level deterioration as a result of compensation, in the fifteenth embodiment, the effective value of the current I_{OLED} can be so set, for example, as to rise exponentially from an intermediate level t₀ of gradation in this first field as shown in FIG. 25. This helps securely suppress black level deterioration.

The relationship between the data voltage and the current I_{OLED} in the first field may be set as shown in FIG. 44. When this relationship is considered in the context of the fifteenth embodiment, the horizontal axis of the FIG. 44 represents the data voltage fed from the data driver 3f to each pixel in the first field, and the vertical axis represents the effective value of the current I_{OLED} that flows through the organic EL element 42 of each pixel to corresponding to the data voltage fed in the first field.

As described earlier, the LUT 9 converts the gradation signal fed thereto into a first converted gradation signal and a second converted gradation signal, and feeds the data driver 3f with the first converted gradation signal in the first field and with the second converted gradation signal in the second field. When the data driver 3f receives a first converted gradation signal, it sets the data voltage DATA to be fed to a pixel during the scan period P_{S1} of the first field equal to a first data voltage commensurate with the first converted gradation signal. Likewise, when the data driver 3f receives a second converted gradation signal, it sets the data voltage DATA to be fed to a pixel during the scan period P_{S2} of the second field equal to a second data voltage commensurate with the second converted gradation signal.

Thus, when the relationship shown in FIG. 44 is considered in the context of the fifteenth embodiment, “D” is regarded as the magnitude of the first data voltage fed from the data driver 3f to each pixel to correspond to a given first converted gradation signal, “I” is regarded as the effective value of the current I_{OLED} that flows in the first field when a first data voltage with a magnitude D is fed to each pixel in its initial state; “D_{B}” and “D_{W}” are regarded as the magnitudes of the first data voltage fed to each pixel when the level of gradation specified by the gradation signal fed to the data driver 3f is the black and white levels, respectively; “I_{B}” and “I_{W}” are regarded as the effective values of the current I_{OLED} that flows in the first field when a first data voltage with a magnitude D_{B} or D_{W}, respectively, is fed to each pixel in its initial state. Moreover, as in the fourteenth embodiment, let x=D−D_{B} and let y_{I}=I−I_{B}+1.

In this case, the variation rate of the ramp voltage RAMP during the light emission period P_{L1} in the first field is so set (that is, the ramp voltage RAMP is given such a curvature) as to fulfill formula (4) above in the initial state. A solid line 510 in FIG. 44 represents the curve fulfilling formula (4) above. While, in the initial state, the relationship between “y_{I}” and “x” fulfills formula (4), when a time-related variation occurs in the organic EL element 42 in a case where the voltage V_{F} is not fed back, the relationship comes to fulfill formula (5) above. A broken line 511 in FIG. 44 represents the curve that fulfills formula (5) above. It should be noted that, in the fifteenth embodiment, “b” reflects the drop in the current both in the first and second fields. That is, in a case where, as in the example of the conventional configuration shown in FIG. 16, the voltage V_{F} is not fed back, the degree of deterioration “b” when the effective value of the current I_{OLED} over one entire frame period corresponding to a given gradation signal becomes ½, ⅓, ¼, . . . is assumed to be 2, 3, 4, . . . , respectively.

By contrast, in a case where the voltage V_{F} is fed back, the relationship between y_{I} and x, which fulfills formula (4) above in the initial state, comes to fulfill, when a time-related variation occurs in the organic EL element 42, formula (6) above. Here, the configuration needs to be so designed as to fulfill the formula “b=a^{c}”. That is, the value of “a” is determined according to the characteristics (time-related variation characteristics) of the organic EL element 42, the characteristics of the driving transistor TR23, and other factors in such a way as to fulfill the formula “b=a^{c}”. This makes formula (6) identical with formula (4) above in the initial state, and thus the drop in the effective value of the current I_{OLED} resulting form a time-related variation or the like is (ideally completely) compensated for. Moreover, this is achieved without black level deterioration.

### Sixteenth Embodiment

The seventh to thirteenth and fifteenth embodiments assume that the first and second fields occur in the same order in all the pixels. Modifications are possible in which the order in which those fields occur is varied from one pixel to another. Such modifications are applicable to any of the seventh to thirteenth and fifteenth embodiments. As an example of such a modification as applied to the seventh embodiment, a sixteenth embodiment of the present invention will be described below. The individual circuit blocks constituting the organic EL display device are so modified as to realize the operation described below.

The display panel 4f is composed of a plurality of pixels 41f arrayed in columns and rows that extend in the vertical and horizontal directions, respectively (that is, in a matrix). Thus, the display panel 4f is composed of a plurality of horizontal lines and a plurality of vertical lines. A plurality of pixels 41f that are adjacent to one another in the horizontal direction form one horizontal line, and a plurality of pixels 41f that are adjacent to one another in the vertical direction form one vertical line.

FIG. 48 shows five horizontal lines. With respect to nth horizontal line (where n represents an arbitrary integer), the horizontal lines located one pixel, two pixels, . . . , and k pixels (where k is a natural number) above it are called the (n−1)th, (n−2)th, . . . , and (n−k)th horizontal line, and the horizontal lines located one pixel, two pixels, . . . , and k pixels (where k is a natural number) below it are called the (n+1)th, (n+2)th, . . . , and (n+k)th horizontal line. The direction in which one horizontal line is located “above” or “below” another is assumed to coincide with the vertical direction of the display panel 4f.

For example, consider the following case: the pixels 41f in the nth horizontal line and the pixels 41f in the horizontal lines located any even number of pixels above or below the nth horizontal line are grouped into a first pixel group; on the other hand, the pixels 41f in the horizontal lines located any odd number of pixels above or below the nth horizontal line are grouped into a second pixel group. In this case, the pixels 41f in the (n−2)th, nth, and (n+2)th horizontal lines are grouped into the first pixel group, and, the pixels 41f in the (n−1)th and (n+1)th horizontal lines are grouped into the second pixel group.

Here, in each frame, the order in which the first and second fields occur is changed between for the first and second pixel groups. For example, as shown in FIG. 49, for the first pixel group, in each frame, first the first frame and then the second field occur, and, for the second pixel group, in each frame, first the second frame and then the first field occur.

As will be understood from FIGS. 23 to 26, the magnitude of the effective value of the current I_{OLED} in response to a given gradation signal differs between in the first and second fields. Here, by making the first and second fields occur in different orders between for the first and second pixel groups as described above, it is possible to reduce fluctuation in brightness and thereby reduce flickering (on the screen). Moreover, doing so prevents the pixels from all operating simultaneously in the second field where the current I_{OLED} is comparatively high, and thus helps reduce the maximum value (peak current magnitude) of the current I_{OLED}.

Many modifications are possible in terms of how the pixels are grouped into a first and a second group. The pixels constituting the display panel may be grouped into a first and a second group in any manner so long as they exhibit some kind of periodicity in the vertical and/or horizontal directions. For example, instead of alternating the first and second pixel groups every horizontal line as described above, it is also possible to alternate them every 2, 3, . . . , or k horizontal lines. Alternatively, the horizontal lines in the above description may be read as vertical lines so that the pixels are grouped into the first and second groups from one vertical line to the next.

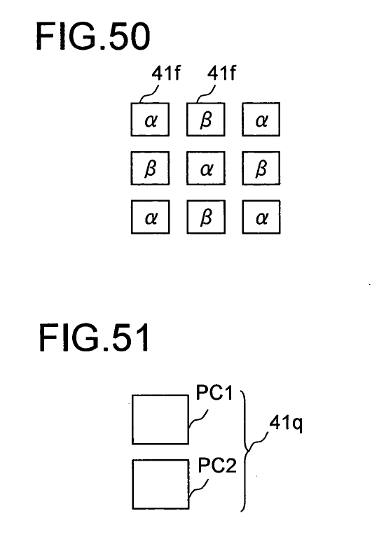

Alternatively, the pixels may be so grouped that, with respect to a given pixel 41f of interest, all the pixels adjacent thereto in the vertical (up-down) and horizontal (right-left) directions belong to a pixel group different from that to which the pixel of interest belongs. Specifically, as shown in FIG. 50, the pixels are so grouped that, with respect to every pixel 41f (indicated as “α” in FIG. 50) belonging to a first pixel group, the four pixels 41f (indicated as “β” in FIG. 50) adjacent thereto in the vertical and horizontal directions all belong to a second pixel group.

### Seventeenth Embodiment

The seventh to thirteenth and fifteenth embodiments assume that the first and second fields do not occur simultaneously. In these embodiments, however, modifications are possible in which, in each period, the first and second periods occur simultaneously. Such modifications are applicable to any of the seventh to thirteenth and fifteenth embodiments. As an example of such a modification as applied to the seventh embodiment, a seventeenth embodiment of the present invention will be described below. The individual circuit blocks constituting the organic EL display device are so modified as to realize the operation described below.

In this embodiment, the display panel 4f is composed of pixels 41q, of which each is configured as shown in FIG. 51, arrayed in a matrix. Each pixel 41q is built with two pixel circuits PC1 and PC2. The pixel circuits PC1 and PC2 are each configured like the pixel circuit of the pixel 41f shown in FIG. 21. Specifically, the pixel circuits PC1 and PC2 each include: an organic EL element 42; a writing transistor TR1; a driving transistor TR3; an adjustment transistor TR5; a turning-off transistor TR7; a capacitor C1; and a capacitor C2. These components (that is, the organic EL element 42 etc.) are interconnected in the same manner as in the pixel circuit of the pixel 41f. Here, advisably, the data voltage line 43a, the scan voltage line 44, the ramp voltage lines 55 and 56, and the control signal line 46 are provided in two sets so that those of one set are connected to the pixel circuit PC1 and those of the other set are connected to the pixel circuit PC2.

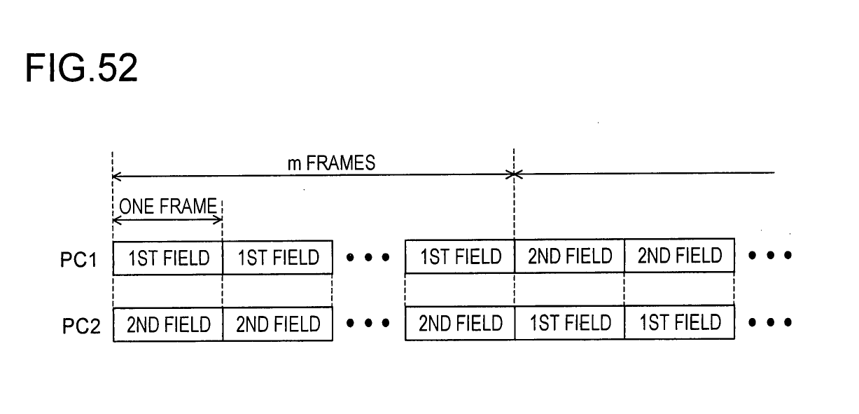

In this configuration, as shown in FIG. 52, during a given frame period, the pixel circuit PC1 of each pixel 41q performs the same operations as those performed by the pixel 41f of the seventh embodiment in the first field (hereinafter the “first-field operations”), and simultaneously the pixel circuit PC2 of each pixel 41q performs the same operations as those performed by the pixel 41f of the seventh embodiment in the second field (hereinafter the “second-field operations”).

When the pixel circuit PC1 ends the first-field operations and the pixel circuit PC2 also ends the second-field operations, the next frame begins. Thus, the length of one frame period in this embodiment equals one half (or approximately one half) of the length of one frame period in the seventh embodiment. When the next frame begins, for example, the pixel circuit PC1 performs the first-field operations again and simultaneously the pixel circuit PC2 performs the second-field operations again, and then the next frame begins.

After a frame in which the pixel circuit PC1 performs the first-field operations and simultaneously the pixel circuit PC2 performs the second-field operations has been repeated m times (where m is an integer equal to one or greater), in the subsequent frame, the pixel circuit PC1 performs the second-field operations and simultaneously the pixel circuit PC2 performs the first-field operations. That is, the operations of the pixel circuit PC1 is switched from the first-field operations to the second-field operations and the operations of the pixel circuit PC2 is switched from the second-field operations to the first-field operations. Then, after a frame in which the pixel circuit PC1 performs the second-field operations and simultaneously the pixel circuit PC2 performs the first-field operations has been repeated m times, the pixel circuit PC1 again performs the first-field operations and simultaneously the pixel circuit PC2 again performs the second-field operations. In this way, every predetermined number of frames (m frames, specifically, for example, m=1), the operations performed by the pixel circuits PC1 and PC2 are interchanged between the first-field and second-field operations.

With the above-described configuration, the light emission periods of the first and second fields occur (substantially) simultaneously. This enhances the dynamic characteristics of the display panel, and helps reduce flickering. Moreover, since the light emission related to a single set of image data takes place simultaneously, the user can view a moving picture that is truer to life. Moreover, since the first-field and second-field operations are switched between the pixel circuits PC1 and PC2 every predetermined number of frames, the organic EL element 42 deteriorates at uniform speed.

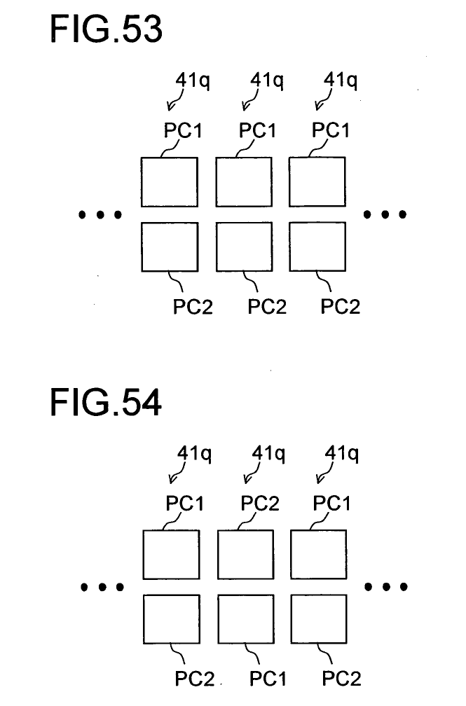

Many modifications are possible in terms of the arrangement of the pixel circuits PC1 and PC2 within the pixel 41q. For example, as shown in FIG. 53, the pixel circuits PC1 and PC2 may be arranged identically within the pixel 41q between adjacent pixels 41q, or, as shown in FIG. 54, the pixel circuits PC1 and PC2 may be arranged oppositely within the pixel 41q between adjacent pixels 41q.

### Other Modifications and Variations

The organic EL display devices of all the embodiments described heretofore are so configured as to reduce variations in brightness resulting from time-related and temperature-related variations. This permits the driving transistor to be operated in a lower-voltage part of the saturation region than is conventionally possible, or in the linear region. This leads to lower power consumption.

The first to seventeenth embodiments described heretofore may be practiced in any combined manner unless contradictions arise. The features described in connection with any of the embodiments may be applied to any other unless contradictions arise.

In the seventh to thirteenth embodiments and fifteenth to seventeenth embodiments, the magnitude (VDD−CV) of the supply voltage for supplying electric power to each display element (the organic EL element 42) via the corresponding driving transistor may be varied between the first and second fields. The supply voltage with the magnitude (VDD−CV) is supplied from an unillustrated power supply circuit, and there is additionally provided a supply voltage controller (unillustrated) for controlling the magnitude of the supply voltage.

Specifically, for example, the potential of VDD and/or CV is varied between the first and second fields so that the magnitude (VDD−CV) of the supply voltage is lower in the second field than in the first field. This leads to further reduced power consumption. In this case, it is preferable that, in the first field, the operating point of the driving transistor lie within the saturation region and that, in the second field, operating point of the driving transistor lie within the linear region.

As described earlier with reference to FIGS. 23 to 26, in the first field, where feedback is performed according to a variation in the voltage V_{F}, it is necessary to increase the current I_{OLED} exponentially as the level of gradation becomes higher. When this is taken into consideration, it is preferable that, in the first field, the operating point of the driving transistor be set within the saturation region. This is because, when the operating point lies within the saturation region, even if the V_{OLED}-I_{OLED} characteristic of the organic EL element 42 shifts from as indicated by the solid line 201 in FIG. 18 to as indicated by the broken line 202, no change arises in the relationship between the level of gradation and the current I_{OLED} (that is, the exponential curve is maintained). On the other hand, in the second field, there is no need to do so, and therefore the magnitude (VDD−CV) of the supply voltage can be made as low as desired.

In the seventh to eleventh, thirteenth, and fifteenth to seventeenth embodiments, all or part of the function of the LUT 9 may be incorporated in the ramp voltage generation circuit 8f. Specifically, in the first and/or second field, the gamma conversion by the LUT 9 (that is, conversion of a gradation signal into a first and second converted gradation signal) may be omitted or modified. In this case, a desired characteristic is obtained by varying the slope or curvature of a ramp voltage and/or the direct-current component of the ramp voltage.

To obtain a desired characteristic, in the first field, either or both of “gamma conversion by the LUT 9” and “varying of the slope or curvature of a ramp voltage and/or the direct-current component of the ramp voltage” are performed, and, in the second filed, either or both of “gamma conversion by the LUT 9” and “varying of the slope or curvature of a ramp voltage and/or the direct-current component of the ramp voltage” are performed. Whether or not to perform “gamma conversion by the LUT 9” and “varying of the slope or curvature of a ramp voltage and/or the direct-current component of the ramp voltage” may be varied between the first and second fields.

The direct-current component of a ramp voltage denotes, for example in the seventh embodiment, the direct-current component present in the ramp voltage RAMP1 during the light emission periods P_{L1} and P_{L2}. The drop in the ramp voltage RAMP1 at the beginning of the light emission periods P_{L1} and P_{L2} may be regarded as the direct-current component in the ramp voltage.

In all the embodiments, the feedback controller, which is given the function of “transmitting a voltage (feedback voltage) commensurate with the voltage V_{F} to the capacitor C1 during a light emission preparation period (a reset period and/or a scan period) to make the capacitor C1 hold a held voltage reflecting that voltage” is constituted mainly by the control signal generation circuit (5, 5e, 5f, or 5k) and/or the ramp voltage generation circuit (8 or 8f). In addition to or in place of these, the scan driver (in particular, the scan driver 2f in the ninth embodiment) may be given the function of the feedback controller.

The order in which the first and second fields occur in the seventh to thirteenth and fifteenth embodiments is merely an example, and may therefore be reversed in practice. Specifically, in each frame, the first field may occur before the second field does, or the second field may occur before the first field does. Alternatively, a frame may consist of three or more fields.

The input and output signals to and from the LUT 9 shown in FIGS. 20 and 37 are, for example, digital signals. In this case, if the input required by the data driver (3f or 3k) is an analog signal, a D/A converter (unillustrated) is provided between the LUT 9 and the data driver (3f or 3k). This D/A converter may be incorporated in the data driver (3f or 3k). Likewise, in FIGS. 1 and 13, as necessary, a D/A converter is provided between the image signal processing circuit 6 and the data driver (3 or 3e).

FIGS. 1, 13, 20, and 37 show examples in which the data driver (3, 3e, 3f, or 3k) and the scan driver (2, 2e, 2f, or 2k) are provided outside the display panel (4, 4e, 4f, or 4k). In practice, the data driver and/or the scan driver may be incorporated in the display panel.

In the seventh to thirteenth and fifteenth to seventeenth embodiments, the LUT 9 may be replaced with one that handles an analog signal. A circuit having a function similar to that of the LUT 9 can generally be called a gamma conversion circuit. Moreover, considering that, as described above, all or part of the LUT 9 may be incorporated in the ramp voltage generation circuit 8f, the gamma conversion circuit can be regarded as being constituted by the LUT 9 and/or the ramp voltage generation circuit 8f.

In the seventh to twelfth and fifteenth embodiments, the voltage at the node N_{A}, N_{B}, or N_{C} during the reset period P_{R2} or the scan period P_{S2} is stated as being equal to (CV+V_{F0}). The voltage there may be other than (CV+V_{F0}). Even when the voltage there is other than (CV+V_{F0}), appropriately changing the other conditions makes it possible to obtain the benefits of the present invention.

The first to sixth embodiments deal with examples in which a reset period occurs in a last part of one frame period. Instead, a reset period may be made to occur in a first part of one frame period as in the fourteenth embodiment. Specifically, in the first to fifth embodiments, a modification is possible in which, the kth (where k is a natural number) frame period starts with a reset period so that the reset period, a scan period, and a light emission period occur in this order. In the sixth embodiment, a modification is possible in which the kth (where k is a natural number) frame period starts with a reset period so that the reset period and a light emission period occur in this order.

The present invention is suitable for display devices such as organic EL display devices in which electroluminescent (EL) elements are driven by the use of thin-film transistors (TFTs), and is suitable particularly for active-matrix-driven organic EL display devices.

What is claimed is:

1. An active-matrix-driven display device including a display panel composed of a plurality of pixels arrayed in a matrix, the display panel being connected to a scan driver for feeding a scan voltage to each pixel and a data driver for feeding a data voltage to each pixel, the display panel being so driven that each frame period contains at least a reset period and a light emission period, each pixel being built with a pixel circuit including:
a display element that emits light when fed with electric power;
a writing transistor that has a first electrode thereof connected to the data driver and that is turned on when a scan voltage having a predetermined level is applied thereto from the scan driver;
a driving transistor that drives, according to a voltage applied to a control electrode thereof, the display element during the light emission period;
a first capacitive element that is provided in series with a line connecting a second electrode of the writing transistor to the control electrode of the driving transistor; and
an adjustment transistor that is turned on during the reset period to feed to a writing-transistor-side electrode of the first capacitive element a voltage commensurate with an electrode-to-electrode voltage of the display element,
wherein the active-matrix-driven display device further includes a control signal generation circuit that, during the reset period, for each pixel circuit, lets a voltage commensurate with a light emission start electrode-to-electrode voltage of the display element be held in the first capacitive element.

2. The active-matrix-driven display device of claim 1,
wherein, after an end of the reset period, for each pixel circuit, the scan driver turns the writing transistor on so that a voltage commensurate with the data voltage and the light emission start electrode-to-electrode voltage is applied to the control electrode of the driving transistor.

3. The active-matrix-driven display device of claim 1,
wherein, during the reset period, for each pixel circuit, the control signal generation circuit, while turning the adjustment transistor on, turns a driving-transistor-side electrode of the first capacitive element to a predetermined potential to let the voltage commensurate with the light emission start electrode-to-electrode voltage of the display element be held in the first capacitive element, and then turns the adjustment transistor off.

4. The active-matrix-driven display device of claim 1,
wherein, in each pixel circuit, the driving transistor has a first electrode, a second electrode, and the control electrode and so operates as to control a current flowing between the first electrode and the second electrode according to a voltage between the control electrode and the first electrode, and
wherein the pixel circuit of each pixel further includes:
an on/off transistor that is provided in series with a power supply line extending from a power source from which to feed electric power to the display element and that turns on and off feeding of electric power to the display element; and
a threshold value compensation transistor that has a first electrode thereof connected to the control electrode of the driving transistor and that has a second electrode thereof connected to the second electrode of the driving transistor.

5. The active-matrix-driven display device of claim 4,
wherein, during the reset period, for each pixel circuit, the control signal generation circuit turns the on/off transistor on and thereby turns the driving transistor on, then turns the on/off transistor off and turns the adjustment transistor and the threshold value compensation transistor on to let a voltage commensurate with the light emission start electrode-to-electrode voltage of the display element and an operation threshold voltage of the driving transistor be held in the first capacitive element, and then turns the adjustment transistor and the threshold value compensation transistor off, and
wherein, after an end of the reset period, for each pixel circuit, the scan driver turns the writing transistor on so that a voltage commensurate with the data voltage, the light emission start electrode-to-electrode voltage, and the operation threshold voltage is applied to the control electrode of the driving transistor.

6. The active-matrix-driven display device of claim 4,
wherein, during the reset period, for each pixel circuit, the control signal generation circuit temporarily feeds from outside the pixel a predetermined reset voltage to the control electrode of the driving transistor to temporarily turn the driving transistor on without turning the on/off transistor on, then turns the adjustment transistor and the threshold value compensation transistor on to let a voltage commensurate with the light emission start electrode-to-electrode voltage of the display element and an operation threshold voltage of the driving transistor be held in the first capacitive element, and then turns the adjustment transistor and the threshold value compensation transistor off, and
wherein, after an end of the reset period, for each pixel circuit, the scan driver turns the writing transistor on so that a voltage commensurate with the data voltage, the light emission start electrode-to-electrode voltage, and the operation threshold voltage is applied to the control electrode of the driving transistor.

7. The active-matrix-driven display device of claim 6,
wherein the pixel circuit of each pixel further includes a resetting transistor that, when turned on, short-circuits between both electrodes of the first capacitive element,
wherein the reset voltage is fed from the data driver during the reset period, and
wherein, during the reset period, for each pixel circuit, the scan driver turns the writing transistor on and the control signal generation circuit turns the resetting transistor on so that the reset voltage is temporarily fed to the control electrode of the driving transistor.

8. The active-matrix-driven display device of claim 1,
wherein the active-matrix-driven display device further includes a ramp voltage generation circuit that generates a ramp voltage whose voltage value varies at a predetermined variation rate, and
wherein the pixel circuit of each pixel includes a second capacitive element that feeds a variation in the ramp voltage to the writing-transistor-side electrode of the first capacitive element.

9. The active-matrix-driven display device of claim 8,
wherein the active-matrix-driven display device receives a gradation signal for image display to display an image,
wherein the data driver feeds a data voltage corresponding to the gradation signal to each pixel circuit, and
wherein the variation rate of the ramp voltage is so set that, for each pixel circuit,
let D represent a data voltage fed as corresponding to the received gradation signal,
let D_{B} represent a data voltage fed when the gradation signal represents a black level of gradation,
let L represent brightness obtained as a result of the display element emitting light according to the fed data voltage D,
let L_{B} represent brightness obtained when the gradation signal represents a black level of gradation,
let x represent D−D_{B}, and
let y represent L−L_{B}+1,
the formula y=a^{x} (where a is a constant fulfilling a>1) is fulfilled.

10. An active-matrix-driven display device including a display panel composed of a plurality of pixels arrayed in a matrix, the display panel being connected to a scan driver for feeding a scan voltage to each pixel and a data driver for feeding a data voltage to each pixel, the display panel being so driven that each frame period contains at least a reset period and a light emission period, each pixel being built with a pixel circuit including:
a display element that emits light when fed with electric power;
a writing transistor that has a first electrode thereof connected to the data driver and that is turned on when a scan voltage having a predetermined level is applied thereto from the scan driver;
a driving transistor that drives, according to a voltage applied to a control electrode thereof, the display element during the light emission period;
a pulse width modulation circuit that outputs, during the light emission period, a predetermined light emission level voltage for making the display element emit light during a period commensurate with a data voltage fed from the data driver while the writing transistor is on;
a first capacitive element that is provided in series with a line connecting an output end of the pulse width modulation circuit to the control electrode of the driving transistor; and
an adjustment transistor that is turned on during the reset period to feed to a pulse-width-modulation-circuit-side electrode of the first capacitive element a voltage commensurate with an electrode-to-electrode voltage of the display element,
wherein the active-matrix-driven display device further includes a control signal generation circuit that, during the reset period, for each pixel circuit, lets a voltage commensurate with a light emission start electrode-to-electrode voltage of the display element be held in the first capacitive element.

11. The active-matrix-driven display device of claim 10,
wherein, before the light emission period, for each pixel circuit, the scan driver turns the writing transistor on so that a voltage commensurate with the light emission level voltage and the light emission start electrode-to-electrode voltage is applied to the control electrode of the driving transistor for the period commensurate with the data voltage.

12. The active-matrix-driven display device of claim 10,
wherein, during the reset period, for each pixel circuit, the control signal generation circuit, while turning the adjustment transistor on, turns a driving-transistor-side electrode of the first capacitive element to a predetermined potential to let the voltage commensurate with the light emission start electrode-to-electrode voltage of the display element be held in the first capacitive element, and then turns the adjustment transistor off.

13. The active-matrix-driven display device of claim 10,
wherein, in each pixel circuit, the driving transistor has a first electrode, a second electrode, and the control electrode and so operates as to control a current flowing between the first electrode and the second electrode according to a voltage between the control electrode and the first electrode, and
wherein the pixel circuit of each pixel further includes:
an on/off transistor that is provided in series with a power supply line extending from a power source from which to feed electric power to the display element and that turns on and off feeding of electric power to the display element; and
a threshold value compensation transistor that has a first electrode thereof connected to the control electrode of the driving transistor and that has a second electrode thereof connected to the second electrode of the driving transistor.

14. The active-matrix-driven display device of claim 13,
wherein, during the reset period, for each pixel circuit, the control signal generation circuit turns the on/off transistor on and thereby turns the driving transistor on, then turns the on/off transistor off and turns the adjustment transistor and the threshold value compensation transistor on to let a voltage commensurate with the light emission start electrode-to-electrode voltage of the display element and an operation threshold voltage of the driving transistor be held in the first capacitive element, and then turns the adjustment transistor and the threshold value compensation transistor off, and
wherein, before the light emission period, for each pixel circuit, the scan driver turns the writing transistor on so that a voltage commensurate with the light emission level voltage, the light emission start electrode-to-electrode voltage, and the operation threshold voltage is applied to the control electrode of the driving transistor for the period commensurate with the data voltage.

15. The active-matrix-driven display device of claim 13,
wherein the pixel circuit of each pixel further includes a clipping circuit that prevents a potential at the control electrode of the driving transistor from becoming higher than a predetermined clip potential, or lower than a predetermined clip potential,
wherein the clip potential is set at a potential that permits, during the reset period, for each pixel circuit, the control signal generation circuit to turn the adjustment transistor on and thereby temporarily turn the driving transistor on,
wherein, during the reset period, for each pixel circuit, the control signal generation circuit turns the adjustment transistor and the threshold value compensation transistor on, without turning the on/off transistor on, to let a voltage commensurate with the light emission start electrode-to-electrode voltage of the display element and an operation threshold voltage of the driving transistor be held in the first capacitive element, and then turns the adjustment transistor and the threshold value compensation transistor off, and
wherein, before the light emission period, for each pixel circuit, the scan driver turns the writing transistor on so that a voltage commensurate with the light emission level voltage, the light emission start electrode-to-electrode voltage, and the operation threshold voltage is applied to the control electrode of the driving transistor for the period commensurate with the data voltage.

16. The active-matrix-driven display device of claim 10,
wherein the active-matrix-driven display device further includes a ramp voltage generation circuit that generates a ramp voltage whose voltage value varies at a predetermined variation rate, and
wherein, in each pixel circuit, the pulse width modulation circuit performs pulse width modulation on the data voltage by using the ramp voltage, and outputs, during the light emission period, the light emission level voltage for a period corresponding to a width of a pulse resulting from the pulse width modulation.

17. An active-matrix-driven display device including a display panel composed of a plurality of pixels arrayed in a matrix, the display panel being connected to a scan driver for feeding a scan voltage to each pixel and a data driver for feeding a data voltage to each pixel, the display panel being so driven that each frame period contains a first field and a second field of which each consists of a light emission preparation period and a light emission period, each pixel being built with a pixel circuit including:
a display element that emits light when fed with electric power;
a writing transistor that has a first electrode thereof connected to the data driver and that is turned on when a scan voltage having a predetermined level is applied thereto from the scan driver;
a driving transistor that drives, according to a voltage applied to a control electrode thereof, the display element;
a first capacitive element that, at one end thereof, is connected to the control electrode of the driving transistor; and
an adjustment transistor that is so connected to the display element as to receive, at a first electrode thereof, a voltage commensurate with an electrode-to-electrode voltage of the display element and that can transmit a feedback voltage commensurate with a light emission start electrode-to-electrode voltage of the display element to the first capacitive element,
wherein the active-matrix-driven display device further includes a feedback controller that, during the light emission preparation period of, of the first and second fields, only the first field, for each pixel circuit, transmits the feedback voltage to the first capacitive element so that a held voltage reflecting the feedback voltage is held in the first capacitive element.

18. The active-matrix-driven display device of claim 17,
wherein the active-matrix-driven display device receives a gradation signal for image display to display an image,
wherein the active-matrix-driven display device further includes a gamma conversion circuit that, on receiving a gradation signal representing a middle level of gradation, converts the gradation signal into a first converted gradation signal corresponding to the first field and a second converted gradation signal corresponding to the second field and then feeds the first and second converted gradation signals to the data driver so that an effective value of a current that flows through the display element during the light emission period of the first field is smaller than an effective value of a current that flows through the display element during the light emission period of the second field, and
wherein the data driver feeds each pixel circuit with a data voltage corresponding to the first converted gradation signal in the first field and with a data voltage corresponding to the second converted gradation signal in the second field.

19. The active-matrix-driven display device of claim 17,
wherein the active-matrix-driven display device receives a gradation signal for image display to display an image,
wherein the active-matrix-driven display device further includes a gamma conversion circuit that converts the gradation signal into a first converted gradation signal corresponding to the first field and a second converted gradation signal corresponding to the second field and then feeds the first and second converted gradation signals to the data driver so that, assuming that an effective value of a current to be passed through the display element of each pixel circuit to correspond to a gradation signal representing a middle level of gradation is a reference current value, an effective value of a current that flows through the display element during the light emission period of the first field is smaller than the reference current value and an effective value of a current that flows through the display element during the light emission period of the second field is larger than the reference current value,
wherein the data driver feeds each pixel circuit with a data voltage corresponding to the first converted gradation signal in the first field and with a data voltage corresponding to the second converted gradation signal in the second field.

20. The active-matrix-driven display device of claim 18,
wherein, in each pixel circuit, the driving transistor,
during the light emission period of the second field, receives at the control electrode thereof a voltage commensurate with the data voltage corresponding to the second converted gradation signal and drives the display element according to that voltage, and,
during the light emission period of the first field, receives at the control electrode thereof a voltage commensurate not only with the data voltage corresponding to the first converted gradation signal but also with the held voltage and drives the display element according to those voltages.

21. The active-matrix-driven display device of claim 17,
wherein, in each pixel circuit, the adjustment transistor has a second electrode thereof connected to the first capacitive element, and
wherein, during the light emission preparation period of the first field, for each pixel circuit, the feedback controller extracts, via the adjustment transistor and the display element, a positive electric charge at the second electrode of the adjustment transistor which is temporarily given a potential higher than a potential equal to a sum of a potential at a cathode of the display element and the light emission start electrode-to-electrode voltage to thereby transmit the feedback voltage to the first capacitive element, and then turns the adjustment transistor off to thereby let the held voltage be held in the first capacitive element.

22. The active-matrix-driven display device of claim 17,
wherein the feedback controller includes a control signal generation circuit that controls turning on and off of the adjustment transistor in each pixel circuit,
wherein, in each pixel circuit, the first capacitive element is provided in series with a line connecting a second electrode of the writing transistor to the control electrode of the driving transistor, and a second electrode of the adjustment transistor is connected to the writing-transistor-side electrode of the first capacitive element, and
wherein, during the light emission preparation period of the first field, for each pixel circuit, the control signal generation circuit turns the adjustment transistor on to transmit the feedback voltage to the first capacitive element, and then turns the adjustment transistor off to let the held voltage be held in the first capacitive element.

23. The active-matrix-driven display device of claim 22,
wherein the active-matrix-driven display device further includes a ramp voltage generation circuit that generates a ramp voltage whose voltage value varies at a predetermined variation rate, and
wherein the pixel circuit of each pixel includes a second capacitive element that feeds a variation in the ramp voltage to the writing-transistor-side electrode of the first capacitive element.

24. The active-matrix-driven display device of claim 22,
wherein, in each pixel circuit, the driving transistor has a first electrode, a second electrode, and the control electrode and so operates as to control a current flowing between the first electrode and the second electrode according to a voltage between the control electrode and the first electrode, and
wherein the pixel circuit of each pixel further includes:
an on/off transistor that is provided in series with a power supply line extending from a power source from which to feed electric power to the display element and that turns on and off feeding of electric power to the display element; and
a threshold value compensation transistor that has a first electrode thereof connected to the control electrode of the driving transistor and that has a second electrode thereof connected to the second electrode of the driving transistor.

25. The active-matrix-driven display device of claim 17,
wherein the feedback controller includes a ramp voltage generation circuit that, during the light emission period of each field, for each pixel circuit, feeds a first ramp voltage to the first electrode of the writing transistor and that outputs a second ramp voltage for controlling turning on and off of the adjustment transistor,
wherein, in each pixel circuit, the first capacitive element is provided in series with a line connecting a second electrode of the writing transistor to the control electrode of the driving transistor, and a second electrode of the adjustment transistor is connected to the driving-transistor-side electrode of the first capacitive element, and
wherein, during the light emission preparation period of the first field, for each pixel circuit, the ramp voltage generation circuit turns the adjustment transistor on to transmit the feedback voltage to the first capacitive element, and then turns the adjustment transistor off to let the held voltage be held in the first capacitive element.

26. The active-matrix-driven display device of claim 17,
wherein the active-matrix-driven display device further includes a ramp voltage generation circuit that generates a ramp voltage whose voltage value varies at a predetermined variation rate and that, during each light emission period, for each pixel circuit, feeds a variation in the ramp voltage via the first capacitive element to the control electrode of the driving transistor,
wherein, in each pixel circuit, the one end of the first capacitive element is connected to a second electrode of the writing transistor, and another end of the first capacitive element is connected to a second electrode of the adjustment transistor, and
wherein, during the light emission preparation period of the first field, for each pixel circuit, the feedback controller turns the adjustment transistor on to transmit the feedback voltage to the first capacitive element, and then turns the adjustment transistor off to let the held voltage be held in the first capacitive element.

27. An active-matrix-driven display device including a display panel composed of a plurality of pixels arrayed in a matrix, the display panel being connected to a scan driver for feeding a scan voltage to each pixel and a data driver for feeding a data voltage to each pixel, the display panel being so driven that each frame period contains a first field and a second field of which each consists of a light emission preparation period and a light emission period, each pixel being built with a pixel circuit including:
a display element that emits light when fed with electric power;
a writing transistor that has a first electrode thereof connected to the data driver and that is turned on when a scan voltage having a predetermined level is applied thereto from the scan driver;
a driving transistor that drives, according to a voltage applied to a control electrode thereof, the display element;
a first capacitive element that, at one end thereof, is connected to the control electrode of the driving transistor; and
an adjustment transistor that is so connected to the display element as to receive, at a first electrode thereof, a voltage commensurate with an electrode-to-electrode voltage of the display element and that can transmit a feedback voltage commensurate with a light emission start electrode-to-electrode voltage of the display element to the first capacitive element,
wherein the active-matrix-driven display device receives a gradation signal for image display to display an image, and further includes:
a ramp voltage generation circuit that generates a ramp voltage whose voltage value varies at a predetermined variation rate and that, during each light emission period, for each pixel circuit, feeds a variation in the ramp voltage via the first capacitive element to the control electrode of the driving transistor;
a feedback controller that, during the light emission preparation periods of both the first and second fields, for each pixel circuit, transmits the feedback voltage to the first capacitive element so that a held voltage reflecting the feedback voltage is held in the first capacitive element; and
a gamma conversion circuit that converts the gradation signal into a first converted gradation signal corresponding to the first field and a second converted gradation signal corresponding to the second field and then feeds the first and second converted gradation signals to the data driver so that, for each pixel circuit, a first data voltage that represents as a data voltage a high-gradation side of the gradation signal is fed to the pixel circuit in the first field and a second data voltage that represents as a data voltage a low-gradation side of the gradation signal is fed to the pixel circuit in the second field,
wherein the variation rate of the ramp voltage in the second field is higher than the variation rate of the ramp voltage in the first field.

28. The active-matrix-driven display device of claim 27,
wherein, in each pixel circuit, the adjustment transistor has a second electrode thereof connected to the first capacitive element, and
wherein, during the light emission preparation period of each of the first and second fields, for each pixel circuit, the feedback controller extracts, via the adjustment transistor and the display element, a positive electric charge at the second electrode of the adjustment transistor which is temporarily given a potential higher than a potential equal to a sum of a potential at a cathode of the display element and the light emission start electrode-to-electrode voltage to thereby transmit the feedback voltage to the first capacitive element, and then turns the adjustment transistor off to thereby let the held voltage be held in the first capacitive element.

29. An active-matrix-driven display device including a display panel composed of a plurality of pixels arrayed in a matrix, the display panel being connected to a scan driver for feeding a scan voltage to each pixel and a data driver for feeding a data voltage to each pixel, the display panel being so driven that each frame period contains at least a reset period and a light emission period, each pixel being built with a pixel circuit including:
a display element that emits light when fed with electric power;
a writing transistor that has a first electrode thereof connected to the data driver and that is turned on when a scan voltage having a predetermined level is applied thereto from the scan driver;
a driving transistor that drives, according to a voltage applied to a control electrode thereof, the display element during the light emission period;
a switching transistor that, when turned on, feeds a voltage for turning the driving transistor on to the control electrode of the driving transistor;
a first capacitive element that is provided in series with a line connecting a second electrode of the writing transistor to a control electrode of the switching transistor; and
an adjustment transistor that is turned on during the reset period to feed to a writing-transistor-side electrode of the first capacitive element a voltage commensurate with an electrode-to-electrode voltage of the display element,
wherein the active-matrix-driven display device further includes a control signal generation circuit that, during the reset period, for each pixel circuit, lets a voltage commensurate with a light emission start electrode-to-electrode voltage of the pixel be held in the first capacitive element.

30. The active-matrix-driven display device of claim 29,
wherein the active-matrix-driven display device further includes a ramp voltage generation circuit that generates a ramp voltage whose voltage value varies at a predetermined variation rate, and
wherein the pixel circuit of each pixel includes a second capacitive element that feeds a variation in the ramp voltage to the writing-transistor-side electrode of the first capacitive element.

31. The active-matrix-driven display device of claim 30,
wherein the active-matrix-driven display device receives a gradation signal for image display to display an image,
wherein the data driver feeds a data voltage corresponding to the gradation signal to each pixel circuit, and
wherein the variation rate of the ramp voltage is so set that, for each pixel circuit,
let D represent a data voltage fed as corresponding to the received gradation signal,
let D_{B} represent a data voltage fed when the gradation signal represents a black level of gradation,
let I represent an effective value of a current that flows through the display element as corresponding to the fed data voltage D,
let I_{B} represent an effective value of a current that flows through the display element when the gradation signal represents a black level of gradation,
let x represent D−D_{B}, and
let y_{I} represent I−I_{B}+1,
the formula y_{I}=a^{x} (where a is a constant fulfilling a>1) is fulfilled.

32. An active-matrix-driven display device including a display panel composed of a plurality of pixels arrayed in a matrix, the display panel being connected to a scan driver for feeding a scan voltage to each pixel and a data driver for feeding a data voltage to each pixel, the display panel being so driven that each frame period contains a first field and a second field of which each consists of a light emission preparation period and a light emission period, each pixel being built with a pixel circuit including:
a display element that emits light when fed with electric power;
a writing transistor that has a first electrode thereof connected to the data driver and that is turned on when a scan voltage having a predetermined level is applied thereto from the scan driver;
a driving transistor that drives, according to a voltage applied to a control electrode thereof, the display element;
a switching transistor that, when turned on, feeds a voltage for turning the driving transistor on to the control electrode of the driving transistor;
a first capacitive element that is provided in series with a line connecting a second electrode of the writing transistor to a control electrode of the switching transistor; and
an adjustment transistor that is so connected to the display element as to receive, at a first electrode thereof, a voltage commensurate with an electrode-to-electrode voltage of the display element and that can transmit a feedback voltage commensurate with a light emission start electrode-to-electrode voltage of the display element to the first capacitive element,
wherein the active-matrix-driven display device further includes a feedback controller that, during the light emission preparation period of, of the first and second fields, only the first field, for each pixel circuit, transmits the feedback voltage to the first capacitive element so that a held voltage reflecting the feedback voltage is held in the first capacitive element.

33. The active-matrix-driven display device of claim 32,
wherein the active-matrix-driven display device further includes a ramp voltage generation circuit that generates a ramp voltage whose voltage value varies at a predetermined variation rate, and
wherein the pixel circuit of each pixel includes a second capacitive element that feeds a variation in the ramp voltage to the writing-transistor-side electrode of the first capacitive element.

34. The active-matrix-driven display device of claim 33,
wherein the active-matrix-driven display device receives a gradation signal for image display to display an image,
wherein the active-matrix-driven display device further includes a gamma conversion circuit that converts the gradation signal into a first converted gradation signal corresponding to the first field and a second converted gradation signal corresponding to the second field and then feeds the first and second converted gradation signals to the data driver,
wherein the data driver feeds each pixel circuit with a first data voltage corresponding to the first converted gradation signal in the first field and with a second data voltage corresponding to the second converted gradation signal in the second field, and
wherein the variation rate of the ramp voltage is so set that, for each pixel circuit,
let D represent a first data voltage fed as corresponding to the received gradation signal,
let D_{B} represent a first data voltage fed when the gradation signal represents a black level of gradation,
let I represent an effective value of a current that flows, in the first field, through the display element as corresponding to the fed first data voltage D,
let I_{B} represent an effective value of a current that flows, in the first field, through the display element when the gradation signal represents a black level of gradation,
let x represent D−D_{B}, and
let y_{I} represent I−I_{B}+1,
the formula y_{I}=a^{x} (where a is a constant fulfilling a>1) is fulfilled.

35. The active-matrix-driven display device of claim 29,
wherein, in each pixel circuit, the voltage fed to the control electrode of the driving transistor while the switching transistor is on is constant.

36. The active-matrix-driven display device of claim 29,
wherein, in each pixel circuit, an operating point at which the driving transistor operates while the switching transistor is on is set within a linear region.

37. The active-matrix-driven display device of claim 17,
wherein the pixels constituting the display panel are divided into a first pixel group and a second pixel group with periodicity in a vertical and/or a horizontal direction of the display panel, and
wherein, during each frame period, the first and second fields are made to occur in different orders between in the first and second pixel groups.

38. The active-matrix-driven display device of claim 17,
wherein, during each frame period, the first and second fields occur simultaneously,
wherein each pixel has two of the pixel circuit, and
wherein, during each frame period, for each pixel, the feedback controller makes one pixel circuit operate in the first field and simultaneously makes the other pixel circuit operate in the second field, and in addition switches, every predetermined number of frames, between the two pixel circuits the pixel circuits that are made to operate in the first and second fields.

39. The active-matrix-driven display device of claim 17,
wherein the active-matrix-driven display device further includes a supply voltage controller that controls a magnitude of a supply voltage for feeding electric power, in each pixel circuit, via the driving transistor to the display element, and
wherein the supply voltage controller makes the magnitude of the supply voltage lower in the second field than in the first field.

40. The active-matrix-driven display device of claim 1,
wherein, in each pixel circuit, when a magnitude of the light emission start electrode-to-electrode voltage of the display element varies from a first voltage value to a second voltage value higher than the first voltage value, an effective value of a current that flows through the display element as corresponding to a given gradation signal increases.

41. An active-matrix-driven display device including a display panel composed of a plurality of pixels arrayed in a matrix, the display panel being connected to a scan driver for feeding a scan voltage to each pixel and a data driver for feeding a data voltage to each pixel, each pixel being built with a pixel circuit including:
a display element that emits light when fed with electric power;
a writing transistor that has a first electrode thereof connected to the data driver and that has a control electrode thereof connected to the scan driver;
a driving transistor that drives, according to a voltage applied to a control electrode thereof, the display element;
a first capacitive element that is provided in series with a line connecting a second electrode of the writing transistor to the control electrode of the driving transistor; and
an adjustment transistor that turns on and off conduction between a writing-transistors-side electrode of the first capacitive element and the display element.

42. An active-matrix-driven display device including a display panel composed of a plurality of pixels arrayed in a matrix, the display panel being connected to a scan driver for feeding a scan voltage to each pixel and a data driver for feeding a data voltage to each pixel, each pixel being built with a pixel circuit including:
a display element that emits light when fed with electric power;
a writing transistor that has a first electrode thereof connected to the data driver and that has a control electrode thereof connected to the scan driver;
a driving transistor that drives, according to a voltage applied to a control electrode thereof, the display element;
a switching transistor that has one conducting electrode thereof connected to the control electrode of the driving transistor;
a first capacitive element that is provided in series with a line connecting a second electrode of the writing transistor to a control electrode of the switching transistor; and
an adjustment transistor that turns on and off conduction between a writing-transistors-side electrode of the first capacitive element and the display element.
